(19) United States
(12) Patent Application Publication
(10) Pub. No.: US 2017/0040402 A1
(43) Pub. Date: Feb. 9, 2017

(54) DISPLAY PANEL, DATA PROCESSING DEVICE, AND METHOD FOR MANUFACTURING DISPLAY PANEL

(71) Applicant: Semiconductor Energy Laboratory Co., Ltd., Atsugi-shi (JP)

(72) Inventors: Seiji YASUMOTO, Tochigi (JP); Hiroki ADACHI, Tochigi (JP); Masataka SATO, Tochigi (JP); Koji KUSUNOKI, Kawasaki (JP); Yoshiharu HIRAKATA, Tochigi (JP)

(21) Appl. No.: 15/221,733

(22) Filed: Jul. 28, 2016

(30) Foreign Application Priority Data
Aug. 7, 2015 (JP) 2015-156992
Jun. 21, 2016 (JP) 2016-122745

(51) Int. Cl. H01L 27/32; G02F 1/1362; G09G 3/20; G02F 1/1335; G06F 3/01; H01L 27/12; G02F 1/1368

(52) U.S. Cl. CPC H01L 27/3267; H01L 27/3262; H01L 27/1237; H01L 27/124; H01L 27/1248; H01L 27/1255; G02F 1/136227; G02F 1/1368; G02F 1/133553; H01L 27/3276; G02F 1/136286; H01L 27/1262; G06F 3/01; G09G 3/2092; H01L 27/1225; H01L 29/7869

(57) ABSTRACT

A novel display panel that is highly convenient or reliable is provided. A structure in invented which includes a first display element, a first conductive film, a second conductive film, a first insulating film, an intermediate film, a pixel circuit, and a second display element. The first conductive film is electrically connected to the first display element. The second conductive film includes a region overlapping with the first conductive film. The first insulating film includes a region located between the second conductive film and the first conductive film. The first conductive film is located between the second conductive film and part of the intermediate film. The pixel circuit is electrically connected to the second conductive film. The second display element is electrically connected to the pixel circuit. The first insulating film has an opening. The second conductive film is electrically connected to the first conductive film through the opening.

### TECHNICAL FIELD

One embodiment of the present invention relates to a display panel, a data processing device, a semiconductor device, or a method for manufacturing a display panel.

Note that one embodiment of the present invention is not limited to the above technical field. The technical field of one embodiment of the invention disclosed in this specification and the like relates to an object, a method, or a manufacturing method. Another embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, a method for driving any of them, and a method for manufacturing any of them.

### BACKGROUND ART

A liquid crystal display device in which a light-condensing means and a pixel electrode are provided on one side of a substrate and a region transmitting visible light in the pixel electrode is provided to overlap with an optical axis of the light-condensing means is known. In addition, a liquid crystal display device which uses an anisotropic light-condensing means having a light-condensing direction X and a non-light-condensing direction Y, where the non-light-condensing direction Y corresponds to the longitudinal direction of a region transmitting visible light in the pixel electrode is known (Patent Document 1).

### REFERENCE

### Patent Document

└Patent Document 1┘ Japanese Published Patent Application No. 2011-191750

### DISCLOSURE OF INVENTION

One object of one embodiment of the present invention is to provide a novel display panel that is highly convenient or reliable. Another object of one embodiment of the present invention is to provide a novel data processing device that is highly convenient or reliable. Another object of one embodiment of the present invention is to provide a method for manufacturing a novel display panel that is highly convenient or reliable. Another object of one embodiment of the present invention is to provide a novel display panel, a novel data processing device, a method for manufacturing a novel display panel, or a novel semiconductor device.

The descriptions of these objects do not disturb the existence of other objects. In one embodiment of the present invention, there is no need to achieve all the objects. Other objects will be apparent from and can be derived from the descriptions of the specification, the drawings, the claims, and the like.

(1) One embodiment of the present invention is a display panel including a signal line and a pixel.

The pixel is electrically connected to the signal line. The pixel includes a first display element, a first conductive film, a second conductive film, a first insulating film, an intermediate film, a pixel circuit, and a second display element.

The first conductive film is electrically connected to the first display element. The second conductive film includes a region overlapping with the first conductive film. The first insulating film includes a region located between the second conductive film and the first conductive film. The first conductive film is interposed between the first insulating film and part of the intermediate film. The pixel circuit is electrically connected to the second conductive film. The second display element is electrically connected to the pixel circuit.

The first insulating film has an opening. The second conductive film is electrically connected to the first conductive film through the opening. The pixel circuit is electrically connected to the signal line.

(2) Another embodiment of the present invention is the above display panel in which the intermediate film includes a conductive oxide or an oxide semiconductor.

(3) Another embodiment of the present invention is the above display panel that includes a second insulating film.

The second insulating film has an opening and includes a region located between the intermediate film and the first insulating film, along an outer edge of the opening.

The intermediate film includes a side end portion embedded at the second insulating film, and includes a region that overlaps with the opening in the second insulating film and is in contact with the first conductive film.

(4) Another embodiment of the present invention is the above display panel in which the pixel circuit includes a switch. The switch includes a transistor. The transistor includes an oxide semiconductor.

(5) Another embodiment of the present invention is the above display panel in which the second display element is located so as to be seen in a part of a range in which the first display element is seen.

(6) Another embodiment of the present invention is the above display panel in which the second display element has a function of displaying an image in a region surrounded by a region in which the first display element displays an image.

(7) Another embodiment of the present invention is the above display panel in which the first display element includes a reflective film and has a function of controlling the intensity of reflected light.

The reflective film has a function of reflecting incident light. The reflective film has an opening. The second display element has a function of emitting light toward the opening.

(8) Another embodiment of the present invention is the above display panel including the pixel, a group of pixels, another group of pixels, and a scan line.

The group of pixels include pixels and are arranged in a row direction. The another group of pixels include pixels and are arranged in a column direction intersecting the row direction.

The scan line is electrically connected to the group of pixels arranged in the row direction.

The another group of pixels arranged in the column direction are electrically connected to the signal line.

Another pixel adjacent to one pixel in the row direction or the column direction has an opening in a position different from that of the opening in the one pixel.

The display panel of one embodiment of the present invention includes a first display element, a first conductive film, a second conductive film, a first insulating film, an intermediate film, a pixel circuit, and a second display element. The first conductive film is electrically connected to the first display element. The second conductive film includes a region overlapping with the first conductive film. The first insulating film includes a region located between the second conductive film and the first conductive film. The first conductive film is located between the second conductive film and part of the intermediate film. The pixel circuit is electrically connected to the second conductive film. The second display element is electrically connected to the pixel circuit. The first insulating film has an opening. The second conductive film is electrically connected to the first conductive film through the opening.

Thus, the first display element and the second display element that displays an image using a method different from that of the first display element can be driven using pixel circuits that can be formed in the same process. Thus, the novel display panel can be highly convenient or reliable.

(9) Another embodiment of the present invention is the above display panel including a terminal and a conductive film.

The first insulating film includes a region located between the terminal and the conductive film. The first insulating film has an opening.

The terminal is electrically connected to the conductive film through the opening. The conductive film is electrically connected to the pixel circuit.

Thus, power or signals can be supplied to the pixel circuit through the terminal. Thus, the novel display panel can be highly convenient or reliable.

(10) Another embodiment of the present invention is a data processing device including an arithmetic device and an input/output device.

The arithmetic device has a function of receiving positional data and supplying image data and control data.

The input/output device has a function of supplying the positional data and receiving the image data and the control data.

The input/output device includes a display portion that displays the image data and an input portion that supplies the positional data.

The display portion includes the above display panel.

The input portion has a function of supplying positional data based on the position of a pointer.

The arithmetic device has a function of determining the moving speed of the pointer in accordance with the positional data.

The arithmetic device has a function of determining contrast or brightness of the image data in accordance with the moving speed of the pointer.

The above data processing device of one embodiment of the present invention includes the input/output device that supplies positional data and receives image data and the arithmetic device that receives the positional data and supplies the image data. The arithmetic device determines the contrast or brightness of image data in accordance with the moving speed of the pointer. With this structure, eyestrain on a user caused when the display position of image data is moved can be reduced, that is, eye-friendly display can be performed. Thus, the novel data processing device can be highly convenient or reliable.

(11) Another embodiment of the present invention is the data processing device in which the input portion includes at least one of a keyboard, a hardware button, a pointing device, a touch sensor, an illuminance sensor, an imaging device, an audio input device, a viewpoint input device, and a posture determination device.

Thus, the data processing device can have low power consumption and excellent visibility even in a bright place. Thus, the novel data processing device can be highly convenient or reliable.

(12) Another embodiment of the present invention is a manufacturing method of the display panel including the following 12 steps.

In the first step, an intermediate film including a region overlapping with a process substrate is formed.

In the second step, a second insulating film is formed so as to cover the intermediate film.

In the third step, the second insulating film is heated.

In the fourth step, the second insulating film is processed into a predetermined shape.

In the fifth step, a first conductive film including a region overlapping with the intermediate film is formed.

In the sixth step, a first insulating film having an opening in a region overlapping with the first conductive film is formed.

In the seventh step, a second conductive film that overlaps with the opening in the first insulating film and a pixel circuit are formed.

In the eighth step, the second display element electrically connected to the pixel circuit is formed.

In the ninth step, a second substrate is stacked such that the second display element is located between the process substrate and the second substrate.

In the tenth step, the process substrate is separated.

In the eleventh step, an alignment film is formed such that the intermediate film is located between the first conductive film and the alignment film.

In the twelfth step, the first display element is formed.

The method for manufacturing the display panel of one embodiment of the present invention includes the step of forming the intermediate film, the step of forming the second insulating film overlapping with the intermediate film, and the step of separating the process substrate. The method enables formation of a region in which the intermediate film is exposed and a region in which the second insulating film is exposed. Thus, the manufacturing method of a novel display panel that is highly convenient or reliable can be provided.

Although the block diagram attached to this specification shows components classified by their functions in independent blocks, it is difficult to classify actual components according to their functions completely and it is possible for one component to have a plurality of functions.

In this specification, the terms “source” and “drain” of a transistor interchange with each other depending on the polarity of the transistor or the levels of potentials supplied to the terminals. In general, in an n-channel transistor, a terminal to which a lower potential is supplied is called a source, and a terminal to which a higher potential is supplied is called a drain. Further, in a p-channel transistor, a terminal to which a lower potential is supplied is called a drain, and a terminal to which a higher potential is supplied is called a source. In this specification, although connection relation of the transistor is described assuming that the source and the drain are fixed in some cases for convenience, actually, the names of the source and the drain interchange with each other depending on the relation of the potentials.

In this specification, a “source” of a transistor means a source region that is part of a semiconductor film functioning as an active layer or a source electrode connected to the semiconductor film. Similarly, a “drain” of the transistor means a drain region that is part of the semiconductor film or a drain electrode connected to the semiconductor film. A “gate” means a gate electrode.

In this specification, a state in which transistors are connected to each other in series means, for example, a state in which only one of a source and a drain of a first transistor is connected to only one of a source and a drain of a second transistor. In addition, a state in which transistors are connected to each other in parallel means a state in which one of a source and a drain of a first transistor is connected to one of a source and a drain of a second transistor and the other of the source and the drain of the first transistor is connected to the other of the source and the drain of the second transistor.

In this specification, the term “connection” means electrical connection and corresponds to a state where a current, a voltage, or a potential can be supplied or transmitted. Accordingly, a connection state means not only a state of direct connection but also a state of indirect connection through a circuit element such as a wiring, a resistor, a diode, or a transistor that allows a current, a voltage, or a potential to be supplied or transmitted.

In this specification, even when different components are connected to each other in a circuit diagram, there is actually a case where one conductive film has functions of a plurality of components, such as a case where part of a wiring serves as an electrode. The term “connection” also means such a case where one conductive film has functions of a plurality of components.

In addition, in this specification, one of a first electrode and a second electrode of a transistor refers to a source electrode and the other refers to a drain electrode.

One embodiment of the present invention provides a novel display panel that is highly convenient or reliable, a novel data processing device that is highly convenient or reliable, a method for manufacturing a novel display panel that is highly convenient or reliable, a novel display panel, a novel data processing device, a method for manufacturing a display panel, or a novel semiconductor device.

Note that the descriptions of these effects does not disturb the existence of other effects. One embodiment of the present invention does not necessarily have all the effects listed above. Other effects will be apparent from and can be derived from the descriptions of the specification, the drawings, the claims, and the like.

### BRIEF DESCRIPTION OF DRAWINGS

FIGS. 1A, 1B1, and 1B2 illustrate the structure of a display panel of an embodiment.

FIGS. 2A to 2C illustrate the structure of a display panel of an embodiment.

FIG. 3 is a circuit diagram illustrating a pixel circuit of an embodiment.

FIGS. 4A, 4B1, and 4B2 illustrate the structures of display panels of embodiments.

FIGS. 5A to 5D illustrate the structure of a transistor of an embodiment.

FIGS. 6A to 6C illustrate the structure of a transistor of an embodiment.

FIG. 7 is a flow chart showing a method for manufacturing a display panel of an embodiment.

FIG. 8 illustrates a method for manufacturing a display panel of an embodiment.

FIG. 9 illustrates a method for manufacturing a display panel of an embodiment.

FIG. 10 illustrates a method for manufacturing a display panel of an embodiment.

FIGS. 11A and 11C illustrates a method for manufacturing a display panel of an embodiment.

FIGS. 12A to 12C illustrate a method for manufacturing a display panel of an embodiment.

FIGS. 13A to 13C illustrate a method for manufacturing a display panel of an embodiment.

FIGS. 14A to 14C illustrate a method for manufacturing a display panel of an embodiment.

FIG. 15 illustrates the structure of an input/output device of an embodiment.

FIGS. 16A to 16C are a block diagram and projection views illustrating the structures of data processing devices of embodiments.

FIGS. 17A to 17C are block diagrams and a circuit diagram illustrating the structures of display portions of embodiments.

FIGS. 18A and 18B are flow charts each showing a program of an embodiment.

FIG. 19 is a schematic diagram illustrating image data of an embodiment.

FIGS. 20A to 20C are a cross-sectional view and circuit diagrams illustrating the structures of semiconductor devices of embodiments.

FIG. 21 is a block diagram illustrating the structure of a CPU of an embodiment.

FIG. 22 is a circuit diagram illustrating the configuration of a storage element of an embodiment.

FIGS. 23A to 23H illustrate the structures of electronic devices of embodiments.

FIGS. 24A and 24B illustrate the structure of a display panel of an embodiment.

FIGS. 25A to 25C illustrate the structure of a display panel of an embodiment.

FIGS. 26A to 26C illustrate the structure of a display panel of an embodiment.

FIG. 27 shows measured XRD spectra of samples.

FIGS. 28A and 28B are TEM images of samples and FIGS. 28C to 28L are electron diffraction patterns thereof.

FIGS. 29A to 29C show EDX mapping images of a sample.

### BEST MODE FOR CARRYING OUT THE INVENTION

The display panel of one embodiment of the present invention includes a first display element, a first conductive film, a second conductive film, a first insulating film, an intermediate film, a pixel circuit, and a second display element. The first conductive film is electrically connected to the first display element. The second conductive film includes a region overlapping with the first conductive film. The first conductive film is located between the second conductive film and part of the intermediate film. The first insulating film includes a region located between the second conductive film and the first conductive film. The pixel circuit is electrically connected to the second conductive film. The second display element is electrically connected to the pixel circuit. The first insulating film has an opening. The second conductive film is electrically connected to the first conductive film through the opening.

Thus, the first display element and the second display element that displays an image using a method different from that of the first display element can be driven using pixel circuits that can be formed in the same process. Thus, the novel display panel can be highly convenient or reliable.

Embodiments will be described in detail with reference to drawings. Note that the present invention is not limited to the description below, and it is easily understood by those skilled in the art that various changes and modifications can be made without departing from the spirit and scope of the present invention. Accordingly, the present invention should not be interpreted as being limited to the content of the embodiments below. Note that in the structures of the invention described below, the same portions or portions having similar functions are denoted by the same reference numerals in different drawings, and description of such portions is not repeated.

### Embodiment 1

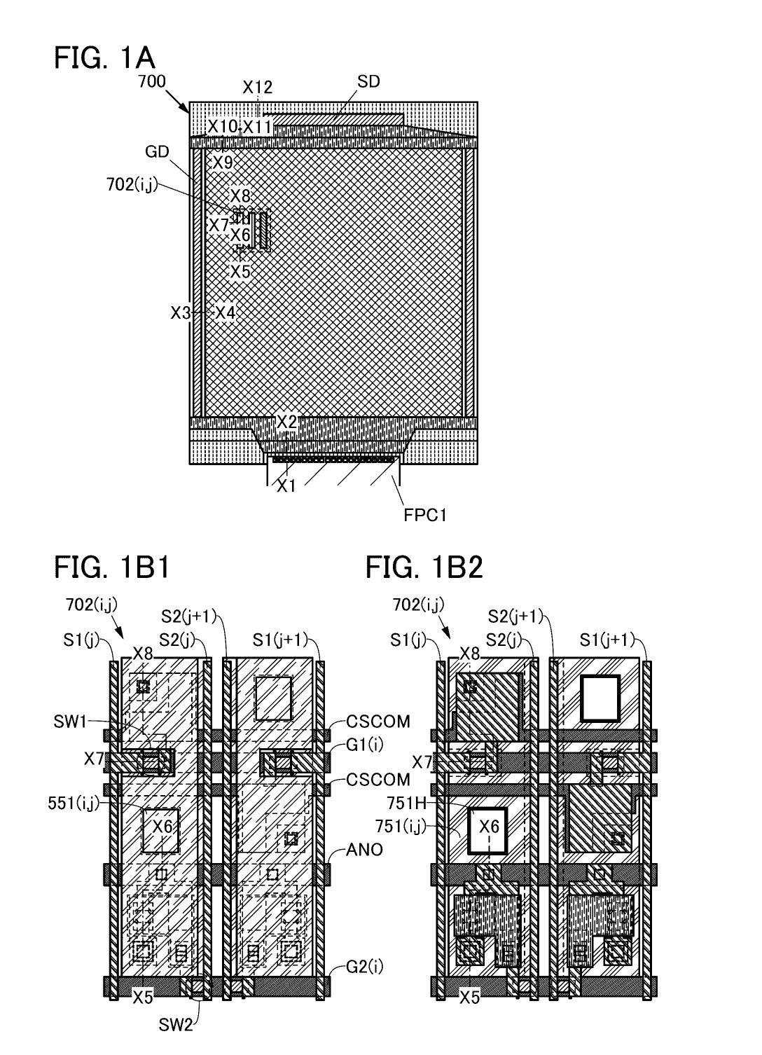

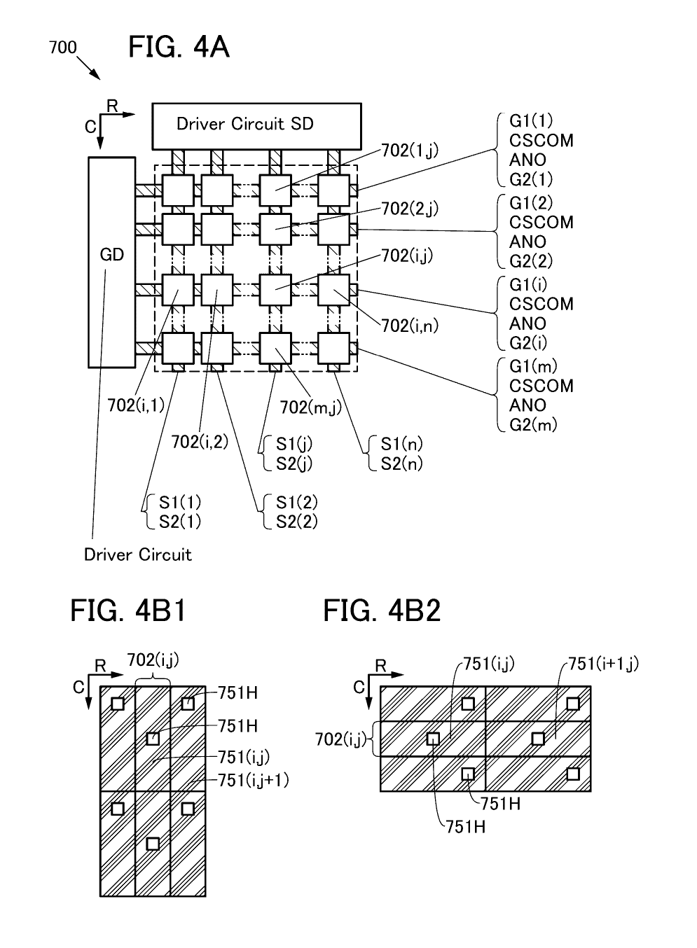

In this embodiment, the structure of a display panel of one embodiment of the present invention will be described with reference to FIGS. 1A, 1B1, and 1B2 to FIGS. 4A, 4B1, and 4B2.

FIGS. 1A, 1B1, and 1B2 illustrate the structure of a display panel 700 of one embodiment of the present invention. FIG. 1A is a bottom view of the display panel 700 of one embodiment of the present invention. FIG. 1B1 is a bottom view illustrating a part of FIG. 1A, and FIG. 1B2 is a bottom view illustrating the part illustrated in FIG. 1B1 in which some components are omitted.

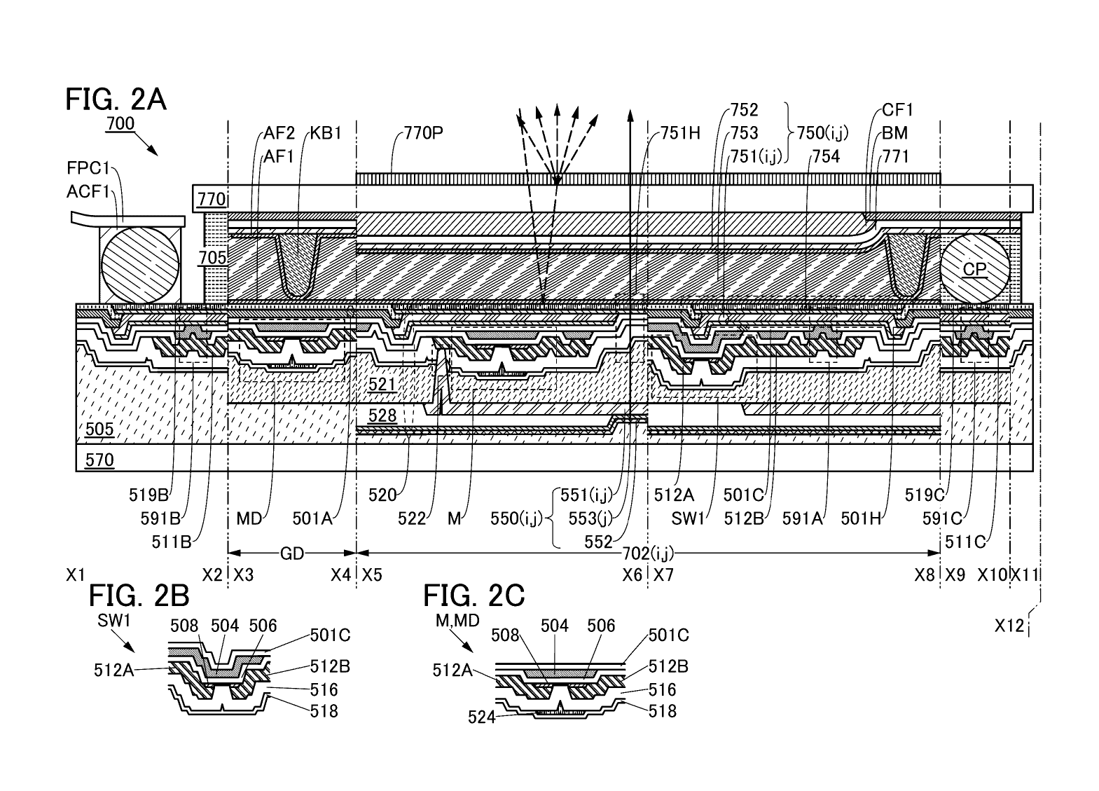

FIGS. 2A to 2C illustrate the structure of the display panel 700 of one embodiment of the present invention. FIG. 2A is a cross-sectional view taken along dashed-dotted lines X1-X2, X3-X4, X5-X6, X7-X8, X9-X10, and X11-X12 in FIG. 1A. FIG. 2B is a cross-sectional view illustrating the structure of part of the display panel, and FIG. 2C is a cross-sectional view illustrating the structure of another part of the display panel.

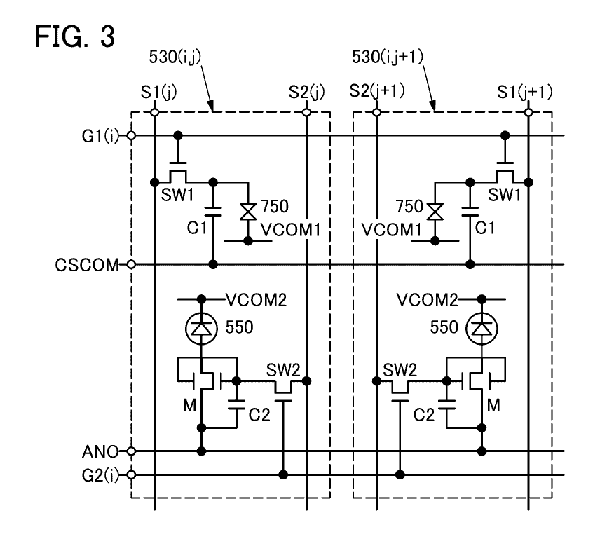

FIG. 3 illustrates the structure of the display panel 700 of one embodiment of the present invention. FIG. 3 is a circuit diagram illustrating a pixel circuit 530(i,j) and a pixel circuit 530(i,j+1) that can be used as pixel circuits included in the display panel 700 of one embodiment of the present invention.

FIGS. 4A, 4B1, and 4B2 illustrate the structure of the display panel 700 of one embodiment of the present invention. FIG. 4A is a block diagram illustrating arrangement of pixels, wirings, and the like that can be used in the display panel 700 of one embodiment of the present invention. FIGS. 4B1 and 4B2 are schematic diagrams each illustrating arrangement of openings 751H that can be used in the display panel 700 of one embodiment of the present invention.

Note that in this specification, an integral variable of 1 or more may be used for a reference numeral. For example, “(p)” where p is an integral variable of 1 or more may be used for part of a reference numeral that specifies any one of components (up to p components). For another example, “(m, n)” where m and n are each an integral variable of 1 or more may be used for part of a reference numeral that specifies any one of components (up to m×n components).

### <Structure Example 1 of Display Panel>

The display panel 700 described in this embodiment includes a signal line S1(j), a pixel 702(i,j) (see FIGS. 1B1 and 1B2).

The pixel 702(i,j) is electrically connected to the signal line S1(j).

The pixel 702(i,j) includes a first display element 750(i,j), a first conductive film, a second conductive film, an intermediate film 754, an insulating film 501C, a pixel circuit 530(i,j), and a second display element 550(i,j) (see FIG. 2A and FIG. 3).

The first conductive film is electrically connected to the first display element 750(i,j) (see FIG. 2A). For example, the first conductive film can be used for a first electrode 751(i,j) of the first display element 750(i,j).

The second conductive film includes a region overlapping with the first conductive film. For example, the second conductive film can be used for a conductive film 512B serving as a source electrode or a drain electrode of a transistor that can be used for a switch SW1.

The insulating film 501C includes a region interposed between the second conductive film and the first conductive film.

The first conductive film is located between the insulating film 501C and part of the intermediate film 754.

The pixel circuit 530(i,j) is electrically connected to the second conductive film. For example, a transistor using the second conductive film for the conductive film 512B serving as a source electrode or a drain electrode can be used for the switch SW1 of the pixel circuit 530(i,j) (see FIG. 2A and FIG. 3).

The second display element 550(i,j) is electrically connected to the pixel circuit 530(i,j).

For example, a film having a function of allowing hydrogen passage and supplying hydrogen can be used as the intermediate film 754. For example, a material having a function of allowing passage of hydrogen supplied by an insulating film 501A can be used for the intermediate film 754.

The insulating film 501C has an opening 591A (see FIG. 2A).

The second conductive film is electrically connected to the first conductive film through the opening 591A. For example, the conductive film 512B is electrically connected to the first electrode 751(i,j) doubling as the first conductive film.

The pixel circuit 530(i,j) is electrically connected to the signal line S1(j) (see FIG. 3). Note that the conductive film 512A is electrically connected to the signal line S1(j) (see FIG. 2A and FIG. 3).

The intermediate film 754 of the display panel described in this embodiment includes a conductive oxide or an oxide semiconductor.

The display panel described in this embodiment includes the insulating film 501A.

The insulating film 501A has an opening 501H. The insulating film 501A includes a region interposed between the intermediate film 754 and the insulating film 501C, along the outer edge of the opening 501H.

The intermediate film 754 includes a side end portion embedded at the insulating film 501A. The intermediate film 754 and the insulating film 501A are level with each other. The intermediate film 754 includes a region that overlaps with the opening in the insulating film 501A and is in contact with the first conductive film.

The pixel circuit 530(i,j) of the display panel described in this embodiment includes the switch SW1. The switch SW1 includes a transistor that includes an oxide semiconductor.

The second display element 550(i,j) of the display panel described in this embodiment is provided so as to be seen in a part of a range in which the first display element 750(i,j) is seen. For example, in the drawing, dashed arrows show the direction in which the first display element 750(i,j) displays images by controlling the intensity of external light reflection. In addition, a solid arrow shows the direction in which the second display element 550(i,j) displays images (see FIG. 2A).

Furthermore, the second display element 550(i,j) of the display panel described in this embodiment has a function of displaying images in a region surrounded by a region in which the first display element 750(i,j) displays images (see FIG. 4B1 or FIG. 4B2). Note that the first display element 750(i,j) displays images in a region overlapping with the first electrode 751(i,j), and the second display element 550(i,j) displays images in a region overlapping with the opening 751H. In other words, the second display element 550(i,j) of the display panel described in this embodiment has a function of displaying images in a region overlapping with the opening 751H surrounded by the first electrode 751(i,j) that overlaps with a region in which the first display element 750(i,j) displays images (see FIG. 4B1 or FIG. 4B2).

The first display element 750(i,j) of the display panel described in this embodiment of the present invention includes a reflective film having a function of reflecting incident light and has a function of controlling the intensity of reflected light. The reflective film has the opening 751H. Note that the first electrode 751(i,j) can be used for the reflective film of the first display element 750(i,j).

The second display element 550(i,j) has a function of emitting light toward the opening 751H.

The display panel described in this embodiment includes the pixel 702(i,j), a group of pixels 702(i,l) to 702(i,n), another group of pixels 702(i,j) to 702(m,j), and a scan line G1(i) (see FIG. 4A). Note that i is an integer greater than or equal to 1 and less than or equal to m, j is an integer greater than or equal to 1 and less than or equal to n, and each of m and n is an integer greater than or equal to 1.

The display panel described in this embodiment also includes a scan line G2(i), a wiring CSCOM, and a wiring ANO.

The group of pixels 702(i,l) to 702(i,n) include the pixel 702(i,j) and are arranged in the row direction (the direction shown by the arrow R in drawings).

The other group of pixels 702(i,j) to 702(m,j) include the pixel 702(i,j) and are arranged in the column direction (the direction shown by the arrow C in drawings) intersecting the row direction.

The scan line G1(i) is electrically connected to the group of pixels 702(i,l) to 702(i,n) arranged in the row direction.

The another group of pixels 702(i,j) to 702(m,j) arranged in the column direction are electrically connected to the signal line S1 (j).

For example, the pixel 702(i,j+1) adjacent to the pixel 702(i,j) in the row direction has an opening in a position different from that of the opening 751H in the pixel 702(i,j) (see FIG. 4B1).

For example, the pixel 702(i+11) adjacent to the pixel 702(i,j) in the column direction has an opening in a position different from that of the opening 751H in the pixel 702(i,j) (see FIG. 4B2). Note that for example, the first electrode 751(i,j) can be used for the reflective film.

The display panel of one embodiment of the present invention includes a first display element, a first conductive film, a second conductive film, a first insulating film, an intermediate film, a pixel circuit, and a second display element. The first conductive film is electrically connected to the first display element. The second conductive film includes a region overlapping with the first conductive film. The first conductive film is located between the second conductive film and part of the intermediate film. The first insulating film includes a region located between the second conductive film and the first conductive film. The pixel circuit is electrically connected to the second conductive film. The second display element is electrically connected to the pixel circuit. The first insulating film has an opening. The second conductive film is electrically connected to the first conductive film through the opening.

Thus, the first display element and the second display element that displays an image using a method different from that of the first display element can be driven using a pixel circuit that can be formed in the same process. Thus, the novel display panel can be highly convenient or reliable.

The display panel described in this embodiment also includes a terminal 519B and a conductive film 511B (see FIG. 2A).

The insulating film 501C includes a region interposed between the terminal 519B and the conductive film 511B. The insulating film 501C has an opening 591B. The terminal 519B is electrically connected to the conductive film 511B through the opening 591B. In addition, the conductive film 511B is electrically connected to the pixel circuit 530(i,j). For example, in the case where the first electrode 751(i,j) is used for the reflective film, a surface serving as a contact of the terminal 519B faces in the same direction as a surface of the first electrode 751(i,j) that faces light incident on the first display element 750(i,j).

Thus, power or signals can be supplied to the pixel circuit through the terminal. Thus, the novel display panel can be highly convenient or reliable.

The first display element 750(i,j) of the display panel described in this embodiment includes a layer 753 containing a liquid crystal material, the first electrode 751(i,j), and a second electrode 752. The second electrode 752 is positioned such that an electric field which controls the alignment of the liquid crystal material is generated between the second electrode 752 and the first electrode 751(i,j).

The display panel described in this embodiment also includes an alignment film AF1 and an alignment film AF2. The alignment film AF2 is provided such that the layer 753 containing a liquid crystal material is interposed between the alignment film AF1 and the alignment film AF2.

The second display element 550(i,j) of the display panel described in this embodiment includes a third electrode 551(i,j), a fourth electrode 552, and a layer 553(j) containing a light-emitting organic compound.

The fourth electrode 552 includes a region overlapping with the third electrode 551(i,j).

The layer 553(j) containing a light-emitting organic compound is provided between the third electrode 551 and the fourth electrode 552. The third electrode 551(i,j) is electrically connected to the pixel circuit 530(i,j) at a connection portion 522.

The pixel 702(i,j) of the display panel described in this embodiment includes a coloring film CF1, a light-blocking film BM, an insulating film 771, and a functional film 770P.

The coloring film CF1 includes a region overlapping with the first display element 750(i,j). The light-blocking film BM has an opening in a region overlapping with the first display element 750(i,j).

The insulating film 771 is provided between the coloring film CF1 and the layer 753 containing a liquid crystal material or between the light-blocking film BM and the layer 753 containing a liquid crystal material. The insulating film 771 can reduce unevenness due to the thickness of the coloring film CF1. Furthermore, the insulating film 771 can prevent impurities from diffusing from the light-blocking film BM, the coloring film CF1, or the like to the layer 753 containing a liquid crystal material.

The functional film 770P includes a region overlapping with the first display element 750(i,j). The functional film 770P is provided such that a substrate 770 is interposed between the functional film 770P and the first display element 750(i,j).

The display panel described in this embodiment also includes a substrate 570, the substrate 770, and a functional layer 520.

The substrate 770 includes a region overlapping with the substrate 570. The functional layer 520 is provided between the substrate 570 and the substrate 770.

The functional layer 520 includes the pixel circuit 530(0, the second display element 550(i,j), an insulating film 521, and an insulating film 528. The functional layer 520 includes an insulating film 518 and an insulating film 516.

The insulating film 521 is provided between the pixel circuit 530(i,j) and the second display element 550(i,j).

The insulating film 528 is provided between the insulating film 521 and the substrate 570, and has an opening in a region overlapping with the second display element 550(i,j). The insulating film 528 formed along the outer edge of the third electrode 551 can prevent a short circuit between the third electrode 551 and the fourth electrode 552.

The insulating film 518 includes a region interposed between the insulating film 521 and the pixel circuit 530(i,j), and the insulating film 516 includes a region interposed between the insulating film 518 and the pixel circuit 530(i,j).

The display panel described in this embodiment also includes a bonding layer 505, a sealing material 705, and a structure body KB1.

The bonding layer 505 is provided between the functional layer 520 and the substrate 570, and has a function of bonding the functional layer 520 and the substrate 570 together.

The sealing material 705 is provided between the functional layer 520 and the substrate 770, and has a function of bonding the functional layer 520 and the substrate 770 together.

The structure body KB1 has a function of providing a certain space between the functional layer 520 and the substrate 770.

The display panel described in this embodiment also includes a terminal 519C, a conductive film 511C, and a conductor CP.

The insulating film 501C includes a region interposed between the terminal 519C and the conductive film 511C. The insulating film 501C has an opening 591C.

The terminal 519C is electrically connected to the conductive film 511C through the opening 591C. The conductive film 511C is electrically connected to the pixel circuit 530(i,j).

The conductor CP is interposed between the terminal 519C and the second electrode 752, and electrically connects the terminal 519C and the second electrode 752. For example, a conductive particle can be used as the conductor CP. The display panel described in this embodiment also includes a driver circuit GD and a driver circuit SD (see FIG. 1A and FIG. 4A).

The driver circuit GD is electrically connected to the scan line G1(i). The driver circuit GD includes a transistor MD, for example. Specifically, a transistor including a semiconductor film that can be formed in the same process as the transistor included in the pixel circuit 530(i,j) can be used as the transistor MD (see FIGS. 2A and 2C).

The driver circuit SD is electrically connected to the signal line S1(j). The driver circuit SD is electrically connected to a terminal that can be formed in the same process as, for example, the terminal 519B or the terminal 519C with the use of a conductive material.

Individual components included in the display panel will be described below. Note that these units cannot be clearly distinguished and one unit also serves as another unit or may include part of another unit.

For example, the first conductive film can be used for the first electrode 751(i,j). Furthermore, the first conductive film can also be used for the reflective film.

The second conductive film can be used for the conductive film 512B serving as the source electrode or the drain electrode of the transistor.

### Structure Example 1

The display panel of one embodiment of the present invention includes the substrate 570, the substrate 770, the structure body KB1, the sealing material 705, and the bonding layer 505.

The display panel of one embodiment of the present invention also includes the functional layer 520, the insulating film 521, and the insulating film 528.

The display panel of one embodiment of the present invention also includes the signal line S1(j), a signal line S2(j), a scan line G1(i), the scan line G2(i), the wiring CSCOM, and the wiring ANO.

The display panel of one embodiment of the present invention also includes a first conductive film or a second conductive film.

The display panel of one embodiment of the present invention also includes the terminal 519B, the terminal 519C, the conductive film 511B, or the conductive film 511C.

The display panel of one embodiment of the present invention also includes the pixel circuit 530(i,j) and the switch SW1.

The display panel of one embodiment of the present invention also includes the first display element 750(i,j), the first electrode 751(i,j), a reflective film, the opening 751H, the layer 753 containing a liquid crystal material, or the second electrode 752.

The display panel of one embodiment of the present invention also includes the alignment film AF1, the alignment film AF2, the coloring film CF1, the light-blocking film BM, the insulating film 771, or the functional film 770P.

The display panel of one embodiment of the present invention also includes the second display element 550(i,j), the third electrode 551(11), the fourth electrode 552, or the layer 553(j) containing a light-emitting organic compound.

The display panel of one embodiment of the present invention also includes the insulating film 501A, the insulating film 501C, or the intermediate film 754.

The display panel of one embodiment of the present invention also includes the driver circuit GD or the driver circuit SD.

### <<Substrate 570>>

The substrate 570 or the like can be formed using a material having heat resistance high enough to withstand heat treatment in the manufacturing process. Specifically, non-alkali glass with a thickness of 0.7 mm can be used.

For example, a large-sized glass substrate having any of the following sizes can be used as the substrate 570 or the like: the 6th generation (1500 mm×1850 mm), the 7th generation (1870 mm×2200 mm), the 8th generation (2200 mm ×2400 mm), the 9th generation (2400 mm×2800 mm), and the 10th generation (2950 mm×3400 mm). Thus, a large-sized display device can be manufactured.

For the substrate 570 or the like, an organic material, an inorganic material, a composite material of an organic material and an inorganic material, or the like can be used. For example, an inorganic material such as glass, ceramic, or metal can be used for the substrate 570 or the like.

Specifically, non-alkali glass, soda-lime glass, potash glass, crystal glass, quartz, sapphire, or the like can be used for the substrate 570. Specifically, a material containing an inorganic oxide, an inorganic nitride, an inorganic oxynitride, or the like can be used for the substrate 570. For example, a material containing silicon oxide, silicon nitride, silicon oxynitride, or aluminum oxide can be used for the substrate 570. For example, stainless steel or aluminum can be used for the substrate 570.

For example, a single crystal semiconductor substrate or a polycrystalline semiconductor substrate of silicon or silicon carbide, a compound semiconductor substrate of silicon germanium or the like, or an SOI substrate can be used as the substrate 570 or the like. Thus, a semiconductor element can be provided over the substrate 570 or the like.

For example, an organic material such as a resin, a resin film, or plastic can be used for the substrate 570 or the like. Specifically, a resin film or resin plate of polyester, polyolefin, polyamide, polyimide, polycarbonate, an acrylic resin, or the like can be used for the substrate 570 or the like.

For example, a composite material formed by attaching a metal plate, a thin glass plate, or a film of an inorganic material to a resin film or the like can be used for the substrate 570 or the like. For example, a composite material formed by dispersing a fibrous or particulate metal, glass, inorganic material, or the like into a resin film can be used for the substrate 570 or the like. For example, a composite material formed by dispersing a fibrous or particulate resin, organic material, or the like into an inorganic material can be used for the substrate 570 or the like.

Furthermore, a single-layer material or a layered material in which a plurality of layers are stacked can be used for the substrate 570 or the like. For example, a layered material in which a base, an insulating film that prevents diffusion of impurities contained in the base, and the like are stacked can be used for the substrate 570 or the like. Specifically, a layered material in which glass and one or a plurality of films that are selected from a silicon oxide layer, a silicon nitride layer, a silicon oxynitride layer, and the like and that prevent diffusion of impurities contained in the glass are stacked can be used for the substrate 570 or the like. Alternatively, a layered material in which a resin and a film for preventing diffusion of impurities that penetrate the resin, such as a silicon oxide film, a silicon nitride film, and a silicon oxynitride film are stacked can be used for the substrate 570 or the like.

Specifically, a resin film, a resin plate, a stack, or the like of polyester, polyolefin, polyamide, polyimide, polycarbonate, an acrylic resin, or the like can be used for the substrate 570 or the like.

Specifically, a material including polyester, polyolefin, polyamide (e.g., nylon or aramid), polyimide, polycarbonate, polyurethane, an acrylic resin, an epoxy resin, a resin having a siloxane bond, such as silicone, or the like can be used for the substrate 570 or the like.

Specifically, polyethylene terephthalate (PET), polyethylene naphthalate (PEN), polyethersulfone (PES), acrylic, or the like can be used for the substrate 570 or the like.

Alternatively, paper, wood, or the like can be used for the substrate 570 or the like.

For example, a flexible substrate can be used as the substrate 570 or the like.

Note that a transistor, a capacitor, or the like can be directly formed on the substrate. Alternatively, a transistor, a capacitor, or the like formed on a substrate for use in manufacturing processes which can withstand heat applied in the manufacturing process can be transferred to the substrate 570 or the like. Thus, a transistor, a capacitor, or the like can be formed over a flexible substrate, for example.

### <<Substrate 770>>

For example, a light-transmitting material can be used for the substrate 770. Specifically, any of the materials that can be used for the substrate 570 can be used for the substrate 770. Specifically, non-alkali glass polished to a thickness of approximately 0.7 mm or 0.1 mm can be used.

### <<Structure Body KB1>>

The structure body KB1 or the like can be formed using an organic material, an inorganic material, or a composite material of an organic material and an inorganic material. This allows a predetermined space to be provided between components between which the structure body KB1 or the like is interposed.

Specifically, for the structure body KB1 or the like, polyester, polyolefin, polyamide, polyimide, polycarbonate, polysiloxane, an acrylic resin, or the like, or a composite material of a plurality of kinds of resins selected from these can be used. Alternatively, a photosensitive material may be used.

### <<Sealing Material 705>>

For the sealing material 705 or the like, an inorganic material, an organic material, a composite material of an inorganic material and an organic material, or the like can be used.

For example, an organic material such as a thermally fusible resin or a curable resin can be used for the sealing material 705 or the like.

For example, an organic material such as a reactive curable adhesive, a light curable adhesive, a thermosetting adhesive, and/or an anaerobic adhesive can be used for the sealing material 705 or the like.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin, or the like can be used for the sealing material 705 or the like.

### <<Bonding Layer 505>>

For example, any of the materials that can be used for the sealing material 705 can be used for the bonding layer 505.

### <<Insulating Film 521>>

For example, an insulating inorganic material, an insulating organic material, an insulating composite material containing an inorganic material and an organic material, or the like can be used for the insulating film 521 or the like.

Specifically, for example, an inorganic oxide film, an inorganic nitride film, an inorganic oxynitride film, or a material obtained by stacking any of these films and the like can be used as the insulating film 521 or the like. For example, a silicon oxide film, a silicon nitride film, a silicon oxynitride film, an aluminum oxide film, or a film including a stack of any of these films and the like can be used as the insulating film 521 or the like.

Specifically, for the insulating film 521 or the like, polyester, polyolefin, polyamide, polyimide, polycarbonate, polysiloxane, an acrylic resin, or the like, or a layered or composite material of a plurality of kinds of resins selected from these can be used. Alternatively, a photosensitive material may be used.

Thus, steps due to various components overlapping with the insulating film 521, for example, can be reduced.

### <<Insulating Film 528>>

For example, any of the materials that can be used for the insulating film 521 can be used for the insulating film 528 or the like. Specifically, a 1-μm-thick polyimide-containing film can be used as the insulating film 528.

### <<Insulating Film 501A>>

For example, any of the materials that can be used for the insulating film 521 can be used for the insulating film 501A.

For example, a material having a function of supplying hydrogen can be used for the insulating film 501A.

Specifically, a material obtained by stacking a material containing silicon and oxygen and a material containing silicon and nitrogen in this order can be used for the insulating film 501A. For example, a material having a function of releasing hydrogen by heating or the like to supply the hydrogen to another component can be used for the insulating film 501A. Specifically, a material having a function of releasing hydrogen taken in the manufacturing process, by heating or the like, to supply the hydrogen to another component can be used for the insulating film 501A.

For example, a film containing silicon and oxygen that is formed by a chemical vapor deposition method using silane or the like as a source gas can be used as the insulating film 501A.

### <<Insulating Film 501C>>

For example, any of the materials that can be used for the insulating film 521 can be used for the insulating film 501C. Specifically, a material containing silicon and oxygen can be used for the insulating film 501C. Thus, diffusion of impurities into the pixel circuit, the second display element, or the like can be inhibited.

For example, a 200-nm-thick film containing silicon, oxygen, and nitrogen can be used as the insulating film 501C.

Note that the insulating film 501C has the opening 591A, the opening 591B, and/or the opening 591C.

### <<Intermediate Film 754>>

For example, a film with a thickness greater than or equal to 10 nm and less than or equal to 500 nm, preferably greater than or equal to 10 nm and less than or equal to 100 nm can be used as the intermediate film 754.

For example, a material having a function of allowing hydrogen passage and supplying hydrogen can be used for the intermediate film 754.

For example, a conductive material can be used for the intermediate film 754.

For example, a light-transmitting material can be used for the intermediate film 754.

Specifically, a material containing indium and oxygen, a material containing indium, gallium, zinc, and oxygen, a material containing indium, tin, and oxygen, or the like can be used for the intermediate film 754.

A material containing indium and oxygen, a material containing indium, gallium, zinc, and oxygen, a material containing indium, tin, and oxygen, and the like have a function of allowing hydrogen passage.

Specifically, a 50- or 100-nm-thick film containing indium, gallium, zinc, and oxygen can be used as the intermediate film 754.

### <<Wiring, Terminal, and Conductive Film>>

A conductive material can be used for the wiring or the like. Specifically, a conductive material can be used for the signal line S1(j), the signal line S2(j), the scan line G1(i), the scan line G2(i), the wiring CSCOM, the wiring ANO, the terminal 519B, the terminal 519C, the conductive film 511B, the conductive film 511C, or the like.

For example, an inorganic conductive material, an organic conductive material, a metal, conductive ceramics, or the like can be used for the wiring or the like.

Specifically, a metal element selected from aluminum, gold, platinum, silver, copper, chromium, tantalum, titanium, molybdenum, tungsten, nickel, iron, cobalt, palladium, and manganese can be used for the wiring or the like. Alternatively, an alloy including any of the above-described metal elements, or the like can be used for the wiring or the like. In particular, an alloy of copper and manganese is preferably used in microfabrication using a wet etching method.

Specifically, any of the following structures can be used for the wiring or the like: a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, and the like.

Specifically, a conductive oxide, such as indium oxide, indium tin oxide, indium zinc oxide, zinc oxide, or zinc oxide to which gallium is added, can be used for the wiring or the like.

Specifically, a film containing graphene or graphite can be used for the wiring or the like.

For example, a film containing graphene formed by reducing a film containing graphene oxide can be used. The reduction can be performed by applying heat, using a reducing agent, or the like.

Specifically, a conductive high molecular compound can be used for the wiring or the like.

### <<First Conductive Film and Second Conductive Film>>

For example, any of the materials that can be used for the wiring or the like can be used for the first conductive film or the second conductive film.

Alternatively, the first electrode 751(i,j), the wiring, or the like can be used for the first conductive film. The wiring, the conductive film 512B of the transistor that can be used for the switch SW1, or the like can be used for the second conductive film.

<<Pixel Circuit 530(i,j)>>

The pixel circuit 530(i,j) is electrically connected to the signal line S1(j), the signal line S2(j), the scan line G1(i), the scan line G2(i), the wiring CSCOM, and the wiring ANO (see FIG. 3).

The pixel circuit 530(i,j+1) is electrically connected to a signal line S1(j+1), a signal line S2(j+1), the scan line G1(i), the scan line G2(i), the wiring CSCOM, and the wiring ANO.

In the case where the voltage of a signal supplied to the signal line S2(j) is different from the voltage of a signal supplied to the signal line S1(j+1), the signal line S1(j+1) is positioned apart from the signal line S2(j). Specifically, the signal line S2(j+1) is positioned adjacent to the signal line S2(j).

The pixel circuit 530(i,j) includes the switch SW1, a capacitor C1, a switch SW2, a transistor M, and a capacitor C2.

For example, a transistor including a gate electrode electrically connected to the scan line G1(i) and a first electrode electrically connected to the signal line S1(j) can be used for the switch SW1.

The capacitor C1 includes a first electrode electrically connected to a second electrode of the transistor used for the switch SW1 and a second electrode electrically connected to the wiring CSCOM.

For example, a transistor including a gate electrode electrically connected to the scan line G2(i) and a first electrode electrically connected to the signal line S2(j) can be used for the switch SW2.

The transistor M includes a gate electrode electrically connected to a second electrode of the transistor used for the switch SW2 and a first electrode electrically connected to the wiring ANO.

Note that a transistor including a conductive film provided such that a semiconductor film is interposed between a gate electrode and the conductive film can be used as the transistor M. For example, a conductive film electrically connected to the wiring capable of supplying a potential equal to that supplied to the first electrode of the transistor M can be used.

The capacitor C2 includes a first electrode electrically connected to the second electrode of the transistor used for the switch SW2 and a second electrode electrically connected to the first electrode of the transistor M.

Note that a first electrode and a second electrode of the first display element 750 are electrically connected to the second electrode of the transistor used for the switch SW1 and the wiring VCOM1, respectively. This enables the first display element 750 to be driven.

Note that a first electrode and a second electrode of the second display element 550 are electrically connected to the second electrode of the transistor M and the wiring VCOM2, respectively. This enables the second display element 550 to be driven.

### <<Switch SW1, Switch SW2, Transistor M, and Transistor MD>>

For example, a bottom-gate or top-gate transistor can be used for the switch SW1, the switch SW2, the transistor M, the transistor MD, and the like.

For example, a transistor including a semiconductor containing an element belonging to Group 14 can be used. Specifically, a semiconductor containing silicon can be used for a semiconductor film. For example, single crystal silicon, polysilicon, microcrystalline silicon, amorphous silicon, or the like can be used for the semiconductor films of the transistors.

For example, a transistor using an oxide semiconductor for a semiconductor film can be used. Specifically, an oxide semiconductor containing indium or an oxide semiconductor containing indium, gallium, and zinc can be used for a semiconductor film.

For example, a transistor having a lower leakage current in an off state than a transistor that uses amorphous silicon for a semiconductor film can be used for the switch SW1, the switch SW2, the transistor M, the transistor MD, and the like. Specifically, a transistor using an oxide semiconductor for a semiconductor film 508 can be used for the switch SW1, the switch SW2, the transistor M, the transistor MD, and the like.

Thus, a pixel circuit can hold an image signal for a longer time than a pixel circuit including a transistor that uses amorphous silicon for a semiconductor film. Specifically, the selection signal can be supplied at a frequency of lower than 30 Hz, preferably lower than 1 Hz, more preferably less than once per minute while flickering is suppressed. Consequently, eyestrain on a user of the data processing device can be reduced, and power consumption for driving can be reduced.

The transistor that can be used for the switch SW1 includes the semiconductor film 508 and a conductive film 504 including a region overlapping with the semiconductor film 508 (see FIG. 2B). The transistor that can be used for the switch SW1 also includes the conductive film 512A and the conductive film 512B.

Note that the conductive film 504 and the insulating film 506 serve as a gate electrode and a gate insulating film, respectively. The conductive film 512A has one of a function of a source electrode and a function of a drain electrode, and the conductive film 512B has the other.

A transistor including a conductive film 524 provided such that the semiconductor film 508 is interposed between the conductive film 504 and the conductive film 524 can be used as the transistor M (see FIG. 2C).

A conductive film formed by stacking a 10-nm-thick film containing tantalum and nitrogen and a 300-nm-thick film containing copper in this order can be used as the conductive film 504.

A material obtained by stacking a 400-nm-thick film containing silicon and nitrogen and a 200-nm-thick film containing silicon, oxygen, and nitrogen can be used for the insulating film 506.

A 25-nm-thick film containing indium, gallium, and zinc can be used as the semiconductor film 508.

A conductive film formed by stacking a 50-nm-thick film containing tungsten, a 400-nm-thick film containing aluminum, and a 100-nm-thick film containing titanium in this order can be used as the conductive film 512A or the conductive film 512B.

<<First Display Element 750(i,j)>>

For example, a display element having a function of controlling transmission or reflection of light can be used as the first display element 750(i,j). For example, a combined structure of a polarizing plate and a liquid crystal element or a MEMS shutter display element can be used. The use of a reflective display element can reduce power consumption of a display panel. Specifically, a reflective liquid crystal display element can be used as the first display element 750(i,j).

Specifically, a liquid crystal element that can be driven by any of the following driving methods can be used: an in-plane switching (IPS) mode, a twisted nematic (TN) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, and the like.

In addition, a liquid crystal element that can be driven by, for example, a vertical alignment (VA) mode such as a multi-domain vertical alignment (MVA) mode, a patterned vertical alignment (PVA) mode, an electrically controlled birefringence (ECB) mode, a continuous pinwheel alignment (CPA) mode, or an advanced super view (ASV) mode can be used.

For example, thermotropic liquid crystal, low-molecular liquid crystal, high-molecular liquid crystal, polymer dispersed liquid crystal, ferroelectric liquid crystal, or anti-ferroelectric liquid crystal can be used. Alternatively, a liquid crystal material which exhibits a cholesteric phase, a smectic phase, a cubic phase, a chiral nematic phase, an isotropic phase, or the like can be used. Alternatively, a liquid crystal material which exhibits a blue phase can be used.

<<First Electrode 751(i,j)>>

For example, the material that is used for the wiring or the like can be used for the first electrode 751(i,j). Specifically, a reflective film can be used for the first electrode 751(i,j).

### <Reflective Film>

For example, a material that reflects visible light can be used for the reflective film. Specifically, a material containing silver can be used for the reflective film. For example, a material containing silver, palladium, and the like or a material containing silver, copper, and the like can be used for the reflective film.

The reflective film reflects light that passes through the layer 753 containing a liquid crystal material, for example. This allows the first display element 750 to serve as a reflective liquid crystal element. Alternatively, for example, a material with unevenness on its surface can be used for the reflective film. In that case, incident light can be reflected in various directions so that a white image can be displayed.

Note that the first electrode 751(i,j) is not necessarily used for the reflective film and any of other structures may be employed. For example, the reflective film can be provided between the layer 753 containing a liquid crystal material and the first electrode 751(i,j). Alternatively, the first electrode 751(i,j) having a light-transmitting property can be provided between the reflective film and the layer 753 containing a liquid crystal material.

### <<Opening 751H>>

If the ratio of the total area of the opening 751H to the total area of the reflective film other than the opening is excessively high, an image displayed using the first display element 750(i,j) is dark. If the ratio of the total area of the opening 751H to the total area of the reflective film other than the opening is excessively low, an image displayed using the second display element 550(i,j) is dark.

If the area of the opening 751H in the reflective film is too small, light emitted from the second display element 550(i,j) is not efficiently extracted for display.

The opening 751H may have a polygonal shape, a quadrangular shape, an elliptical shape, a circular shape, a cross shape, a stripe shape, a slit-like shape, or a checkered pattern. The opening 751H may be close to the adjacent pixel. The opening 751H is preferably provided close to a pixel that has a function of emitting light of the same color, in which case an undesired phenomenon in which light emitted from the second display element 550 enters a coloring film of the adjacent pixel, which is called cross talk, can be suppressed.

### <<Second Electrode 752>>

For example, a material having a visible-light-transmitting property and conductivity can be used for the second electrode 752.

For example, a conductive oxide, a metal film thin enough to transmit light, or a metal nanowire can be used for the second electrode 752.

Specifically, a conductive oxide containing indium can be used for the second electrode 752. Alternatively, a metal thin film with a thickness greater than or equal to 1 nm and less than or equal to 10 nm can be used for the second electrode 752. Alternatively, a metal nanowire containing silver can be used for the second electrode 752.

Specifically, indium oxide, indium tin oxide, indium zinc oxide, zinc oxide, zinc oxide to which gallium is added, zinc oxide to which aluminum is added, or the like can be used for the second electrode 752.

### <<Alignment Films AF1 and AF2>>

The alignment films AF1 and AF2 can be formed using a material containing polyimide or the like, for example. Specifically, a material formed to have alignment in the predetermined direction by rubbing treatment or an optical alignment technique can be used.

For example, a film containing soluble polyimide can be used for the alignment films AF1 and AF2.

### <<Coloring Film CF1>>

The coloring film CF1 can be formed using a material transmitting light of a predetermined color, and can thus be used as a color filter or the like.

The coloring film CF1 can be formed using a material transmitting light of blue, green, red, yellow, or white, for example.

### <<Light-blocking Film BM>>

A material that prevents light transmission can be used for the light-blocking film BM, in which case the light-blocking film BM serves as a black matrix, for example.

<<Insulating film 771>>

The insulating film 771 can be formed using polyimide, epoxy resin, acrylic resin, or the like.

### <<Functional Film 770P>>

For example, a polarizing plate, a retardation plate, a diffusing film, an anti-reflective film, a condensing film, or the like can be used as the functional film 770P. Alternatively, a polarizing plate containing a dichromatic pigment can be used for the functional film 770P.

Alternatively, an antistatic film preventing the attachment of a foreign substance, a water repellent film suppressing the attachment of stain, a hard coat film suppressing a scratch in use, or the like can be used as the functional film 770P.

<<Second Display Element 550(i,j)>>

A light-emitting element, for example, can be used as the second display element 550(i,j). Specifically, an organic electroluminescence element, an inorganic electroluminescence element, a light-emitting diode, or the like can be used for the second display element 550(i,j).

For example, a stack formed so as to emit blue, green, or red light, or the like can be used for the layer 553(j) containing a light-emitting organic compound.

For example, a belt-like stack that extends in the column direction along the signal line S1(j) can be used for the layer 553(j) containing a light-emitting organic compound. Furthermore, a belt-like stack that extends in the column direction along the signal line S1(j+1) that emits light of a color different from that of light emitted from the layer 553(j) containing a light-emitting organic compound can be used for a layer 553(j+1) containing a light-emitting organic compound.

For example, a stack formed so as to emit white light can be used for the layer 553(j) containing a light-emitting organic compound and the layer 553(j+1) containing a light-emitting organic compound. Specifically, a stack of a layer containing a light-emitting organic compound including a fluorescent material that emits blue light, and a layer containing materials that are other than a fluorescent material and that emit green light and red light or a layer containing a material that is other than a fluorescent material and that emits yellow light can be used for the layer 553(j) containing a light-emitting organic compound and the layer 553(j+1) containing a light-emitting organic compound.

For example, any of the materials that can be used for the wiring or the like can be used for the third electrode 551(i,j) or the fourth electrode 552.

For example, a material that transmits visible light among the materials that can be used for the wiring or the like can be used for the third electrode 551(i,j).

Specifically, conductive oxide, indium-containing conductive oxide, indium oxide, indium tin oxide, indium zinc oxide, zinc oxide, zinc oxide to which gallium is added, or the like can be used for the third electrode 551(i,j). Alternatively, a metal film that is thin enough to transmit light can be used as the third electrode 551(i,j).

For example, a material that reflects visible light among the materials that can be used for the wiring or the like can be used for the fourth electrode 552.

### <<Driver Circuit GD>>

Any of a variety of sequential circuits such as a shift register can be used as the driver circuit GD. For example, the transistor MD, a capacitor, and the like can be used in the driver circuit GD. Specifically, a transistor including a semiconductor film that can be formed in the same step as the transistor M can be used.

As the transistor MD, a transistor different from the transistor that can be used for the switch SW1 can be used. Specifically, a transistor including the conductive film 524 can be used for the transistor MD (see FIG. 2C).

The semiconductor film 508 is provided between the conductive films 524 and 504. The insulating film 516 is provided between the conductive film 524 and the semiconductor film 508. The insulating film 506 is provided between the semiconductor film 508 and the conductive film 504. For example, the conductive film 524 is electrically connected to a wiring that supplies a potential equal to that supplied to the conductive film 504.

Note that the transistor MD can have the same structure as the transistor M.

### <<Driver Circuit SD>>

For example, an integrated circuit can be used as the driver circuit SD. Specifically, an integrated circuit formed on a silicon substrate can be used as the driver circuit SD.

For example, a chip on glass (COG) method can be used to mount the driver circuit SD on a pad electrically connected to the pixel circuit 530(i,j). Specifically, an anisotropic conductive film can be used to mount the integrated circuit on the pad.

Note that the pad can be formed in the same process as the terminal 519B or the terminal 519C.

### <Structure Example 2 of Display Panel>

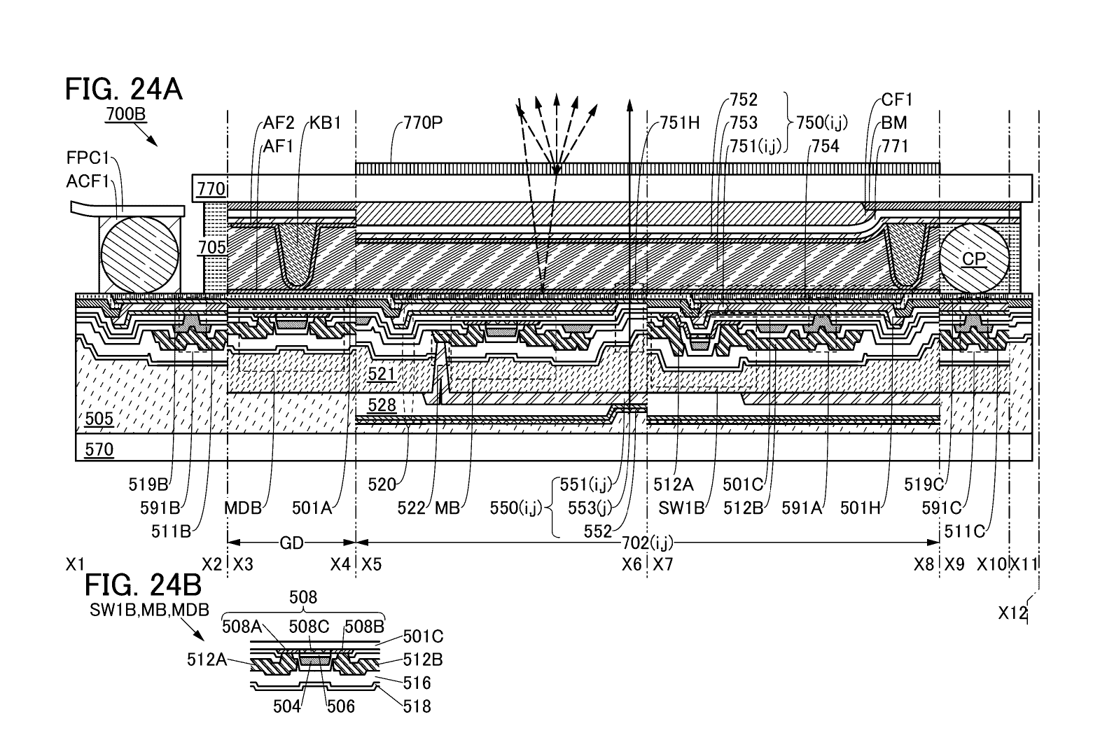

FIGS. 24A and 24B illustrate the structure of the display panel 700B of one embodiment of the present invention. FIG. 24A is a cross-sectional view taken along dashed-dotted lines X1 -X2, X3-X4, X5-X6, X7-X8, X9-X10, and X11-X12 in FIG. 1A. FIG. 24B is a cross-sectional view illustrating the structure of part of the display panel.

The display panel 700B is different from the display panel 700 described with reference to FIGS. 2A to 2C in that it includes a top-gate transistor instead of a bottom-gate transistor. Here, the above description is referred to for the other similar structures, and different structures will be described in detail.

### <<Switch SW1B, Transistor MB, Transistor MDB>>

A transistor that can be used for a switch SW1B, the transistor MB, and the transistor MDB include the conductive film 504 having a region overlapping with the insulating film 501C and the semiconductor film 508 having a region located between the insulating film 501C and the conductive film 504. Note that the conductive film 504 functions as a gate electrode (see FIG. 24B).

The semiconductor film 508 includes a first region 508A, a second region 508B, and a third region 508C. The first region 508A and the second region 508B do not overlap with the conductive film 504. The third region 508C is positioned between the first region 508A and the second region 508B and overlaps with the conductive film 504.

The transistor MDB includes the insulating film 506 between the third region 508C and the conductive film 504. Note that the insulating film 506 functions as a gate insulating film.

The first region 508A and the second region 508B have a lower resistivity than the third region 508C, and function as a source region and a drain region.

Note that, for example, a method for controlling the resistivity of the oxide semiconductor film that is described in the end of this embodiment can be used in forming the first region 508A and the second region 508B in the semiconductor film 508. Specifically, plasma treatment using a gas containing a rare gas can be employed.

For example, the conductive film 504 can be used as a mask. The use of the conductive film 504 as a mask allows the shape of part of the third region 508C to be self-aligned with the shape of an end of the conductive film 504.

The transistor MDB includes the conductive films 512A and 512B which are in contact with the first region 508A and the second region 508B, respectively. The conductive film 512A and the conductive film 512B function as a source electrode and a drain electrode.

A transistor that can be formed in the same process as the transistor MDB can be used as the transistor MB.

### <Structure Example 3 of Display Panel>

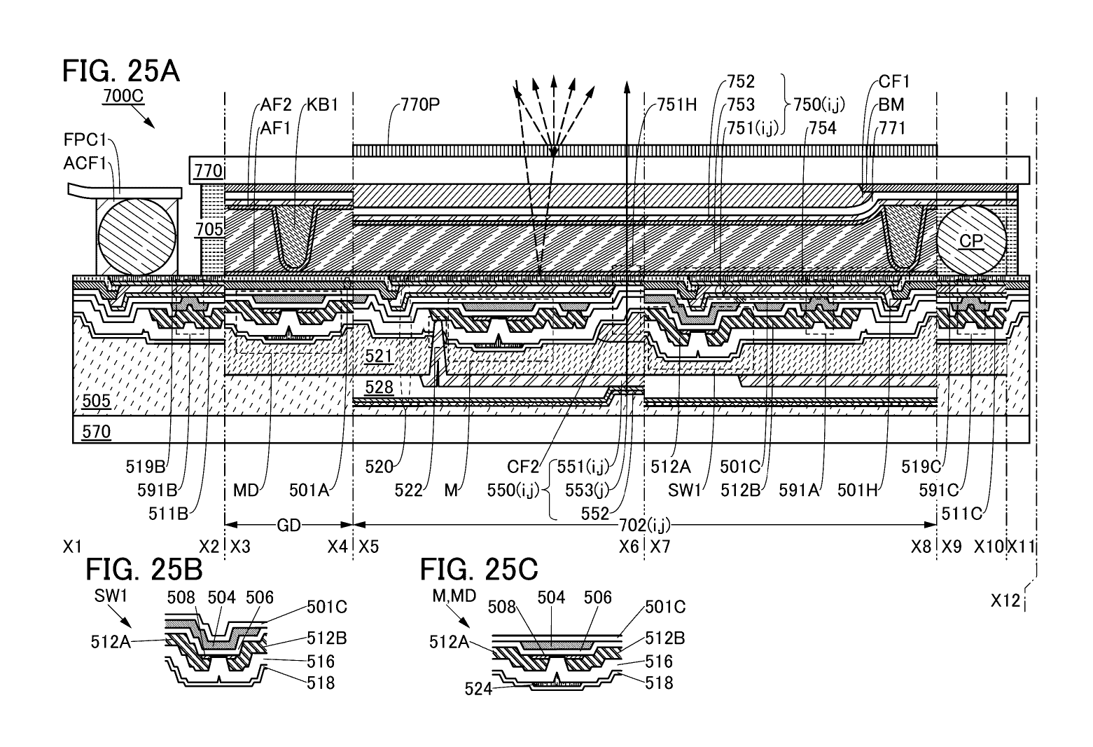

FIGS. 25A to 25C illustrate the structure of the display panel 700C of one embodiment of the present invention. FIG. 25A is a cross-sectional view taken along dashed-dotted lines X1 -X2, X3-X4, X5-X6, X7-X8, X9-X10, and X11-X12 in FIG. 1A. FIGS. 25B and 25C are each a cross-sectional view illustrating the structure of part of the display panel.

Note that the display panel 700C is different from the display panel 700 described with reference to FIGS. 2A to 2C in that the second display element 550(i,j) that emits white light is provided and a coloring film CF2 including a region overlapping with the opening 751H is provided between the second display element 550(i,j) and the insulating film 501C.

In the case where a reflective display element is used as the first display element 750(i,j) together with the coloring film CF1, the first display element 750(i,j) reflects incident light that has passed through the coloring film CF1 such that the light passes through the coloring film CF1 again.

The second display element 550(i,j) emits white light such that it passes through the coloring film CF2 and the coloring film CF1. Note that a material having a function of converting the emitted light into a predetermined color light can be used for the coloring film CF2. Specifically, quantum dots can be used for the coloring film CF2. Thus, display with high color purity can be achieved.

### <Structure Example 4 of Display Panel>

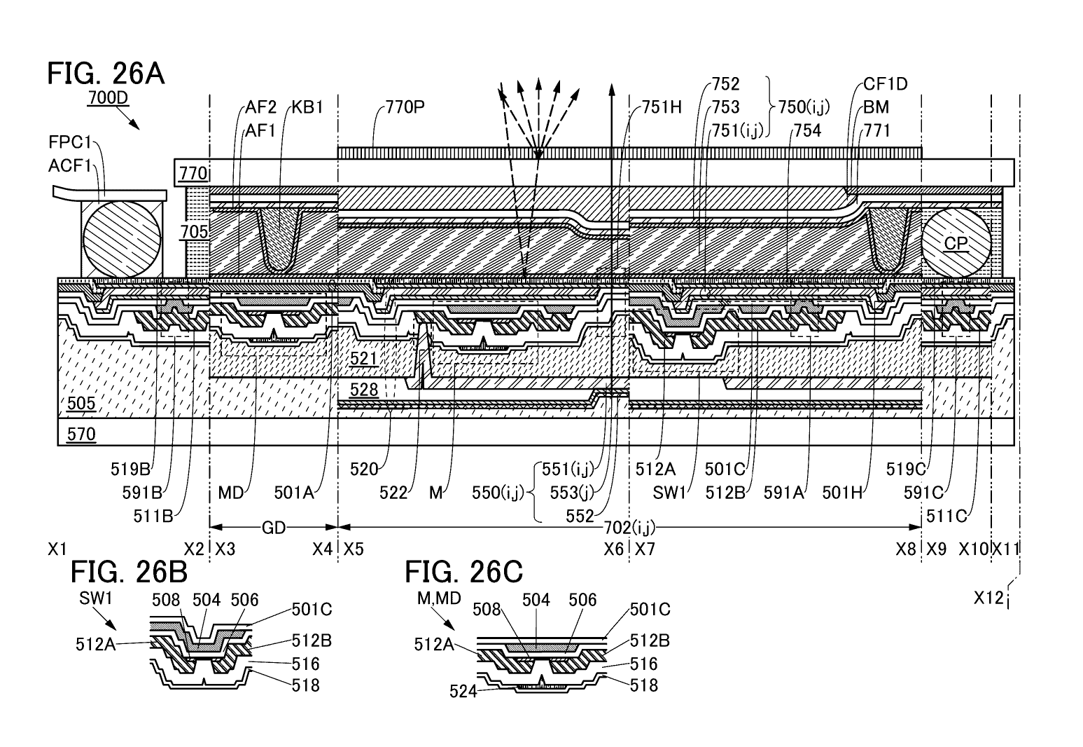

FIGS. 26A to 26C illustrate the structure of the display panel 700D of one embodiment of the present invention. FIG. 26A is a cross-sectional view taken along dashed-dotted lines X1-X2, X3-X4, X5-X6, X7-X8, X9-X10, and X11-X12 in FIG. 1A. FIGS. 26B and 26C are each a cross-sectional view illustrating the structure of part of the display panel.

Note that the display panel 700D is different from the display panel 700 described with reference to FIGS. 2A to 2C in that the first display element 550(i,j) that emits white light is provided and a coloring film CF1D including a thick region overlapping with the opening 751H is provided.

In the case where a reflective display element is used as the first display element 750(i,j) together with the coloring film CF1D, the first display element 750(i,j) reflects incident light that has passed through the coloring film CF1D such that the light passes through the coloring film CF1D again.

Furthermore, the second display element 550(i,j) emits white light such that the light passes through a thick region of the coloring film CF1D.

### <Method for Controlling Resistivity of Oxide Semiconductor Film>

The method for controlling the resistivity of an oxide semiconductor film will be described.

An oxide semiconductor film with a predetermined resistivity can be used for the semiconductor film 508, the conductive film 524, or the like.

For example, a method for controlling the concentration of impurities such as hydrogen and water contained in the oxide semiconductor film and/or the oxygen vacancies in the film can be used as the method for controlling the resistivity of the oxide semiconductor film.

Specifically, plasma treatment can be used as a method for increasing or decreasing the concentration of impurities such as hydrogen and water and/or the oxygen vacancies in the film.

Specifically, plasma treatment using a gas containing one or more kinds selected from a rare gas (He, Ne, Ar, Kr, or Xe), hydrogen, boron, phosphorus, and nitrogen can be employed. For example, plasma treatment in an Ar atmosphere, plasma treatment in a mixed gas atmosphere of Ar and hydrogen, plasma treatment in an ammonia atmosphere, plasma treatment in a mixed gas atmosphere of Ar and ammonia, or plasma treatment in a nitrogen atmosphere can be employed. Thus, the oxide semiconductor film can have a high carrier density and a low resistivity.

Alternatively, hydrogen, boron, phosphorus, or nitrogen is added to the oxide semiconductor film by an ion implantation method, an ion doping method, a plasma immersion ion implantation method, or the like, so that the oxide semiconductor film can have a low resistivity.

Alternatively, an insulating film containing hydrogen is formed in contact with the oxide semiconductor film, and the hydrogen is diffused from the insulating film to the oxide semiconductor film, so that the oxide semiconductor film can have a high carrier density and a low resistivity.

For example, an insulating film with a hydrogen concentration of greater than or equal to 1×10²² atoms/cm³ is formed in contact with the oxide semiconductor film, whereby hydrogen can be effectively supplied to the oxide semiconductor film. Specifically, a silicon nitride film can be used as the insulating film formed in contact with the oxide semiconductor film.

Hydrogen contained in the oxide semiconductor film reacts with oxygen bonded to a metal atom to be water, and an oxygen vacancy is formed in a lattice from which oxygen is released (or a portion from which oxygen is released). Due to entry of hydrogen into the oxygen vacancy, an electron serving as a carrier is generated in some cases. Furthermore, bonding of part of hydrogen to oxygen bonded to a metal atom causes generation of an electron serving as a carrier in some cases. Thus, the oxide semiconductor film can have a high carrier density and a low resistivity.

Specifically, an oxide semiconductor film with a hydrogen concentration measured by secondary ion mass spectrometry (SIMS) of greater than or equal to 8×10¹⁹ atoms/cm³, preferably greater than or equal to 1×10²⁰ atoms/cm³, more preferably greater than or equal to 5×10²° atoms/cm³ can be suitably used as the conductive film 524.

On the other hand, an oxide semiconductor film with a high resistivity can be used for a semiconductor film where a channel of a transistor is formed. Specifically, the oxide semiconductor film can be suitably used for as the semiconductor film 508.

For example, an insulating film containing oxygen, in other words, an insulating film capable of releasing oxygen, is formed in contact with an oxide semiconductor film, and the oxygen is supplied from the insulating film to the oxide semiconductor film, so that oxygen vacancies in the film or at the interface can be filled. Thus, the oxide semiconductor film can have a high resistivity.

For example, a silicon oxide film or a silicon oxynitride film can be used as the insulating film capable of releasing oxygen.

The oxide semiconductor film in which oxygen vacancy is filled with oxygen and the concentration of hydrogen is reduced can be referred to as a highly purified intrinsic or substantially highly purified intrinsic oxide semiconductor film. The term “substantially intrinsic” refers to a state where an oxide semiconductor has a carrier density lower than 8×10¹¹/cm³, preferably lower than 1×10¹¹/cm³, more preferably lower than 1×10¹⁰/cm³. A highly purified intrinsic or substantially highly purified intrinsic oxide semiconductor film has few carrier generation sources, and thus can have a low carrier density. The highly purified intrinsic or substantially highly purified intrinsic oxide semiconductor film has a low density of defect states and accordingly can have a low density of trap states.

Furthermore, a transistor including the highly purified intrinsic or substantially highly purified intrinsic oxide semiconductor film has an extremely low off-state current; even when an element has a channel width of 1×10⁶ μm and a channel length L of 10 μm, the off-state current can be lower than or equal to the measurement limit of a semiconductor parameter analyzer, that is, lower than or equal to 1×10^{—13} A, at a voltage (drain voltage) between a source electrode and a drain electrode of from 1 V to 10 V.

The transistor in which a channel region is formed in the oxide semiconductor film that is a highly purified intrinsic or substantially highly purified intrinsic oxide semiconductor film can have a small change in electrical characteristics and high reliability.

Specifically, an oxide semiconductor film having a hydrogen concentration which is measured by secondary ion mass spectrometry (SIMS) of lower than or equal to 2×10²⁰ atoms/cm³, preferably lower than or equal to 5×10¹⁹ atoms/cm³, more preferably lower than or equal to 1×10¹⁹ atoms/cm³, more preferably lower than 5×10¹⁸ atoms/cm³, more preferably lower than or equal to 1×10¹⁸ atoms/cm³, more preferably lower than or equal to 5×10¹⁷ atoms/cm³, more preferably lower than or equal to 1×10¹⁶ atoms/cm³ can be favorably used for a semiconductor film where a channel of a transistor is formed.

An oxide semiconductor film that has a higher hydrogen concentration and/or a larger number of oxygen vacancies and that has a lower resistivity than the semiconductor film 508 is used as the conductive film 524. A film whose hydrogen concentration is twice or more, preferably ten times or more the hydrogen concentration in the semiconductor film 508 can be used as the conductive film 524.

A film whose resistivity is greater than or equal to 1×10⁻⁸ times and less than 1×10⁻¹ times the resistivity of the semiconductor film 508 can be used as the conductive film 524.

Specifically, a film with a resistivity of greater than or equal to 1×10⁻³ Ωcm and less than 1×10⁴ Ωcm, preferably greater than or equal to 1×10⁻³ Ωcm and less than 1×10⁻¹ Ωcm can be used as the conductive film 524.

This embodiment can be combined with any of the other embodiments in this specification as appropriate.

### Embodiment 2

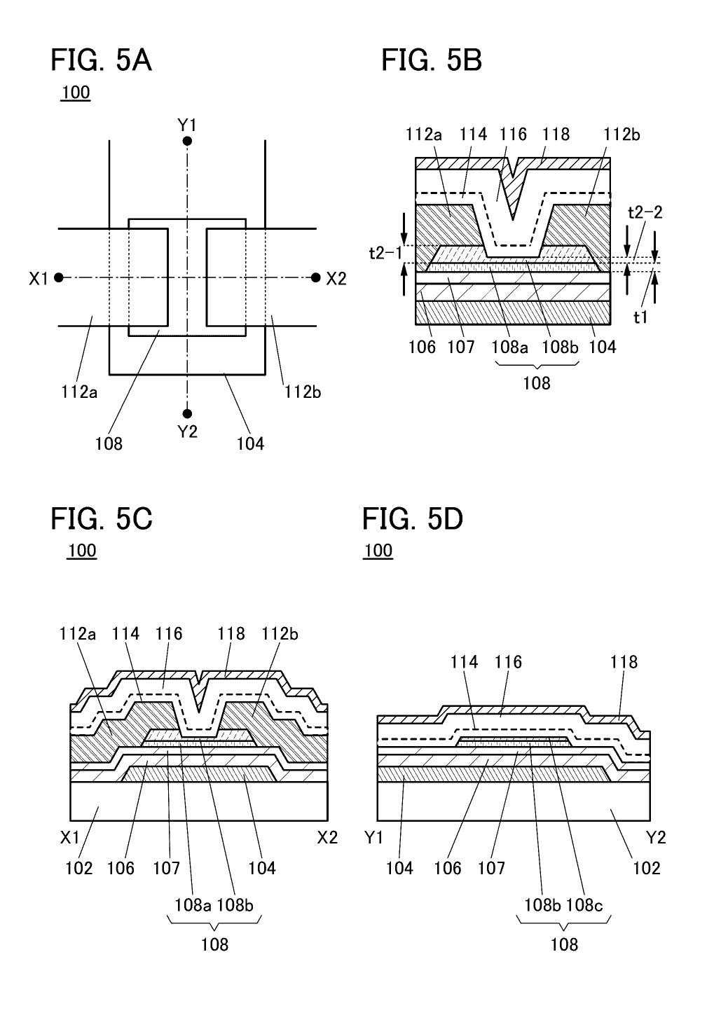

In this embodiment, the structure of a transistor which can be used for the display panel of one embodiment of the present invention will be described with reference to FIGS. 5A to 5D.

### <Structural Example of Semiconductor Device>

FIG. 5A is a top view of the transistor 100. FIG. 5C is a cross-sectional view taken along the section line X1-X2 in FIG. 5A, and FIG. 5D is a cross-sectional view taken along the section line Y1 -Y2 in FIG. 5A. Note that in FIG. 5A, some components of the transistor 100 (e.g., an insulating film serving as a gate insulating film) are not illustrated to avoid complexity. In some cases, the direction of the section line X1X2 is referred to as a channel length direction and the direction of the section line Y1-Y2 is referred to as a channel width direction. As in FIG. 5A, some components might not be illustrated in some top views of transistors described below.

Note that the transistor 100 can be used in the display panel 700 described in Embodiment 1, or the like.

For example, when the transistor 100 is used for the switch SW1, a substrate 102, a conductive film 104, a stacked film of an insulating film 106 and an insulating film 107, an oxide semiconductor film 108, a conductive film 112a, a conductive film 112b, a stacked film of an insulating film 114 and an insulating film 116, and an insulating film 118 can be read as the insulating film 501C, the conductive film 504, the insulating film 506, the semiconductor film 508, the conductive film 512A, the conductive film 512B, the insulating film 516, and the insulating film 518, respectively.

The transistor 100 includes the conductive film 104 functioning as a gate electrode over the substrate 102, the insulating film 106 over the substrate 102 and the conductive film 104, the insulating film 107 over the insulating film 106, the oxide semiconductor film 108 over the insulating film 107, and the conductive films 112a and 112b functioning as source and drain electrodes electrically connected to the oxide semiconductor film 108. Over the transistor 100, specifically, over the conductive films 112a and 112b and the oxide semiconductor film 108, insulating films 114, 116, and 118 are provided. The insulating films 114, 116, and 118 function as protective insulating films for the transistor 100.

The oxide semiconductor film 108 includes an oxide semiconductor film 108a on the side of the conductive film 104 serving as a gate electrode and an oxide semiconductor film 108b over the oxide semiconductor film 108a. Furthermore, the insulating films 106 and 107 function as gate insulating films of the transistor 100.

An In-M oxide (M is Ti, Ga, Sn, Y, Zr, La, Ce, Nd, or Hf) or an In—M—Zn oxide can be used for the oxide semiconductor film 108. It is particularly preferable to use an In—M—Zn oxide for the semiconductor film 108.

The oxide semiconductor film 108a includes a first region in which the atomic proportion of In is larger than the atomic proportion of M. The oxide semiconductor film 108b includes a second region in which the atomic proportion of In is smaller than that in the oxide semiconductor film 108a. The second region includes a portion thinner than the first region.

The oxide semiconductor film 108a including the first region in which the atomic proportion of In is larger than that of M can increase the field-effect mobility (also simply referred to as mobility or μFE) of the transistor 100. Specifically, the field-effect mobility of the transistor 100 can exceed 10 cm²/Vs.

For example, the use of the transistor with high field-effect mobility for a gate driver that generates a gate signal (specifically, a demultiplexer connected to an output terminal of a shift register included in a gate driver) allows a semiconductor device or a display device to have a narrow frame.

On the other hand, the electrical characteristics of the transistor 100 that includes the oxide semiconductor film 108a including the first region in which the atomic proportion of In is larger than that of M are likely to be changed by light irradiation. However, in the semiconductor device of one embodiment of the present invention, the oxide semiconductor film 108b is formed over the oxide semiconductor film 108a. In addition, the thickness of a channel region in the oxide semiconductor film 108b is smaller than the thickness of the oxide semiconductor film 108a.

Furthermore, the oxide semiconductor film 108b includes the second region in which the atomic proportion of In is smaller than that in the oxide semiconductor film 108a and thus has larger Eg than that of the oxide semiconductor film 108a. For this reason, the oxide semiconductor film 108 which has a layered structure of the oxide semiconductor film 108a and the oxide semiconductor film 108b has high resistance to a negative bias stress test with light irradiation.

The amount of light absorbed by the oxide semiconductor film 108 with the above structure during light irradiation can be reduced. As a result, the change in the electrical characteristics of the transistor 100 due to light irradiation can be reduced. In the semiconductor device of one embodiment of the present invention, the insulating film 114 or the insulating film 116 includes excess oxygen. This structure can further reduce the change in the electrical characteristics of the transistor 100 due to light irradiation.

Here, the oxide semiconductor film 108 is described in detail with reference to FIG. 5B.

FIG. 5B is an enlarged cross-sectional view of the oxide semiconductor film 108 and the vicinity thereof in the transistor 100 illustrated in FIG. 5C.

In FIG. 5B, t1, t2-1, and t2-2 denote the thickness of the oxide semiconductor film 108a, one thickness of the oxide semiconductor film 108b, and the other thickness of the oxide semiconductor film 108b, respectively. The oxide semiconductor film 108b over the oxide semiconductor film 108a prevents the oxide semiconductor film 108a from being exposed to an etching gas, an etchant, or the like when the conductive films 112a and 112b are formed. This is why the oxide semiconductor film 108a is not or is hardly reduced in thickness. In contrast, in the oxide semiconductor film 108b, a portion not overlapping with the conductive films 112a and 112b is etched in formation of the conductive films 112a and 112b, so that a depression is formed in the etched region. In other words, the thickness of the oxide semiconductor film 108b in a region overlapping with the conductive films 112a and 112b is t2-1, and the thickness of the oxide semiconductor film 108b in a region not overlapping with the conductive films 112a and 112b is t2-2.

As for the relationships between the thicknesses of the oxide semiconductor film 108a and the oxide semiconductor film 108b, t2-1>t1> t2-2 is preferable. A transistor with the thickness relationships can have high field-effect mobility and less variation in threshold voltage in light irradiation.

When oxygen vacancies are formed in the oxide semiconductor film 108 included in the transistor 100, electrons serving as carriers are generated; as a result, the transistor 100 tends to be normally-on. Therefore, for stable transistor characteristics, it is important to reduce oxygen vacancies in the oxide semiconductor film 108 particularly oxygen vacancies in the oxide semiconductor film 108a. In the structure of the transistor of one embodiment of the present invention, excess oxygen is introduced into an insulating film over the oxide semiconductor film 108, here, the insulating film 114 and/or the insulating film 116 over the oxide semiconductor film 108, whereby oxygen is moved from the insulating film 114 and/or the insulating film 116 to the oxide semiconductor film 108 to fill oxygen vacancies in the oxide semiconductor film 108 particularly in the oxide semiconductor film 108a.

It is preferable that the insulating films 114 and 116 each include a region (oxygen excess region) including oxygen in excess of that in the stoichiometric composition. In other words, the insulating films 114 and 116 are insulating films capable of releasing oxygen. Note that the oxygen excess region is formed in the insulating films 114 and 116 in such a manner that oxygen is introduced into the insulating films 114 and 116 after the deposition, for example. As a method for introducing oxygen, an ion implantation method, an ion doping method, a plasma immersion ion implantation method, plasma treatment, or the like may be employed.

In order to fill oxygen vacancies in the oxide semiconductor film 108a, the thickness of the portion including the channel region and the vicinity of the channel region in the oxide semiconductor film 108b is preferably small, and t2-2< t1 is preferably satisfied. For example, the thickness of the portion including the channel region and the vicinity of the channel region in the oxide semiconductor film 108b is preferably more than or equal to 1 nm and less than or equal to 20 nm, more preferably more than or equal to 3 nm and less than or equal to 10 nm.

Other components of the semiconductor device of this embodiment will be described below in detail.

### <<Substrate>>

There is no particular limitation on the property of a material and the like of the substrate 102 as long as the material has heat resistance enough to withstand at least heat treatment to be performed later. For example, a glass substrate, a ceramic substrate, a quartz substrate, or a sapphire substrate may be used as the substrate 102.

Alternatively, a single crystal semiconductor substrate or a polycrystalline semiconductor substrate of silicon or silicon carbide, a compound semiconductor substrate of silicon germanium, an SOI substrate, or the like can be used as the substrate 102.

Alternatively, any of these substrates provided with a semiconductor element, an insulating film, or the like may be used as the substrate 102.

In the case where a glass substrate is used as the substrate 102, a large substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large display device can be manufactured.

Alternatively, a flexible substrate may be used as the substrate 102, and the transistor 100 may be provided directly on the flexible substrate. Alternatively, a separation layer may be provided between the substrate 102 and the transistor 100. The separation layer can be used when part or the whole of a semiconductor device formed over the separation layer is separated from the substrate 102 and transferred onto another substrate. In such a case, the transistor 100 can also be transferred to a substrate having low heat resistance or a flexible substrate.

### <<Conductive Film Functioning as Gate Electrode and Source and Drain Electrodes>>

The conductive film 104 functioning as a gate electrode and the conductive films 112a and 112b functioning as a source electrode and a drain electrode, respectively, can each be formed using a metal element selected from chromium (Cr), copper (Cu), aluminum (Al), gold (Au), silver (Ag), zinc (Zn), molybdenum (Mo), tantalum (Ta), titanium (Ti), tungsten (W), manganese (Mn), nickel (Ni), iron (Fe), and cobalt (Co); an alloy including any of these metal elements as its component; an alloy including a combination of any of these metal elements; or the like.

Furthermore, the conductive films 104, 112a, and 112b may have a single-layer structure or a layered structure of two or more layers. For example, a single-layer structure of an aluminum film including silicon, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, and a three-layer structure in which a titanium film, an aluminum film, and a titanium film are stacked in this order can be given. Alternatively, an alloy film or a nitride film in which aluminum and one or more elements selected from titanium, tantalum, tungsten, molybdenum, chromium, neodymium, and scandium are combined may be used.

The conductive films 104, 112a, and 112b can be formed using a light-transmitting conductive material such as indium tin oxide, indium oxide including tungsten oxide, indium zinc oxide including tungsten oxide, indium oxide including titanium oxide, indium tin oxide including titanium oxide, indium zinc oxide, or indium tin oxide to which silicon oxide is added.

A Cu—X alloy film (X is Mn, Ni, Cr, Fe, Co, Mo, Ta, or Ti) may be used for the conductive films 104, 112a, and 112b. The use of a Cu—X alloy film enables the manufacturing cost to be reduced because wet etching process can be used in the processing.

### <<Insulating Film Functioning as Gate Insulating Film>>

As each of the insulating films 106 and 107 functioning as a gate insulating film of the transistor 100, an insulating film including at least one of the following films formed by a plasma chemical vapor deposition (CVD) method, a sputtering method, or the like can be used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film. Note that the layered structure of the insulating films 106 and 107 is not necessarily employed, and an insulating film with a single-layer structure selected from the above films or an insulating film of three or more layers may be used.

The insulating film 106 has a function of a blocking film that inhibits penetration of oxygen. For example, in the case where excess oxygen is supplied to the insulating film 107, the insulating film 114, the insulating film 116, and/or the oxide semiconductor film 108, the insulating film 106 can inhibit penetration of oxygen.

Note that the insulating film 107 that is in contact with the oxide semiconductor film 108 functioning as a channel region of the transistor 100 is preferably an oxide insulating film and preferably includes a region including oxygen in excess of that in the stoichiometric composition (an oxygen-excess region). In other words, the insulating film 107 is an insulating film which is capable of releasing oxygen. In order to provide the oxygen-excess region in the insulating film 107, the insulating film 107 is formed in an oxygen atmosphere, for example. Alternatively, the oxygen-excess region may be formed by supplying oxygen to the formed insulating film 107. As a method for supplying oxygen, an ion implantation method, an ion doping method, a plasma immersion ion implantation method, plasma treatment, or the like can be employed.

In the case where hafnium oxide is used for the insulating film 107, the following effect is attained. Hafnium oxide has a higher dielectric constant than silicon oxide and silicon oxynitride. Therefore, the thickness of the insulating film 107 can be made large as compared with the case where silicon oxide is used; as a result, a leakage current due to a tunnel current can be low. That is, it is possible to provide a transistor with a low off-state current. Moreover, hafnium oxide with a crystalline structure has higher dielectric constant than hafnium oxide with an amorphous structure. Therefore, it is preferable to use hafnium oxide with a crystalline structure in order to provide a transistor with a low off-state current. Examples of the crystalline structure include a monoclinic crystal structure and a cubic crystal structure. Note that one embodiment of the present invention is not limited to the above examples.

In this embodiment, a silicon nitride film is formed as the insulating film 106, and a silicon oxide film is formed as the insulating film 107. The silicon nitride film has a higher dielectric constant than a silicon oxide film and needs a larger thickness for capacitance equivalent to that of the silicon oxide film. Thus, when the silicon nitride film is included as the gate insulating film of the transistor 100, the physical thickness of the insulating film can be increased. Therefore, the electrostatic breakdown of the transistor 100 can be prevented by inhibiting a reduction in the withstand voltage of the transistor 100 and improving the withstand voltage of the transistor 100.

### <<Oxide Semiconductor Film>>

The oxide semiconductor film 108 can be formed using the materials described above.

In the case where the oxide semiconductor film 108 includes In-M-Zn oxide, it is preferable that the atomic ratio of metal elements of a sputtering target used for forming the In-M-Zn oxide satisfy In≧M and Zn≧M As the atomic ratio of metal elements of such a sputtering target, In:M:Zn=1:1:1, In:M:Zn=1:1:1.2, In:M:Zn=2:1:3, In:M:Zn=3:1:2, and In:M:Zn=4:2:4.1 are preferable.

In the case where the oxide semiconductor film 108 is formed of In-M-Zn oxide, it is preferable to use a target including polycrystalline In-M-Zn oxide as the sputtering target. The use of the target including polycrystalline In-M-Zn oxide facilitates formation of the oxide semiconductor film 108 having crystallinity. Note that the atomic ratios of metal elements in the formed oxide semiconductor film 108 vary from the above atomic ratio of metal elements of the sputtering target within a range of ±40% as an error. For example, when a sputtering target with an atomic ratio of In to Ga and Zn of 4:2:4.1 is used, the atomic ratio of In to Ga and Zn in the oxide semiconductor film 108 may be 4:2:3 or in the vicinity of 4:2:3.

The oxide semiconductor film 108a can be formed using the sputtering target having an atomic ratio of In:M:Zn=2:1:3, In:M:Zn=3:1:2, or In:M:Zn=4:2:4.1. The oxide semiconductor film 108b can be formed using the sputtering target having an atomic ratio of In:M:Zn=1:1:1 or In:M:Zn=1:1:1.2. Note that the atomic ratio of metal elements in a sputtering target used for forming the oxide semiconductor film 108b does not necessarily satisfy In ≧Zn and Zn≧M, and may satisfy In≧M and Zn<M, such as In:M:Zn=1:3:2.

The energy gap of the oxide semiconductor film 108 is 2 eV or more, preferably 2.5 eV or more, more preferably 3 eV or more. The use of an oxide semiconductor having a wide energy gap can reduce off-state current of the transistor 100. In particular, an oxide semiconductor film having an energy gap more than or equal to 2 eV, preferably more than or equal to 2 eV and less than or equal to 3.0 eV is preferably used as the oxide semiconductor film 108a, and an oxide semiconductor film having an energy gap more than or equal to 2.5 eV and less than or equal to 3.5 eV is preferably used as the oxide semiconductor film 108b. Furthermore, the oxide semiconductor film 108b preferably has a higher energy gap than that of the oxide semiconductor film 108a.

Each thickness of the oxide semiconductor film 108a and the oxide semiconductor film 108b is more than or equal to 3 nm and less than or equal to 200 nm, preferably more than or equal to 3 nm and less than or equal to 100 nm, more preferably more than or equal to 3 nm and less than or equal to 50 nm. Note that the above-described thickness relationships between them are preferably satisfied.

An oxide semiconductor film with a low carrier density is used as the oxide semiconductor film 108b. For example, an oxide semiconductor film whose carrier density is 1×10¹⁷ /cm³ or lower, preferably 1×10¹⁵ /cm³ or lower, more preferably 1×10¹³ /cm³ or lower, much more preferably 1×10¹¹ /cm³ or lower is used as the oxide semiconductor film 108b.

Note that, without limitation to those described above, a material with an appropriate composition may be used according to required semiconductor characteristics and electrical characteristics (e.g., field-effect mobility and threshold voltage) of a transistor. To obtain the required semiconductor characteristics of the transistor, it is preferable that the carrier density, the impurity concentration, the defect density, the atomic ratio between a metal element and oxygen, the interatomic distance, the density, and the like of the oxide semiconductor film 108a and the oxide semiconductor film 108b be set to appropriate values.

Note that it is preferable to use, as the oxide semiconductor film 108a and the oxide semiconductor film 108b, an oxide semiconductor film in which the impurity concentration is low and the density of defect states is low, in which case the transistor can have more excellent electrical characteristics. Here, the state in which the impurity concentration is low and the density of defect states is low (the amount of oxygen vacancies is small) is referred to as “highly purified intrinsic” or “substantially highly purified intrinsic”. A highly purified intrinsic or substantially highly purified intrinsic oxide semiconductor film has few carrier generation sources, and thus can have a low carrier density. Thus, a transistor in which a channel region is formed in the oxide semiconductor film rarely has a negative threshold voltage (is rarely normally on). A highly purified intrinsic or substantially highly purified intrinsic oxide semiconductor film has a low density of defect states and accordingly has few carrier traps in some cases. Further, the highly purified intrinsic or substantially highly purified intrinsic oxide semiconductor film has an extremely low off-state current; even when an element has a channel width of 1×10⁶ ₗam and a channel length of 10 μm, the off-state current can be less than or equal to the measurement limit of a semiconductor parameter analyzer, that is, less than or equal to 1×10^{—13}A, at a voltage (drain voltage) between a source electrode and a drain electrode of from 1 V to 10 V.

Accordingly, the transistor in which the channel region is formed in the highly purified intrinsic or substantially highly purified intrinsic oxide semiconductor film can have a small change in electrical characteristics and high reliability. Charges trapped by the trap states in the oxide semiconductor film take a long time to be released and may behave like fixed charges. Thus, the transistor whose channel region is formed in the oxide semiconductor film having a high density of trap states has unstable electrical characteristics in some cases. As examples of the impurities, hydrogen, nitrogen, alkali metal, alkaline earth metal, and the like are given.

Hydrogen contained in the oxide semiconductor film reacts with oxygen bonded to a metal atom to be water, and also causes an oxygen vacancy in a lattice from which oxygen is released (or a portion from which oxygen is released). Due to entry of hydrogen into the oxygen vacancy, an electron serving as a carrier is generated in some cases. In some cases, bonding of part of hydrogen to oxygen bonded to a metal atom causes generation of an electron serving as a carrier. Thus, a transistor including an oxide semiconductor film which contains hydrogen is likely to be normally on. Accordingly, it is preferable that hydrogen be reduced as much as possible in the oxide semiconductor film 108. Specifically, in the oxide semiconductor film 108, the hydrogen concentration which is measured by SIMS is set to lower than or equal to 2×10²⁰ atoms/cm³, preferably lower than or equal to 5×10¹⁹ atoms/cm³, more preferably lower than or equal to 1×10¹⁹ atoms/cm³, more preferably lower than or equal to 5×10¹⁸ atoms/cm³, more preferably lower than or equal to 1×10¹⁸ atoms/cm³, more preferably lower than or equal to 5×10¹⁷ atoms/cm³, more preferably lower than or equal to 1×10¹⁶ atoms/cm³.

When silicon or carbon that is one of the elements belonging to Group 14 is contained in the oxide semiconductor film 108a, the amount of oxygen vacancies is increased in the oxide semiconductor film 108a, and the oxide semiconductor film 108a becomes n-type. Thus, the concentration of silicon or carbon (the concentration is measured by SIMS) in the oxide semiconductor film 108a or the concentration of silicon or carbon (the concentration is measured by SIMS) in the vicinity of an interface with the oxide semiconductor film 108a is lower than or equal to 2×10¹⁸ atoms/cm³, preferably lower than or equal to 2×10¹⁷ atoms/cm³.

The concentration of alkali metal or alkaline earth metal in the oxide semiconductor film 108a, which is measured by SIMS, is set to lower than or equal to 1×10¹⁸ atoms/cm³, preferably lower than or equal to 2×10¹⁶ atoms/cm³. Alkali metal and alkaline earth metal might generate carriers when bonded to an oxide semiconductor, increasing the off-state current of the transistor. Thus, it is preferred that the concentration of alkali metal or alkaline earth metal in the oxide semiconductor film 108a be reduced.

In addition, when nitrogen is contained in the oxide semiconductor film 108a, electrons serving as carriers are generated to increase the carrier density, so that the oxide semiconductor film 108a easily becomes an n-type film. Thus, a transistor including an oxide semiconductor film that contains nitrogen is likely to be normally on. For this reason, nitrogen in the oxide semiconductor film is preferably reduced as much as possible. The concentration of nitrogen measured by SIMS is preferably set to, for example, lower than or equal to 5×10¹⁸ atoms/cm³.

The oxide semiconductor film 108a and the oxide semiconductor film 108b may each have, for example, a non-single crystal structure. Examples of the non-single crystal structure include a c-axis aligned crystalline oxide semiconductor (CAAC—OS), a polycrystalline structure, a microcrystalline structure, and an amorphous structure. Among the non-single crystal structures, the amorphous structure has the highest density of defect states, whereas CAAC—OS has the lowest density of defect states.

<<Insulating Film functioning as Protective Insulating Film for Transistor>>

The insulating films 114 and 116 each have a function of supplying oxygen to the oxide semiconductor film 108. The insulating film 118 functions as a protective insulating film for the transistor 100. The insulating films 114 and 116 contain oxygen. Furthermore, the insulating film 114 is an insulating film which is permeable to oxygen. Note that the insulating film 114 also functions as a film which relieves damage to the oxide semiconductor film 108 at the time of forming the insulating film 116 in a later step.

Silicon oxide, silicon oxynitride, or the like with a thickness greater than or equal to 5 nm and less than or equal to 150 nm, preferably greater than or equal to 5 nm and less than or equal to 50 nm can be used for the insulating film 114.

It is preferable that the number of defects in the insulating film 114 be small, typically the spin density of a signal that appears at g=2.001 due to a dangling bond of silicon, be lower than or equal to 3×10¹⁷ spins/cm³ by ESR measurement. This is because if the density of defects in the insulating film 114 is high, oxygen is bonded to the defects and the amount of oxygen that passes through the insulating film 114 is decreased.

Note that all oxygen that enters the insulating film 114 from the outside does not move to the outside of the insulating film 114. Some oxygen that enters the insulating film 114 from the outside remains in the insulating film 114. Furthermore, movement of oxygen occurs in the insulating film 114 in some cases in such a manner that oxygen enters the insulating film 114 from the outside and oxygen contained in the insulating film 114 moves to the outside of the insulating film 114. When an oxide insulating film which is permeable to oxygen is formed as the insulating film 114, oxygen released from the insulating film 116 provided over the insulating film 114 can be moved to the oxide semiconductor film 108 through the insulating film 114.

The insulating film 114 can be formed using an oxide insulating film having a low density of states due to nitrogen oxide. Note that the density of states due to nitrogen oxide can be formed between the energy of the valence band maximum (Eᵥ_{_}ₒₛ) and the energy of the conduction band minimum (E_{c}_{_}ₒₛ) of the oxide semiconductor film. A silicon oxynitride film that releases less nitrogen oxide, an aluminum oxynitride film that releases less nitrogen oxide, or the like can be used as the oxide insulating film.

Note that a silicon oxynitride film that releases a small amount of nitrogen oxide is a film of which the amount of released ammonia is larger than the amount of released nitrogen oxide in TDS; the amount of released ammonia is typically greater than or equal to 1×10¹⁸ /cm³ and less than or equal to 5×10¹⁹ /cm³. The amount of released ammonia corresponds to the released amount caused by heat treatment at a film surface temperature higher than or equal to 50° C. and lower than or equal to 650° C., preferably higher than or equal to 50° C. and lower than or equal to 550° C.

Nitrogen oxide (NOₓ; x is greater than 0 and less than or equal to 2, preferably greater than or equal to 1 and less than or equal to 2), typically NO₂ or NO, forms levels in the insulating film 114, for example. The levels are positioned in the energy gap of the oxide semiconductor film 108. Therefore, when nitrogen oxide is diffused to the interface between the insulating film 114 and the oxide semiconductor film 108, an electron is trapped by the level on the insulating film 114 side. As a result, the trapped electron remains in the vicinity of the interface between the insulating film 114 and the oxide semiconductor film 108; thus, the threshold voltage of the transistor is shifted in the positive direction.

Nitrogen oxide reacts with ammonia and oxygen in heat treatment. Since nitrogen oxide contained in the insulating film 114 reacts with ammonia contained in the insulating film 116 in heat treatment, nitrogen oxide contained in the insulating film 114 is reduced. Therefore, an electron is hardly trapped at the interface between the insulating film 114 and the oxide semiconductor film 108.

In a transistor using the oxide insulating film as the insulating film 114, the shift in threshold voltage can be reduced, which leads to a smaller change in electrical characteristics of the transistor.

Note that in an ESR spectrum obtained at 100 K or lower of the insulating film 114, by heat treatment in a manufacturing process of the transistor, typically heat treatment at a temperature higher than or equal to 300° C. and lower than 350° C., a first signal that appears at a g-factor of greater than or equal to 2.037 and less than or equal to 2.039, a second signal that appears at a g-factor of greater than or equal to 2.001 and less than or equal to 2.003, and a third signal that appears at a g-factor of greater than or equal to 1.964 and less than or equal to 1.966 are observed. The split width of the first and second signals and the split width of the second and third signals, which are obtained by ESR measurement using an X-band, are each approximately 5 mT. The sum of the spin densities of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is less than 1×10¹⁸ spins/cm³, typically greater than or equal to 1×10¹⁷ spins/cm³ and less than 1×10¹⁸ spins/cm³.

In the ESR spectrum at 100 K or lower, the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 correspond to signals attributed to nitrogen oxide (NOₓ; x is greater than 0 and less than or equal to 2, preferably greater than or equal to 1 and less than or equal to 2). Typical examples of nitrogen oxide include nitrogen monoxide and nitrogen dioxide. In other words, the smaller the sum of the spin densities of the first signal that appears at a g-factor greater than or equal to 2.037 and less than or equal to 2.039, the second signal that appears at a g-factor greater than or equal to 2.001 and less than or equal to 2.003, and the third signal that appears at a g-factor greater than or equal to 1.964 and less than or equal to 1.966 is, the lower the content of nitrogen oxide in the oxide insulating film is.

The nitrogen concentration of the oxide insulating film measured by SIMS is lower than or equal to 6×10²⁰ atoms/cm³.

The oxide insulating film is formed by a PECVD method at a film surface temperature higher than or equal to 220° C. and lower than or equal to 350° C. using silane and dinitrogen monoxide, whereby a dense and hard film can be formed.

The insulating film 116 is formed using an oxide insulating film whose oxygen content is in excess of that in the stoichiometric composition. Part of oxygen is released from the oxide insulating film whose oxygen content is in excess of that in the stoichiometric composition by heating. The oxide insulating film whose oxygen content is in excess of that in the stoichiometric composition is an oxide insulating film of which the amount of released oxygen converted into oxygen atoms is greater than or equal to 1.0×10¹⁹ atoms/cm³, preferably greater than or equal to 3.0×10²⁰ atoms/cm³ in TDS. Note that the temperature of the film surface in the TDS is preferably higher than or equal to 100° C. and lower than or equal to 700° C., or higher than or equal to 100° C. and lower than or equal to 500° C.

Silicon oxide, silicon oxynitride, or the like with a thickness greater than or equal to 30 nm and less than or equal to 500 nm, preferably greater than or equal to 50 nm and less than or equal to 400 nm can be used for the insulating film 116.

Furthermore, it is preferable that the amount of defects in the insulating film 116 be small, typically the spin density of a signal that appears at g=2.001 due to a dangling bond of silicon, be less than 1.5×10¹⁸ spins/cm³, preferably less than or equal to 1×10¹⁸ spins/cm³ by ESR measurement. Note that the insulating film 116 is provided more apart from the oxide semiconductor film 108 than the insulating film 114 is; thus, the insulating film 116 may have higher defect density than the insulating film 114.

The insulating films 114 and 116 can be formed using insulating films formed of the same kinds of materials; thus, a boundary between the insulating films 114 and 116 cannot be clearly observed in some cases. Thus, in this embodiment, the boundary between the insulating films 114 and 116 is shown by a dashed line. Although a two-layer structure of the insulating films 114 and 116 is described in this embodiment, one embodiment of the present invention is not limited to this. For example, a single-layer structure of the insulating film 114 may be used.

The insulating film 118 contains nitrogen. Alternatively, the insulating film 118 contains nitrogen and silicon. The insulating film 118 has a function of blocking oxygen, hydrogen, water, an alkali metal, an alkaline earth metal, or the like. By providing the insulating film 118, it is possible to prevent outward diffusion of oxygen from the oxide semiconductor film 108, outward diffusion of oxygen contained in the insulating films 114 and 116, and entry of hydrogen, water, or the like into the oxide semiconductor film 108 from the outside. A nitride insulating film, for example, can be used as the insulating film 118. The nitride insulating film is formed using silicon nitride, silicon nitride oxide, aluminum nitride, aluminum nitride oxide, or the like. Note that instead of the nitride insulating film having a blocking effect against oxygen, hydrogen, water, alkali metal, alkaline earth metal, and the like, an oxide insulating film having a blocking effect against oxygen, hydrogen, water, and the like, may be provided. As the oxide insulating film having a blocking effect against oxygen, hydrogen, water, and the like, an aluminum oxide film, an aluminum oxynitride film, a gallium oxide film, a gallium oxynitride film, an yttrium oxide film, an yttrium oxynitride film, a hafnium oxide film, and a hafnium oxynitride film can be given.

Although the variety of films such as the conductive films, the insulating films, and the oxide semiconductor films which are described above can be formed by a sputtering method or a PECVD method, such films may be formed by another method, e.g., a thermal CVD method. Examples of a thermal CVD method include a metal organic chemical vapor deposition (MOCVD) method and an atomic layer deposition (ALD) method.

A thermal CVD method has an advantage that no defect due to plasma damage is generated because it does not utilize plasma for forming a film.

Deposition by a thermal CVD method may be performed in such a manner that the pressure in a chamber is set to an atmospheric pressure or a reduced pressure, and a source gas and an oxidizer are supplied to the chamber at a time and react with each other in the vicinity of the substrate or over the substrate.

Deposition by an ALD method may be performed in such a manner that the pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves). In such a case, a first source gas is introduced, an inert gas (e.g., argon or nitrogen) or the like is introduced at the same time or after the first source gas is introduced such that the source gases are not mixed, and then a second source gas is introduced. Note that in the case where the first source gas and the inert gas are introduced at a time, the inert gas serves as a carrier gas, and the inert gas may also be introduced at the same time as the second source gas. Alternatively, the first source gas may be exhausted by vacuum evacuation instead of the introduction of the inert gas, and then the second source gas may be introduced. The first source gas is adsorbed on the surface of the substrate to form a first single-atomic layer; then the second source gas is introduced to react with the first single-atomic layer; as a result, a second single-atomic layer is stacked over the first single-atomic layer, so that a thin film is formed. The sequence of the gas introduction is repeated more than once until a desired thickness is obtained, whereby a thin film with excellent step coverage can be formed. The thickness of the thin film can be adjusted by the number of repetition times of the sequence of the gas introduction; therefore, an ALD method makes it possible to accurately adjust a thickness and thus is suitable for manufacturing a minute FET.

The variety of films such as the conductive films, the insulating films, the oxide semiconductor films, and the metal oxide films in this embodiment can be formed by a thermal CVD method such as an MOCVD method or an ALD method. For example, trimethylindium, trimethylgallium, and dimethylzinc are used to form an In—Ga—ZnO film. Note that the chemical formula of trimethylindium is In(CH₃)₃. The chemical formula of trimethylgallium is Ga(CH₃)3. The chemical formula of dimethylzinc is Zn(CH₃)₂. Without limitation to the above combination, triethylgallium (chemical formula: Ga(C₂H₅)₃) can be used instead of trimethylgallium, and diethylzinc (chemical formula: Zn(C₂H₅)₂) can be used instead of dimethylzinc.

For example, in the case where a hafnium oxide film is formed by a deposition apparatus using ALD, two kinds of gases, i.e., ozone (O₃) as an oxidizer and a source gas that is obtained by vaporizing liquid containing a solvent and a hafnium precursor compound (hafnium alkoxide or hafnium amide such as tetrakis(dimethylamide)hafnium (TDMAH)), are used. Note that the chemical formula of tetrakis(dimethylamide)hafnium is Hf[N(CH₃)₂]₄. Examples of another material liquid include tetrakis(ethylmethylamide)hafnium.

For example, in the case where an aluminum oxide film is formed by a deposition apparatus using ALD, two kinds of gases, i.e., H₂O as an oxidizer and a source gas that is obtained by vaporizing liquid containing a solvent and an aluminum precursor compound (e.g., trimethylaluminum (TMA)) are used. Note that the chemical formula of trimethylaluminum is Al(CH₃)₃. Examples of another material liquid include tris(dimethylamide)aluminum, triisobutylaluminum, and aluminum tris(2,2,6,6-tetramethyl-3,5-heptanedionate).

For example, in the case where a silicon oxide film is formed by a deposition apparatus using ALD, hexachlorodisilane is adsorbed on a deposition surface, chlorine contained in adsorbate is removed, and radicals of an oxidizing gas (e.g., O₂ or dinitrogen monoxide) are supplied to react with the adsorbate.

For example, in the case where a tungsten film is formed using a deposition apparatus using ALD, a WF₆ gas and a B₂H₆ gas are sequentially introduced plural times to form an initial tungsten film, and then a WF₆ gas and an H₂ gas are used, so that a tungsten film is formed. Note that a SiH₄ gas may be used instead of a B₂H₆ gas.

For example, in the case where an oxide semiconductor film, e.g., an In—Ga—ZnO film is formed using a deposition apparatus using ALD, an In(CH₃)₃ gas and an O₃ gas are sequentially introduced plural times to form an InO layer, a GaO layer is formed using a Ga(CH₃)₃ gas and an O₃ gas, and then a ZnO layer is formed using a Zn(CH₃)₂ gas and an O₃ gas. Note that the order of these layers is not limited to this example. A mixed compound layer such as an In—Ga—O layer, an In—Zn—O layer, or a Ga—Zn—O layer may be formed by mixing these gases. Note that although an H₂O gas that is obtained by bubbling with an inert gas such as Ar may be used instead of an O₃ gas, it is preferable to use an O₃ gas that does not contain H. Instead of an In(CH₃)₃ gas, an In(C₂H₅)₃ gas may be used.e Instead of a Ga(CH₃)₃ gas, a Ga(C₂H₅)₃ gas may be used. Alternatively, a Zn (CH₃)₂ gas may be used.

This embodiment can be combined with any of the other embodiments in this specification as appropriate.

### Embodiment 3

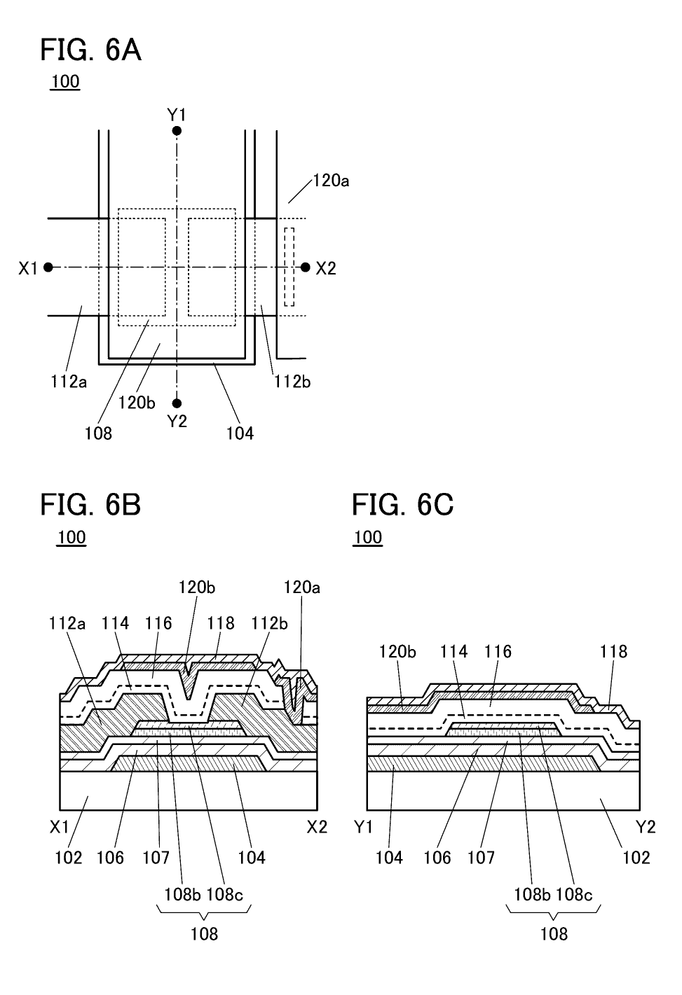

In this embodiment, the structure of a transistor that can be used in the display panel of one embodiment of the present invention will be described with reference to FIGS. 6A to 6C.

### <Structure Example of Semiconductor Device>

FIG. 6A is a top view of the transistor 100. FIG. 6B is a cross-sectional view taken along the section line X1-X2 in FIG. 6A, and FIG. 6C is a cross-sectional view taken along the section line Y1-Y2 in FIG. 6A. Note that in FIG. 6A, some components of the transistor 100 (e.g., an insulating film serving as a gate insulating film) are not illustrated to avoid complexity. Furthermore, the direction of the section line X1-X2 may be called the channel length direction, and the direction of the section line Y1-Y2 may be called the channel width direction. As in FIG. 6A, some components are not illustrated in some cases in top views of transistors described below.

The transistor 100 can be used for the display panel 700 described in Embodiment 1, or the like.

For example, when the transistor 100 is used as the transistor M or the transistor MD, the substrate 102, the conductive film 104, a stacked film of the insulating film 106 and the insulating film 107, the oxide semiconductor film 108, the conductive film 112a, the conductive film 112b, a stacked film of the insulating film 114 and the insulating film 116, the insulating film 118, and a conductive film 120b can be read as the insulating film 501C, the conductive film 504, the insulating film 506, the semiconductor film 508, the conductive film 512A, the conductive film 512B, the insulating film 516, the insulating film 518, and the conductive film 524, respectively.

The transistor 100 includes the conductive film 104 functioning as a first gate electrode over the substrate 102, the insulating film 106 over the substrate 102 and the conductive film 104, the insulating film 107 over the insulating film 106, the oxide semiconductor film 108 over the insulating film 107, and the conductive films 112a and 112b functioning as source and drain electrodes electrically connected to the oxide semiconductor film 108, the insulating films 114 and 116 over the oxide semiconductor film 108 and the conductive films 112a and 112b, a conductive film 120a that is over the insulating film 116 and electrically connected to the conductive film 112b, the conductive film 120b over the insulating film 116, and the insulating film 118 over the insulating film 116 and the conductive films 120a and 120b.

The insulating films 106 and 107 function as a first gate insulating film of the transistor 100. The insulating films 114 and 116 function as a second gate insulating film of the transistor 100. The insulating film 118 functions as a protective insulating film for the transistor 100. In this specification and the like, the insulating films 106 and 107 are collectively referred to as a first insulating film, the insulating films 114 and 116 are collectively referred to as a second insulating film, and the insulating film 118 is referred to as a third insulating film in some cases.

The conductive film 120b can be used as a second gate electrode of the transistor 100.

In the case where the transistor 100 is used in a pixel portion of a display panel, the conductive film 120a can be used as an electrode of a display element, or the like.

The oxide semiconductor film 108 includes the oxide semiconductor film 108b (on the conductive film 104 side) that functions as a first gate electrode, and an oxide semiconductor film 108c over the oxide semiconductor film 108b. The oxide semiconductor films 108b and 108c contain In, M (M is Al, Ga, Y, or Sn), and Zn.

The oxide semiconductor film 108b preferably includes a region in which the atomic proportion of In is larger than the atomic proportion of M, for example. The oxide semiconductor film 108c preferably includes a region in which the atomic proportion of In is smaller than that in the oxide semiconductor film 108b.

The oxide semiconductor film 108b including the region in which the atomic proportion of In is larger than that of M can increase the field-effect mobility (also simply referred to as mobility or μFE) of the transistor 100. Specifically, the field-effect mobility of the transistor 100 can exceed 10 cm²/Vs, preferably 30 cm²/Vs.

For example, the use of the transistor with high field-effect mobility for a gate driver that generates a gate signal (specifically, a demultiplexer connected to an output terminal of a shift register included in a gate driver) allows a semiconductor device or a display device to have a narrow frame.

On the other hand, the electrical characteristics of the transistor 100 including the oxide semiconductor film 108b that includes the region in which the atomic proportion of In is larger than that of M are likely to be changed by light irradiation. However, in the semiconductor device of one embodiment of the present invention, the oxide semiconductor film 108c is formed over the oxide semiconductor film 108b. Furthermore, the oxide semiconductor film 108c including the region in which the atomic proportion of In is smaller than that in the oxide semiconductor film 108b has larger Eg than the oxide semiconductor film 108b. For this reason, the oxide semiconductor film 108 which is a layered structure of the oxide semiconductor film 108b and the oxide semiconductor film 108c has high resistance to a negative bias stress test with light irradiation.

Impurities such as hydrogen or moisture that enter the channel region of the oxide semiconductor film 108, particularly the oxide semiconductor film 108b adversely affect the transistor characteristics and therefore cause a problem. Moreover, it is preferable that the amount of impurities such as hydrogen or moisture in the channel region of the oxide semiconductor film 108b be as small as possible. Furthermore, oxygen vacancies formed in the channel region in the oxide semiconductor film 108b adversely affect the transistor characteristics and therefore cause a problem. For example, oxygen vacancies formed in the channel region in the oxide semiconductor film 108b are bonded to hydrogen to serve as a carrier supply source. The carrier supply source generated in the channel region in the oxide semiconductor film 108b causes a change in the electrical characteristics, typically, shift in the threshold voltage, of the transistor 100 including the oxide semiconductor film 108b. Therefore, it is preferable that the amount of oxygen vacancies in the channel region of the oxide semiconductor film 108b be as small as possible.

In view of this, one embodiment of the present invention is a structure in which insulating films in contact with the oxide semiconductor film 108, specifically the insulating film 107 formed under the oxide semiconductor film 108 and the insulating films 114 and 116 formed over the oxide semiconductor film 108 include excess oxygen. Oxygen or excess oxygen is transferred from the insulating film 107 and the insulating films 114 and 116 to the oxide semiconductor film 108, whereby the oxygen vacancies in the oxide semiconductor film can be reduced. As a result, a change in the electrical characteristics of the transistor 100, particularly a change in the transistor 100 due to light irradiation, can be reduced.

In one embodiment of the present invention, a manufacturing method is used in which the number of manufacturing steps is not increased or an increase in the number of manufacturing steps is extremely small, because the insulating film 107 and the insulating films 114 and 116 are made to contain excess oxygen. Thus, the transistors 100 can be manufactured with high yield.

Specifically, in a step of forming the oxide semiconductor film 108b, the oxide semiconductor film 108b is formed by a sputtering method in an atmosphere containing an oxygen gas, whereby oxygen or excess oxygen is added to the insulating film 107 over which the oxide semiconductor film 108b is formed.

Furthermore, in a step of forming the conductive films 120a and 120b, the conductive films 120a and 120b are formed by a sputtering method in an atmosphere containing an oxygen gas, whereby oxygen or excess oxygen is added to the insulating film 116 over which the conductive films 120a and 120b are formed. Note that in some cases, oxygen or excess oxygen is added also to the insulating film 114 and the oxide semiconductor film 108 under the insulating film 116 when oxygen or excess oxygen is added to the insulating film 116.

### <Oxide Conductor>

Next, an oxide conductor will be described. In a step of forming the conductive films 120a and 120b, the conductive films 120a and 120b serve as protective films for suppressing release of oxygen from the insulating films 114 and 116. The conductive films 120a and 120b serve as semiconductors before a step of forming the insulating film 118 and serve as conductors after the step of forming the insulating film 118.

To allow the conductive films 120a and 120b to serve as conductors, oxygen vacancies are formed in the conductive films 120a and 120b and hydrogen is added from the insulating film 118 to the oxygen vacancies, whereby a donor level is formed in the vicinity of the conduction band. As a result, the conductivity of each of the conductive films 120a and 120b is increased, so that the conductive films 120a and 120b become conductors. The conductive films 120a and 120b having become conductors can each be referred to as an oxide conductor. Oxide semiconductors generally have a visible light transmitting property because of their large energy gap. An oxide conductor is an oxide semiconductor having a donor level in the vicinity of the conduction band. Therefore, the influence of absorption due to the donor level is small in an oxide conductor, and an oxide conductor has a visible light transmitting property comparable to that of an oxide semiconductor.

### <Components of Semiconductor Device>

Components of the semiconductor device of this embodiment will be described below in detail.

As materials described below, the materials described in Embodiment 2 can be used. The material that can be used for the substrate 102 described in Embodiment 2 can be used for the substrate 102. Furthermore, the materials that can be used for the insulating films 106 and 107 described in Embodiment 2 can be used for the insulating films 106 and 107.

In addition, the materials that can be used for the conductive films functioning as the gate electrode, the source electrode, and the drain electrode described in Embodiment 2 can be used for the conductive films functioning as the first gate electrode, the source electrode, and the drain electrode.

### <<Oxide Semiconductor Film>>

The oxide semiconductor film 108 can be formed using any of the materials described above.

In the case where the oxide semiconductor film 108b includes In-M-Zn oxide, it is preferable that the atomic ratio of metal elements of a sputtering target used for forming the In-M-Zn oxide satisfy In>M. The atomic ratio of metal elements of such a sputtering target is, for example, In:M:Zn=2:1:3, In:M:Zn=3:1:2, or In:M:Zn=4:2:4.1.

In the case where the oxide semiconductor film 108c is In-M-Zn oxide, it is preferable that the atomic ratio of metal elements of a sputtering target used for forming a film of the In-M-Zn oxide satisfy In M. The atomic ratio of metal elements of such a sputtering target is, for example, In:M:Zn=1:1:1, In:M:Zn=1:1:1.2, In:M:Zn=1:3:2, In:M:Zn=1:3:4, In:M:Zn=1:3:6, or In:M:Zn=1:4:5.

In the case where the oxide semiconductor films 108b and 108c are formed of In-M-Zn oxide, it is preferable to use a target including polycrystalline In-M-Zn oxide as the sputtering target. The use of the target including polycrystalline In-M-Zn oxide facilitates formation of the oxide semiconductor films 108b and 108c having crystallinity. Note that the atomic ratio of metal elements in each of the formed oxide semiconductor films 108b and 108c varies from the above atomic ratio of metal elements of the sputtering target within a range of ±40% as an error. For example, when a sputtering target of the oxide semiconductor film 108b with an atomic ratio of In to Ga and Zn of 4:2:4.1 is used, the atomic ratio of In to Ga and Zn in the oxide semiconductor film 108b may be 4:2:3 or in the neighborhood of 4:2:3.

The energy gap of the oxide semiconductor film 108 is 2 eV or more, preferably 2.5 eV or more, more preferably 3 eV or more. The use of an oxide semiconductor having a wide energy gap can reduce off-state current of the transistor 100. In particular, an oxide semiconductor film having an energy gap more than or equal to 2 eV, preferably more than or equal to 2 eV and less than or equal to 3.0 eV is preferably used as the oxide semiconductor film 108b, and an oxide semiconductor film having an energy gap more than or equal to 2.5 eV and less than or equal to 3.5 eV is preferably used as the oxide semiconductor film 108c. Furthermore, the oxide semiconductor film 108c preferably has a larger energy gap than the oxide semiconductor film 108b.

The thickness of each of the oxide semiconductor film 108b and the oxide semiconductor film 108c is greater than or equal to 3 nm and less than or equal to 200 nm, preferably greater than or equal to 3 nm and less than or equal to 100 nm, more preferably greater than or equal to 3 nm and less than or equal to 50 nm.

An oxide semiconductor film with a low carrier density is used as the oxide semiconductor film 108c. For example, the carrier density of the oxide semiconductor film 108c is 1×10¹⁷ /cm³ or lower, preferably 1×10¹⁵ /cm³ or lower, more preferably 1×10¹³ /cm³ or lower, much more preferably 1×10¹¹ /cm³ or lower.

Note that, without limitation to those described above, a material with an appropriate composition may be used according to required semiconductor characteristics and electrical characteristics (e.g., field-effect mobility and threshold voltage) of a transistor. To obtain the required semiconductor characteristics of the transistor, it is preferable that the carrier density, the impurity concentration, the defect density, the atomic ratio between a metal element and oxygen, the interatomic distance, the density, and the like of each of the oxide semiconductor film 108b and the oxide semiconductor film 108c be set to appropriate values.

Note that it is preferable to use, as the oxide semiconductor film 108b and the oxide semiconductor film 108c, an oxide semiconductor film in which the impurity concentration is low and the density of defect states is low, in which case the transistor can have more excellent electrical characteristics. Here, the state in which the impurity concentration is low and the density of defect states is low (the amount of oxygen vacancies is small) is referred to as “highly purified intrinsic” or “substantially highly purified intrinsic”. A highly purified intrinsic or substantially highly purified intrinsic oxide semiconductor film has few carrier generation sources, and thus can have a low carrier density. Thus, a transistor in which a channel region is formed in the oxide semiconductor film rarely has a negative threshold voltage (is rarely normally on). A highly purified intrinsic or substantially highly purified intrinsic oxide semiconductor film has a low density of defect states and accordingly has a low density of trap states in some cases. Furthermore, the highly purified intrinsic or substantially highly purified intrinsic oxide semiconductor film has an extremely low off-state current; even when an element has a channel width of 1×10^{6 μ}m and a channel length of 10 μm, the off-state current can be less than or equal to the measurement limit of a semiconductor parameter analyzer, that is, less than or equal to 1×10⁻¹³ A, at a voltage (drain voltage) between a source electrode and a drain electrode of from 1 V to 10 V.

Accordingly, the transistor in which the channel region is formed in the highly purified intrinsic or substantially highly purified intrinsic oxide semiconductor film can have a small change in electrical characteristics and high reliability. Charges trapped by the trap states in the oxide semiconductor film take a long time to be released and may behave like fixed charges. Thus, the transistor whose channel region is formed in the oxide semiconductor film having a high density of trap states has unstable electrical characteristics in some cases. As examples of the impurities, hydrogen, nitrogen, alkali metal, and alkaline earth metal are given.

Hydrogen included in the oxide semiconductor film reacts with oxygen bonded to a metal atom to be water, and also causes oxygen vacancy in a lattice from which oxygen is released (or a portion from which oxygen is released). Due to entry of hydrogen into the oxygen vacancy, an electron serving as a carrier is generated in some cases. Furthermore, in some cases, bonding of part of hydrogen to oxygen bonded to a metal atom causes generation of an electron serving as a carrier. Thus, a transistor including an oxide semiconductor film which contains hydrogen is likely to be normally on. Accordingly, it is preferable that hydrogen be reduced as much as possible in the oxide semiconductor film 108. Specifically, in the oxide semiconductor film 108, the concentration of hydrogen which is measured by SIMS is lower than or equal to 2×10²⁰ atoms/cm³, preferably lower than or equal to 5×10¹⁹ atoms/cm³, more preferably lower than or equal to 1×10¹⁹ atoms/cm³, more preferably lower than or equal to 5×10¹⁸ atoms/cm³, more preferably lower than or equal to 1×10¹⁸ atoms/cm³, more preferably lower than or equal to 5×10¹⁷ atoms/cm³, and more preferably lower than or equal to 1×10¹⁶ atoms/cm³.

The oxide semiconductor film 108b preferably includes a region in which the hydrogen concentration is smaller than that in the oxide semiconductor film 108c. A semiconductor device including the oxide semiconductor film 108b having the region in which the hydrogen concentration is smaller than that in the oxide semiconductor film 108c can have high reliability.

When silicon or carbon that is one of the elements belonging to Group 14 is contained in the oxide semiconductor film 108b, the amount of oxygen vacancies is increased in the oxide semiconductor film 108b, and the oxide semiconductor film 108b becomes n-type. Thus, the concentration of silicon or carbon (the concentration is measured by SIMS) in the oxide semiconductor film 108b or the concentration of silicon or carbon (the concentration is measured by SIMS) in the vicinity of an interface with the oxide semiconductor film 108b is set to be lower than or equal to 2×10¹⁸ atoms/cm³, preferably lower than or equal to 2×10¹⁷ atoms/cm³.

The concentration of alkali metal or alkaline earth metal in the oxide semiconductor film 108b, which is measured by SIMS, is set to lower than or equal to 1×10¹⁸ atoms/cm³, preferably lower than or equal to 2×10¹⁶ atoms/cm³. Alkali metal and alkaline earth metal might generate carriers when bonded to an oxide semiconductor, increasing the off-state current of the transistor. Thus, it is preferred that the concentration of alkali metal or alkaline earth metal in the oxide semiconductor film 108b be reduced.

In addition, when nitrogen is contained in the oxide semiconductor film 108b, electrons serving as carriers are generated to increase the carrier density, so that the oxide semiconductor film 108b easily becomes an n-type film. Thus, a transistor including an oxide semiconductor that contains nitrogen is likely to be normally on. For this reason, nitrogen in the oxide semiconductor film is preferably reduced as much as possible. The concentration of nitrogen measured by SIMS is preferably set to, for example, lower than or equal to 5×10¹⁸ atoms/cm³.

The oxide semiconductor film 108b and the oxide semiconductor film 108c may each have, for example, a non-single crystal structure. Examples of the non-single crystal structure include a c-axis aligned crystalline oxide semiconductor (CAAC—OS), a polycrystalline structure, a microcrystalline structure, and an amorphous structure. Among the non-single crystal structures, the amorphous structure has the highest density of defect states, whereas CAAC—OS has the lowest density of defect states.

### <<Insulating Films Functioning as Second Gate Insulating Film>>

The insulating films 114 and 116 function as a second gate insulating film of the transistor 100. In addition, the insulating films 114 and 116 each have a function of supplying oxygen to the oxide semiconductor film 108. That is, the insulating films 114 and 116 contain oxygen. Furthermore, the insulating film 114 is an insulating film which is permeable to oxygen. Note that the insulating film 114 also functions as a film which relieves damage to the oxide semiconductor film 108 at the time of forming the insulating film 116 in a later step.

For example, the insulating films 114 and 116 described in Embodiment 2 can be used as the insulating films 114 and 116.

### <<Oxide Semiconductor Film Functioning as Conductive Film, Oxide Semiconductor Film Functioning as Second Gate Electrode>>

The material of the oxide semiconductor film 108 described above can be used for the conductive film 120a functioning as a conductive film and the conductive film 120b functioning as the second gate electrode.

That is, the conductive film 120a and the conductive film 120b functioning as a second gate electrode contain a metal element which is the same as that contained in the oxide semiconductor film 108 (the oxide semiconductor film 108b and the oxide semiconductor film 108c). For example, the conductive film 120b functioning as a second gate electrode and the oxide semiconductor film 108 (the oxide semiconductor film 108b and the oxide semiconductor film 108c) contain the same metal element; thus, the manufacturing cost can be reduced.

For example, in the case where the conductive film 120a functioning as a conductive film and the conductive film 120b functioning as a second gate electrode are each In-M-Zn oxide, the atomic ratio of metal elements in a sputtering target used for forming the In-M-Zn oxide preferably satisfies In≧M. The atomic ratio of metal elements in such a sputtering target is In:M:Zn=2:1:3, In:M:Zn=3:1:2, In:M:Zn=4:2:4.1, or the like.

The conductive film 120a functioning as a conductive film and the conductive film 120b functioning as a second gate electrode can each have a single-layer structure or a layered structure of two or more layers. Note that in the case where the conductive film 120a and the conductive film 120b each have a layered structure, the composition of the sputtering target is not limited to that described above.

### <<Insulating Film Functioning as Protective Insulating Film for Transistor>>

The insulating film 118 serves as a protective insulating film for the transistor 100.

The insulating film 118 includes one or both of hydrogen and nitrogen. Alternatively, the insulating film 118 includes nitrogen and silicon. The insulating film 118 has a function of blocking oxygen, hydrogen, water, alkali metal, alkaline earth metal, or the like. It is possible to prevent outward diffusion of oxygen from the oxide semiconductor film 108, outward diffusion of oxygen included in the insulating films 114 and 116, and entry of hydrogen, water, or the like into the oxide semiconductor film 108 from the outside by providing the insulating film 118.

The insulating film 118 has a function of supplying one or both of hydrogen and nitrogen to the conductive film 120a functioning as a conductive film and the conductive film 120b functioning as a second gate electrode. The insulating film 118 preferably includes hydrogen and has a function of supplying the hydrogen to the conductive films 120a and 120b. The conductive films 120a and 120b supplied with hydrogen from the insulating film 118 function as conductors.

A nitride insulating film, for example, can be used as the insulating film 118. The nitride insulating film is formed using silicon nitride, silicon nitride oxide, aluminum nitride, aluminum nitride oxide, or the like.

Although the variety of films such as the conductive films, the insulating films, and the oxide semiconductor films which are described above can be formed by a sputtering method or a PECVD method, such films may be formed by another method, e.g., a thermal CVD method. Examples of a thermal CVD method include an MOCVD method and an ALD method.

A thermal CVD method has an advantage that no defect due to plasma damage is generated because it does not utilize plasma for forming a film.

Deposition by a thermal CVD method may be performed in such a manner that a source gas and an oxidizer are supplied to the chamber at a time while the pressure in the chamber is set to an atmospheric pressure or a reduced pressure, and the source gas and the oxidizer react with each other in the vicinity of the substrate or over the substrate.

Deposition by an ALD method may be performed in such a manner that the pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves). In such a case, a first source gas is introduced, an inert gas (e.g., argon or nitrogen) or the like is introduced at the same time or after the first source gas is introduced such that the source gases are not mixed, and then a second source gas is introduced. Note that in the case where the first source gas and the inert gas are introduced at a time, the inert gas serves as a carrier gas, and the inert gas may also be introduced at the same time as the second source gas. Alternatively, the first source gas may be exhausted by vacuum evacuation instead of the introduction of the inert gas, and then the second source gas may be introduced. The first source gas is adsorbed on the surface of the substrate to form a first layer; then the second source gas is introduced to react with the first layer; as a result, a second layer is stacked over the first layer, so that a thin film is formed. The sequence of the gas introduction is repeated more than once until a desired thickness is obtained, whereby a thin film with excellent step coverage can be formed. The thickness of the thin film can be adjusted by the number of repetition times of the sequence of the gas introduction; therefore, an ALD method makes it possible to accurately adjust a thickness and thus is suitable for manufacturing a minute FET.

The variety of films such as the conductive films, the insulating films, the oxide semiconductor films, and the metal oxide films which are described in the above embodiments can be formed by a thermal CVD method such as a MOCVD method or an ALD method. For example, trimethylindium, trimethylgallium, and dimethylzinc are used to form an In—Ga—ZnO film. Note that the chemical formula of trimethylindium is In(CH₃)₃. The chemical formula of trimethylgallium is Ga(CH₃)₃. The chemical formula of dimethylzinc is Zn(CH₃)₂. Without limitation to the above combination, triethylgallium (chemical formula: Ga(C₂H₅)₃) can be used instead of trimethylgallium, and diethylzinc (chemical formula: Zn(C₂H₅)₂) can be used instead of dimethylzinc.

For example, in the case where a hafnium oxide film is formed with a deposition apparatus employing ALD, two kinds of gases, i.e., ozone (O₃) as an oxidizer and a source gas that is obtained by vaporizing liquid containing a solvent and a hafnium precursor compound (hafnium alkoxide or hafnium amide such as tetrakis(dimethylamide)hafnium (TDMAH)), are used. Note that the chemical formula of tetrakis(dimethylamide)hafnium is Hf[N(CH₃)₂]₄. Examples of another material liquid include tetrakis(ethylmethylamide)hafnium.

For example, in the case where an aluminum oxide film is formed with a deposition apparatus employing ALD, two kinds of gases, i.e., H₂O as an oxidizer and a source gas that is obtained by vaporizing liquid containing a solvent and an aluminum precursor compound (e.g., trimethylaluminum (TMA)) are used. Note that the chemical formula of trimethylaluminum is Al(CH₃)₃. Examples of another material liquid include tris(dimethylamide)aluminum, triisobutylaluminum, and aluminum tris(2,2,6,6-tetramethyl-3,5-heptanedionate).

For example, in the case where a silicon oxide film is formed with a deposition apparatus employing ALD, hexachlorodisilane is adsorbed on a deposition surface, chlorine contained in adsorbate is removed, and radicals of an oxidizing gas (e.g., O₂ or dinitrogen monoxide) are supplied to react with the adsorbate.

For example, when a tungsten film is formed with a deposition apparatus using ALD, a WF₆ gas and a B₂H₆ gas are sequentially introduced multiple times to form an initial tungsten film, and then a WF₆ gas and an H₂ gas are used, so that a tungsten film is formed. Note that a SiH₄ gas may be used instead of a B₂H₆ gas.

For example, in the case where an oxide semiconductor film, for example, an InGaZnOₓ, film (x>0) is formed with a deposition apparatus employing an ALD method, an In(CH₃)₃ gas and an O₃ gas are sequentially introduced more than once to form an InO₂ layer, a GaO layer is formed using a Ga(CH₃)₃ gas and an O₃ gas, and then a ZnO layer is formed using a Zn(CH₃)₂ gas and an O₃ gas. Note that the order of these layers is not limited to this example. A mixed compound layer such as an In—Ga—O layer, an In—Zn—O layer, or a Ga—Zn—O layer may be formed by mixing of these gases. Note that although an H₂O gas that is obtained by bubbling with an inert gas such as Ar may be used instead of an O₃ gas, it is preferable to use an O₃ gas that does not contain H. Instead of an In(CH₃)₃ gas, an In(C₂H₅)₃ gas may be used. Instead of a Ga(CH₃)₃ gas, a Ga(C₂H₅)₃ gas may be used. Alternatively, a Zn(CH₃)₂ gas may be used.

This embodiment can be combined with any of the other embodiments in this specification as appropriate.

### Embodiment 4

### <Composition of CAC—OS>

Described below will be the composition of a cloud aligned complementary oxide semiconductor (CAC—OS) applicable to a transistor disclosed in one embodiment of the present invention.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is called an oxide semiconductor in some cases. In other words, an OS FET is a transistor including a metal oxide or an oxide semiconductor.

In this specification, a metal oxide in which regions functioning as a conductor and regions functioning as a dielectric are mixed and which functions as a semiconductor as a whole is defined as a CAC—OS or a CAC-metal oxide.

The CAC—OS has, for example, a composition in which elements included in an oxide semiconductor are unevenly distributed. Materials including unevenly distributed elements each have a size of greater than or equal to 0.5 nm and less than or equal to 10 nm, preferably greater than or equal to 0.5 nm and less than or equal to 3 nm, or a similar size. Note that in the following description of an oxide semiconductor, a state in which one or more elements are unevenly distributed and regions including the element(s) are mixed is referred to as a mosaic pattern or a patch-like pattern. The region has a size of greater than or equal to 0.5 nm and less than or equal to 10 nm, preferably greater than or equal to 0.5 nm and less than or equal to 3 nm, or a similar size.

The physical properties of a region including an unevenly distributed element are determined by the properties of the element. For example, a region including an unevenly distributed element which relatively tends to serve as an insulator among elements included in a metal oxide serves as a dielectric region. In contrast, a region including an unevenly distributed element which relatively tends to serve as a conductor among elements included in a metal oxide serves as a conductive region. A material in which conductive regions and dielectric regions are mixed to form a mosaic pattern serves as a semiconductor.

That is, a metal oxide in one embodiment of the present invention is a kind of matrix composite or metal matrix composite, in which materials having different physical properties are mixed.

Note that an oxide semiconductor preferably contains at least indium. In particular, indium and zinc are preferably contained. In addition, an element M (M is one or more of gallium, aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) may be contained.

For example, of the CAC—OS, an In—Ga—Zn oxide with the CAC composition (such an In—Ga—Zn oxide may be particularly referred to as CAC-IGZO) has a composition in which materials are separated into indium oxide (InOₓ₁, where X1 is a real number greater than 0) or indium zinc oxide (Inₓ₂Zn_{y2}O_{z2}, where X2, Y2, and Z2 are real numbers greater than 0), and gallium oxide (GaOₓ₃, where X3 is a real number greater than 0), gallium zinc oxide (Gaₓ₄Zn_{y4}O_{z4}, where X4, Y4, and Z4 are real numbers greater than 0), or the like, and a mosaic pattern is formed. Then, InOₓᵢ and Inₓ₂Zn_{y2}O_{z2} forming the mosaic pattern are evenly distributed in the film. This composition is also referred to as a cloud-like composition.

That is, the CAC—OS is a composite oxide semiconductor with a composition in which a region including GaOₓ₃ as a main component and a region including Inₓ₂Zn_{y2}O_{z2} or InOₓ₁ as a main component are mixed. Note that in this specification, for example, when the atomic ratio of In to an element M in a first region is greater than the atomic ratio of In to an element M in a second region, the first region has higher In concentration than the second region.

Note that a compound including In, Ga, Zn, and O is also known as IGZO. Typical examples of IGZO include a crystalline compound represented by InGaO₃(ZnO)ₘ₁ (m1 is a natural number) and a crystalline compound represented by In₍₁₊ₓ₀₎Ga₍₁₋ₓ₀₎O₃(ZnO)ₘ₀ (−1≦×0≦1; m0 is a given number).

The above crystalline compounds have a single crystal structure, a polycrystalline structure, or a CAAC structure. Note that the CAAC structure is a crystal structure in which a plurality of IGZO nanocrystals have c-axis alignment and are connected in the a-b plane direction without alignment.

On the other hand, the CAC—OS relates to the material composition of an oxide semiconductor. In a material composition of a CAC—OS including In, Ga, Zn, and O, nanoparticle regions including Ga as a main component and nanoparticle regions including In as a main component are observed in parts of the CAC—OS. These nanoparticle regions are randomly dispersed to form a mosaic pattern. Therefore, the crystal structure is a secondary element for the CAC—OS.

Note that in the CAC—OS, a layered structure including two or more films with different atomic ratios is not included. For example, a two-layer structure of a film including In as a main component and a film including Ga as a main component is not included.

A boundary between the region including GaOₓ₃ as a main component and the region including Inₓ₂Zn_{y2}O_{z2} or InOₓ₁ as a main component is not clearly observed in some cases.

In the case where one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like are contained instead of gallium in a CAC—OS, nanoparticle regions including the selected element(s) as a main component(s) and nanoparticle regions including In as a main component are observed in parts of the CAC—OS , and these nanoparticle regions are randomly dispersed to form a mosaic pattern in the CAC—OS.

### <Analysis of CAC—OS>

Next, measurement results of an oxide semiconductor over a substrate by a variety of methods will be described.

### <<Structure of Samples and Formation Method Thereof>>

Nine samples of one embodiment of the present invention will be described below. The samples are formed at different substrate temperatures and with different ratios of an oxygen gas flow rate in formation of the oxide semiconductor. Note that each sample includes a substrate and an oxide semiconductor over the substrate.

A method for forming the samples will be described.

A glass substrate is used as the substrate. Over the glass substrate, a 100-nm-thick In—Ga—Zn oxide is formed as an oxide semiconductor with a sputtering apparatus. The formation conditions are as follows: the pressure in a chamber is 0.6 Pa, and an oxide target (with an atomic ratio of In:Ga:Zn=4:2:4.1) is used as a target. The oxide target provided in the sputtering apparatus is supplied with an AC power of 2500 W.

As for the conditions in the formation of the oxide of the nine samples, the substrate temperature is set to a temperature that is not increased by intentional heating (hereinafter such a temperature is also referred to as room temperature or R.T.), to 130° C., and to 170° C. The ratio of a flow rate of an oxygen gas to a flow rate of a mixed gas of Ar and oxygen (also referred to as an oxygen gas flow rate ratio) is set to 10%, 30%, and 100%.

### <<Analysis by X-ray Diffraction>>

In this section, results of X-ray diffraction (XRD) measurement performed on the nine samples will be described. As an XRD apparatus, D8 ADVANCE manufactured by Bruker AXS is used. The conditions are as follows: scanning is performed by an out-of-plane method at θ/2θ, the scanning range is 15 deg. to 50 deg., the step width is 0.02 deg., and the scanning speed is 3.0 deg./min.

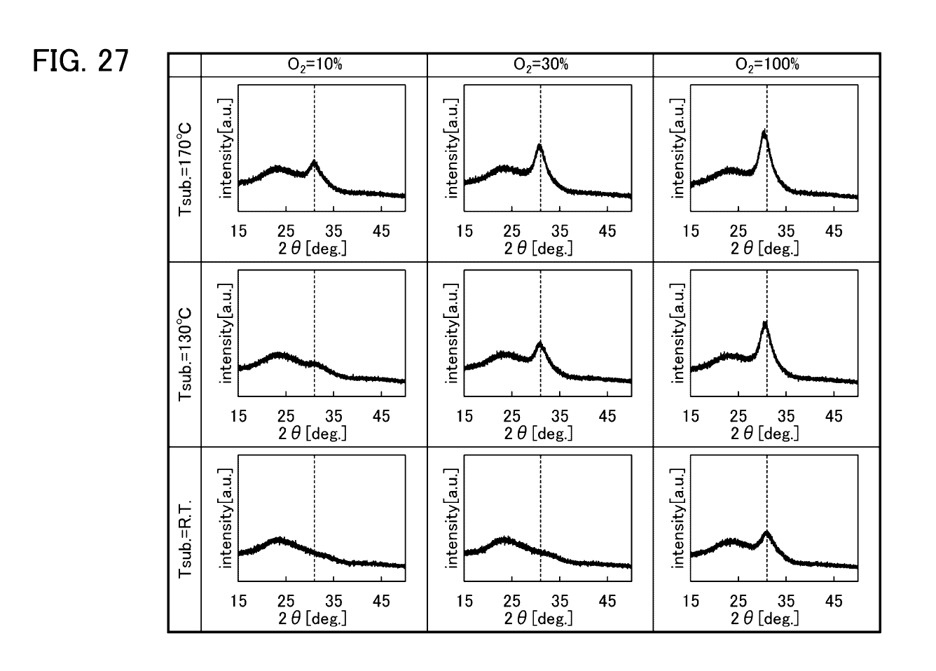

FIG. 27 shows XRD spectra measured by an out-of-plane method. In FIG. 27, the top row shows the measurement results of the samples formed at a substrate temperature of 170° C.; the middle row shows the measurement results of the samples formed at a substrate temperature of 130° C.; the bottom row shows the measurement results of the samples formed at a substrate temperature of R.T. The left column shows the measurement results of the samples formed at an oxygen gas flow rate ratio of 10%; the middle column shows the measurement results of the samples formed at an oxygen gas flow rate ratio of 30%; the right column shows the measurement results of the samples formed at an oxygen gas flow rate ratio of 100%.

In the XRD spectra shown in FIG. 27, the higher the substrate temperature at the time of formation is or the higher the oxygen gas flow rate ratio at the time of formation is, the higher the intensity of the peak at around 2θ=31° is. Note that it is found that the peak at around θ=31° is derived from a crystalline IGZO compound whose c-axes are aligned in the direction substantially perpendicular to a formation surface or a top surface of the crystalline IGZO compound (such a compound is also referred to as c-axis aligned crystalline (CAAC) IGZO).

As shown in the XRD spectra in FIG. 27, as the substrate temperature at the time of formation is lower or the oxygen gas flow rate ratio at the time of formation is lower, a peak becomes less clear. Accordingly, it is found that there are no alignment in the a-b plane direction and c-axis alignment in the measured areas of the samples that are formed at a lower substrate temperature or a lower oxygen gas flow rate ratio.

<<Analysis with Electron Microscope>>

This section will describe the observation and analysis results of the samples formed at a substrate temperature of R.T. and an oxygen gas flow rate ratio of 10% with a high-angle annular dark-field scanning transmission electron microscope (HAADF-STEM). An image obtained with an HAADF-STEM is also referred to as a TEM image.

Described will be the results of image analysis of plan-view images and cross-sectional images obtained with a HAADF-STEM (also referred to as plan-view TEM images and cross-sectional TEM images, respectively). The TEM images are observed with a spherical aberration corrector function. The HAADF-STEM images are obtained using an atomic resolution analytical electron microscope JEM-ARM200F manufactured by JEOL Ltd. under the following conditions: the acceleration voltage is 200 kV, and irradiation with an electron beam with a diameter of approximately 0.1 nm is performed.

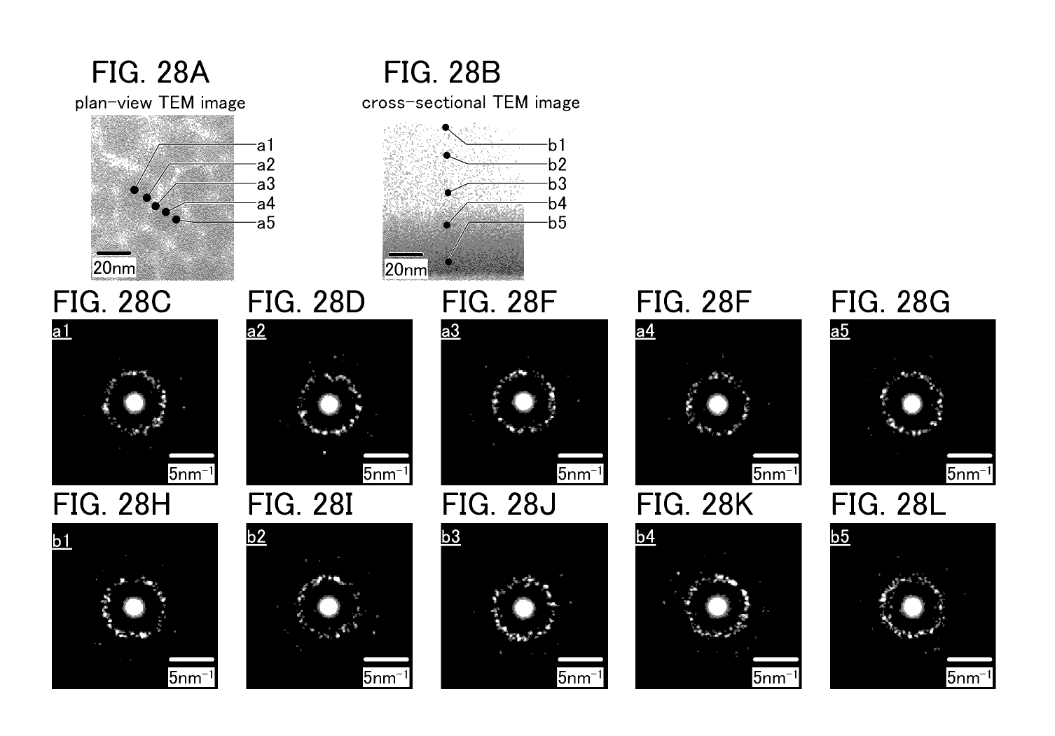

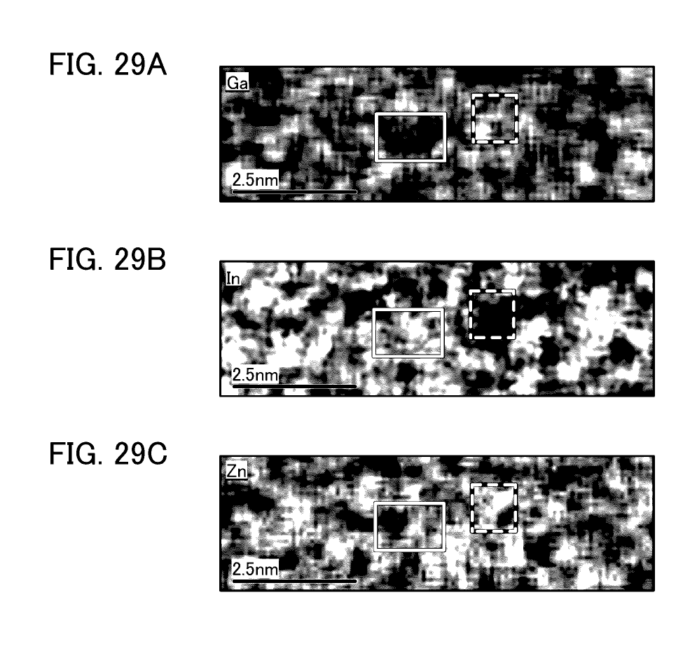

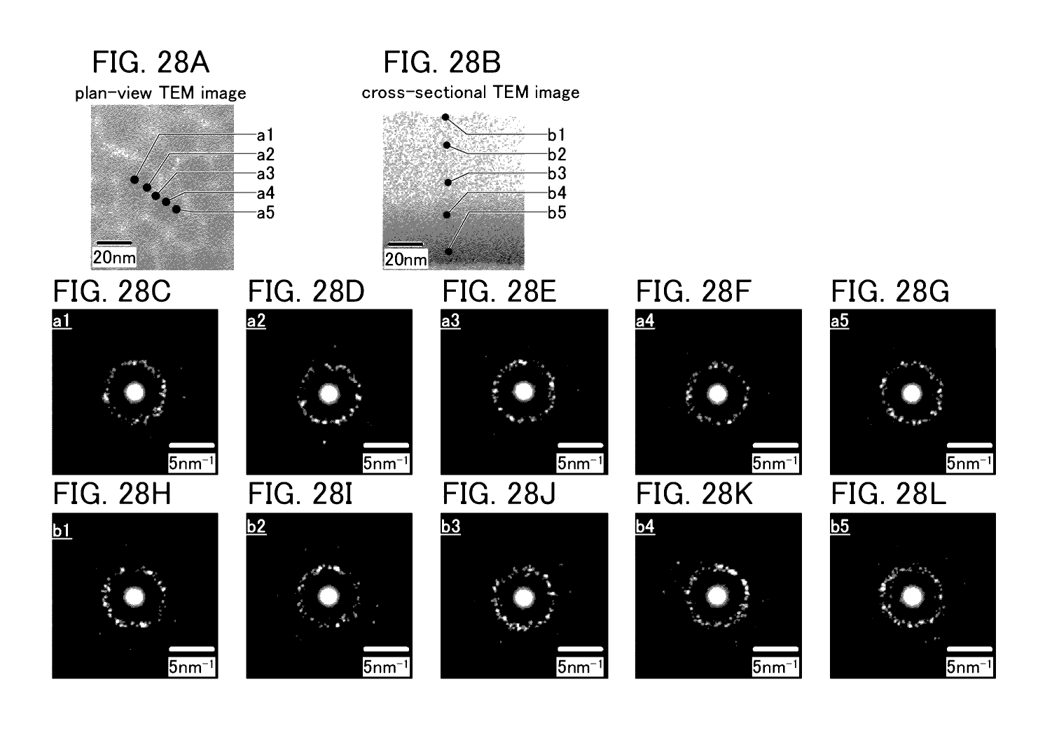

FIG. 28A is a plan-view TEM image of the sample formed at a substrate temperature of R.T. and an oxygen gas flow rate ratio of 10%. FIG. 28B is a cross-sectional TEM image of the sample formed at a substrate temperature of R.T. and an oxygen gas flow rate ratio of 10%.

### <<Analysis of Electron Diffraction Patterns>>

This section will describe electron diffraction patterns obtained by irradiation of the sample formed at a substrate temperature of R.T. and an oxygen gas flow rate ratio of 10% with an electron beam with a probe diameter of 1 nm (also referred to as a nanobeam).

Electron diffraction patterns of points indicated by black dots a1, a2, a3, a4, and a5 in the plan-view TEM image in FIG. 28A of the sample formed at a substrate temperature of R.T.

and an oxygen gas flow rate ratio of 10% are observed. Note that the electron diffraction patterns are observed while electron beam irradiation is performed at a constant rate for 35 seconds. FIGS. 28C, 28D, 28E, 28F, and 28G show the results of the points indicated by the black dots a1, a2, a3, a4, and a5, respectively.

In FIGS. 28C, 28D, 28E, 28F, and 28G, regions with high luminance in a circular (ring) pattern can be shown. Furthermore, a plurality of spots can be shown in a ring-like shape.

Electron diffraction patterns of points indicated by black dots b1, b2, b3, b4, and b5 in the cross-sectional TEM image in FIG. 28B of the sample formed at a substrate temperature of R.T. and an oxygen gas flow rate ratio of 10% are observed. FIGS. 28H, 28I, 28J, 28K, and 28L show the results of the points indicated by the black dots b1, b2, b3, b4, and b5, respectively.

In FIGS. 28H, 28I, 28J, 28K, and 28L, regions with high luminance in a ring pattern can be shown. Furthermore, a plurality of spots can be shown in a ring-like shape.

For example, when an electron beam with a probe diameter of 300 nm is incident on a CAAC-OS including an InGaZnO₄ crystal in the direction parallel to the sample surface, a diffraction pattern including a spot derived from the (009) plane of the InGaZnO₄ crystal is obtained. That is, the CAAC—OS has c-axis alignment and the c-axes are aligned in the direction substantially perpendicular to the formation surface or the top surface of the CAAC—OS. Meanwhile, a ring-like diffraction pattern is shown when an electron beam with a probe diameter of 300 nm is incident on the same sample in the direction perpendicular to the sample surface. That is, it is found that the CAAC—OS has neither a-axis alignment nor b-axis alignment.

Furthermore, a diffraction pattern like a halo pattern is observed when an oxide semiconductor including a nanocrystal (a nanocrystalline oxide semiconductor (nc—OS)) is subjected to electron diffraction using an electron beam with a large probe diameter (e.g., 50 nm or larger). Meanwhile, bright spots are shown in a nanobeam electron diffraction pattern of the nc—OS obtained using an electron beam with a small probe diameter (e.g., smaller than 50 nm). Furthermore, in a nanobeam electron diffraction pattern of the nc—OS, regions with high luminance in a circular (ring) pattern are shown in some cases. Also in a nanobeam electron diffraction pattern of the nc—OS, a plurality of bright spots are shown in a ring-like shape in some cases.

The electron diffraction pattern of the sample formed at a substrate temperature of R.T. and an oxygen gas flow rate ratio of 10% has regions with high luminance in a ring pattern and a plurality of bright spots appear in the ring-like pattern. Accordingly, the sample formed at a substrate temperature of R.T. and an oxygen gas flow rate ratio of 10% exhibits an electron diffraction pattern similar to that of the nc—OS and does not show alignment in the plane direction and the cross-sectional direction.

According to what is described above, an oxide semiconductor formed at a low substrate temperature or a low oxygen gas flow rate ratio is likely to have characteristics distinctly different from those of an oxide semiconductor film having an amorphous structure and an oxide semiconductor film having a single crystal structure.

### <<Elementary Analysis>>

This section will describe the analysis results of elements included in the sample formed at a substrate temperature of R.T. and an oxygen gas flow rate ratio of 10%. For the analysis, by energy dispersive X-ray spectroscopy (EDX), EDX mapping images are obtained. An energy dispersive X-ray spectrometer AnalysisStation JED-2300T manufactured by JEOL Ltd. is used as an elementary analysis apparatus in the EDX measurement. A Si drift detector is used to detect an X-ray emitted from the sample.

In the EDX measurement, an EDX spectrum of a point is obtained in such a manner that electron beam irradiation is performed on the point in a detection target region of a sample, and the energy of characteristic X-ray of the sample generated by the irradiation and its frequency are measured. In this embodiment, peaks of an EDX spectrum of the point are attributed to electron transition to the L shell in an In atom, electron transition to the K shell in a Ga atom, and electron transition to the K shell in a Zn atom and the K shell in an O atom, and the proportions of the atoms in the point are calculated. An EDX mapping image indicating distributions of proportions of atoms can be obtained through the process in an analysis target region of a sample.

FIGS. 29A to 29C show EDX mapping images in a cross section of the sample formed at a substrate temperature of R.T. and an oxygen gas flow rate ratio of 10%. FIG. 29A shows an EDX mapping image of Ga atoms. The proportion of the Ga atoms in all the atoms is 1.18 atomic % to 18.64 atomic %. FIG. 29B shows an EDX mapping image of In atoms. The proportion of the In atoms in all the atoms is 9.28 atomic % to 33.74 atomic %. FIG. 29C shows an EDX mapping image of Zn atoms. The proportion of the Zn atoms in all the atoms is 6.69 atomic % to 24.99 atomic %. FIGS. 29A to 29C show the same region in the cross section of the sample formed at a substrate temperature of R.T. and an oxygen gas flow rate ratio of 10%. In the EDX mapping images, the proportion of an element is indicated by grayscale: the more measured atoms exist in a region, the brighter the region is; the less measured atoms exist in a region, the darker the region is. The magnification of the EDX mapping images in FIGS. 29A to 29C is 7200000 times.

The EDX mapping images in FIGS. 29A to 29C show relative distribution of brightness indicating that each element has a distribution in the sample formed at a substrate temperature of R.T. and an oxygen gas flow rate ratio of 10%. Areas surrounded by solid lines and areas surrounded by dashed lines in FIGS. 29A to 29C are examined.

In FIG. 29A, a relatively dark region occupies a large area in the area surrounded by the solid line, while a relatively bright region occupies a large area in the area surrounded by the dashed line. In FIG. 29B, a relatively bright region occupies a large area in the area surrounded by the solid line, while a relatively dark region occupies a large area in the area surrounded by the dashed line.

That is, the areas surrounded by the solid lines are regions including a relatively large number of In atoms and the areas surrounded by the dashed lines are regions including a relatively small number of In atoms. In FIG. 29C, the right portion of the area surrounded by the solid line is relatively bright and the left portion thereof is relatively dark. Thus, the area surrounded by the solid line is a region including Inₓ₂Zn_{y2}O_{z2}, InOₓ₁, and the like as main components.

The area surrounded by the solid line is a region including a relatively small number of Ga atoms and the area surrounded by the dashed line is a region including a relatively large number of Ga atoms. In FIG. 29C, the upper left portion of the area surrounded by the dashed line is relatively bright and the lower right portion thereof is relatively dark. Thus, the area surrounded by the dashed line is a region including GaOₓ₃, Gaₓ₄Zn_{y4}O_{z4}, and the like as main components.

Furthermore, as shown in FIGS. 29A to 29C, the In atoms are relatively more uniformly distributed than the Ga atoms, and regions including InOₓ₁ as a main component is seemingly joined to each other through a region including Inₓ₂Zn_{y2}O_{z2} as a main component. Thus, the regions including Inₓ₂Zn_{y2}O_{z2} and InOₓ₁ as main components extend like a cloud.

An In—Ga—Zn oxide having a composition in which the regions including GaOₓ₃ or the like as a main component and the regions including Inₓ₂Zn_{y2}O_{z2} or InOₓ₁ as a main component are unevenly distributed and mixed can be referred to as a CAC—OS.

The crystal structure of the CAC—OS includes an nc structure. In an electron diffraction pattern of the CAC—OS with the nc structure, several or more bright spots appear in addition to bright sports derived from IGZO including a single crystal, a polycrystal, or a CAAC. Alternatively, the crystal structure is defined as having high luminance regions appearing in a ring pattern in addition to the several or more bright spots.

As shown in FIGS. 29A to 29C, each of the regions including GaOₓ₃ or the like as a main component and the regions including Inₓ₂Zn_{y2}O_{z2} or InOₓ₁ as a main component has a size of greater than or equal to 0.5 nm and less than or equal to 10 nm, or greater than or equal to 1 nm and less than or equal to 3 nm. Note that it is preferable that a diameter of a region including each metal element as a main component be greater than or equal to 1 nm and less than or equal to 2 nm in the EDX mapping images.

As described above, the CAC—OS has a structure different from that of an IGZO compound in which metal elements are evenly distributed, and has characteristics different from those of the IGZO compound. That is, in the CAC—OS, regions including GaOₓ₃ or the like as a main component and regions including Inₓ₂Zn_{y2}O_{z2} or InOₓ₁ as a main component are separated to form a mosaic pattern.

The conductivity of a region including Inₓ₂Zn_{y2}O_{z2} or InOₓ₁ as a main component is higher than that of a region including GaOₓ₃ or the like as a main component. In other words, when carriers flow through regions including Inₓ₂Zn_{y2}O_{z2} or InOₓ₁ as a main component, the conductivity of an oxide semiconductor exhibits. Accordingly, when regions including Inₓ₂Zn_{y2}O_{z2} or InOₓ₁ as a main component are distributed in an oxide semiconductor like a cloud, high field-effect mobility (μ) can be achieved.

In contrast, the insulating property of a region including GaOₓ₃ or the like as a main component is higher than that of a region including Inₓ₂Zn_{y2}O_{z2} or InOₓ₁ as a main component.

In other words, when regions including GaOₓ₃ or the like as a main component are distributed in an oxide semiconductor, a leakage current can be suppressed and favorable switching operation can be achieved.

Accordingly, when a CAC—OS is used for a semiconductor element, the insulating property derived from GaOₓ₃ or the like and the conductivity derived from Inₓ₂Zn_{y2}O_{z2} or InOₓ₁ complement each other, whereby a high on-state current (Iₒₙ) and high field-effect mobility (μ) can be achieved.

A semiconductor element including a CAC—OS has high reliability. Thus, the CAC—OS is suitably used in a variety of semiconductor devices typified by a display.

At least part of this embodiment can be implemented in combination with any of the other embodiments and the other examples described in this specification as appropriate.

### Embodiment 5

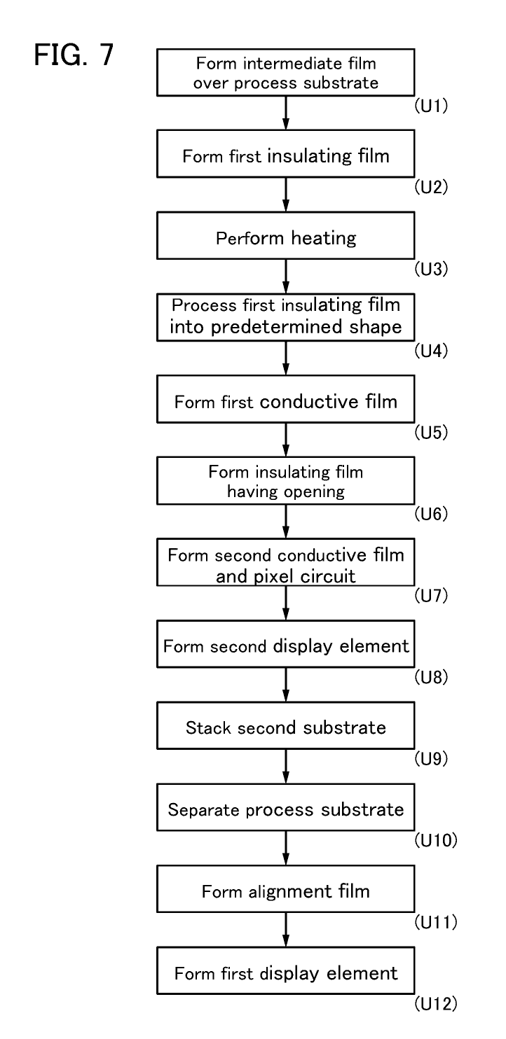

In this embodiment, a method for manufacturing a display panel of one embodiment of the present invention will be described with reference to FIG. 7 to FIGS. 14A to 14C.

FIG. 7 is a flow chart showing a method for manufacturing the display panel of one embodiment of the present invention.

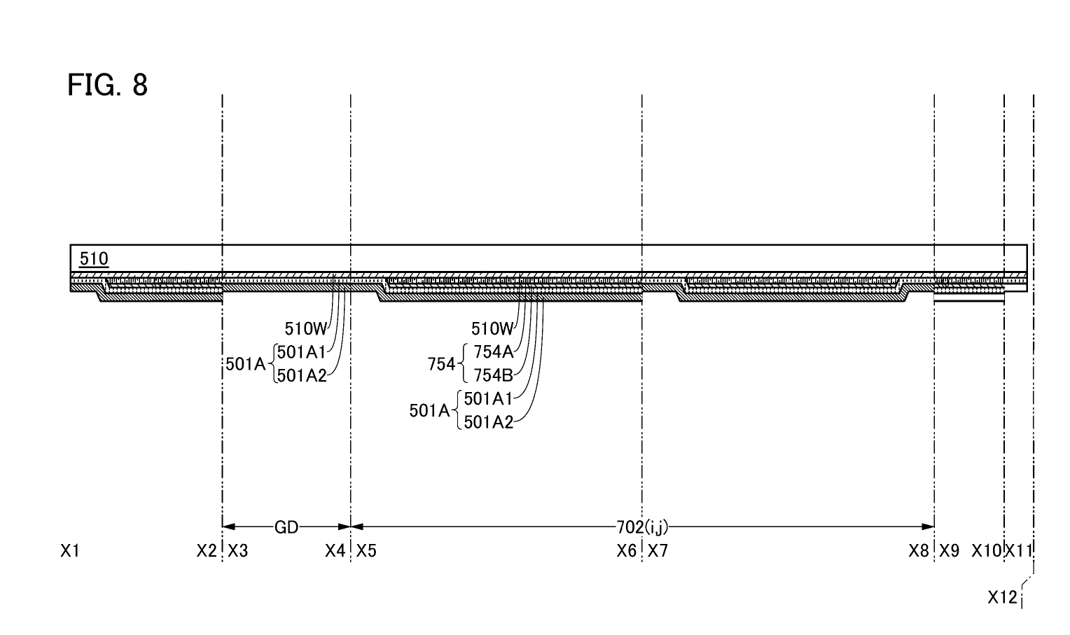

FIG. 8 to FIGS. 14A to 14C each illustrate the structure of the display panel of one embodiment of the present invention in a manufacturing process. FIG. 8 to FIGS. 14A to 14C are each a cross-sectional view taken along dashed-dotted lines X1-X2, X3-X4, X5-X6, X7-X8, X9-X10, and X11-X12 in FIG. 1A.

### <Method for Manufacturing Display Panel>

A method for manufacturing a display panel described in this embodiment includes the following 12 steps.

### <<First Step>>

In the first step, an intermediate film 754 including a region overlapping with a process substrate is formed (see (U1) in FIG. 7).

For example, a substrate 510 over which a separation film 510W is stacked can be used as the process substrate. A material that can be separated from the substrate 510 in a later step is used for the intermediate film 754. This allows the separation film 510W to remain on the substrate 510 side after the intermediate film 754 is separated from the substrate 510. Alternatively, the separation film 510W can be separated together with the intermediate film 754 from the substrate 510.

For the separation film 510W, an inorganic material, an organic resin, or the like can be used, for example.

For example, a single-layer material or a layered material including a plurality of films can be used for the separation film 510W.

Specifically, an inorganic material such as a metal containing an element selected from tungsten, molybdenum, titanium, tantalum, niobium, nickel, cobalt, zirconium, zinc, ruthenium, rhodium, palladium, osmium, iridium, and silicon, an alloy including any of the elements, or a compound including any of the elements can be used for the separation film 510W.

A film containing tungsten or a material obtained by stacking a film containing tungsten and a film containing an oxide of tungsten can be used as the separation film 510W.

The film containing an oxide of tungsten can be formed on a film containing tungsten by a method in which another film is stacked on a film containing tungsten. Specifically, a film containing silicon and oxygen is stacked on the film containing tungsten. For example, the film containing silicon and oxygen is stacked on the film containing tungsten with the use of a gas containing nitrous oxide (N₂O).

The film containing an oxide of tungsten may be formed by subjecting a surface of a film containing tungsten to thermal oxidation treatment, oxygen plasma treatment, nitrous oxide (N₂O) plasma treatment, treatment with a solution with high oxidizing power (e.g., ozone water), or the like.

Specifically, a 30-nm-thick film containing tungsten having a surface subjected to plasma treatment in an atmosphere containing nitrous oxide (N₂O) can be used as the separation film 510W.

An organic material such as polyimide, polyester, polyolefin, polyamide, polycarbonate, or an acrylic resin can be used for the separation film 510W. Specifically, a film containing polyimide that has heat resistance of higher than or equal to 200° C., preferably higher than or equal to 250° C., more preferably higher than or equal to 300° C., still more preferably higher than or equal to 350° C. can be used as the separation film 510W.

A material having heat resistance high enough to withstand heat treatment in the manufacturing process can be used for the substrate 510.

For example, a large-sized glass substrate having any of the following sizes can be used as the substrate 510: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

For example, an inorganic material such as glass, ceramic, or metal can be used for the substrate 510.

Specifically, non-alkali glass, soda-lime glass, potash glass, crystal glass, quartz, sapphire, or the like can be used for the substrate 510. Specifically, a material containing inorganic oxide, inorganic nitride, or inorganic oxynitride, or the like can be used for the substrate 510. For example, a material containing silicon oxide, silicon nitride, silicon oxynitride, aluminum oxide, or the like can be used for the substrate 510. For example, stainless steel or aluminum can be used for the substrate 510.

Note that a material obtained by stacking films serving as an etching stopper can be used as the intermediate film 754. Specifically, a material obtained by stacking a 50-nm-thick intermediate film 754A containing indium, gallium, zinc, and oxygen and a 20-nm-thick intermediate film 754B containing indium, tin, and oxygen, in this order, can be used for the intermediate film 754. A 20-nm-thick film containing indium, tin, silicon, and oxygen can alternatively be used as the intermediate film 754B. Accordingly, a reduction in the thickness of the intermediate film 754 in a later step for processing the insulating film 501A into a predetermined shape can be suppressed.

The intermediate film 754 can be formed by a sputtering method, for example. Specifically, a sputtering method using a material containing indium, gallium, and zinc at a ratio of 1:1:1 as a target can be employed. Alternatively, a sputtering method using a material containing indium, gallium, and zinc at a ratio of 4:2:3 as a target can be employed.

### <<Second Step>>

In the second step, the insulating film 501A that covers the intermediate film 754 is formed (see (U2) in FIG. 7 and FIG. 8). Note that a material that can be separated from the substrate 510 in a later step can be used for the insulating film 501A.

The insulating film 501A can be formed by a chemical vapor deposition method using silane or the like as a source gas, for example.

Specifically, a material obtained by stacking an insulating film 501A1 and an insulating film 501A2 in this order can be used for the insulating film 501A.

For example, the insulating film 501A1 with a thickness greater than or equal to 200 nm and less than or equal to 600 nm can be used. A material containing silicon and oxygen or a material containing silicon, oxygen, and nitrogen can be used for the insulating film 501A1.

For example, the insulating film 501A2 with a thickness of approximately 200 nm can be used. A material containing silicon and nitrogen can be used for the insulating film 501A2.

The insulating film 501A is heated in a later step to supply hydrogen. The insulating film 501A2 prevents hydrogen passage. Thus, hydrogen diffuses toward the interface between the insulating film 501A and the separation film 510W or the interface between the intermediate film 754 and the separation film 510W.

### <<Third Step>>

In the third step, the insulating film 501A is heated (see (U3) in FIG. 7).

For example, the insulating film 501A is heated to supply hydrogen. Specifically, the insulating film 501A is heated at 450° C. for one hour.

Hydrogen supplied by the insulating film 501A passes through the intermediate film 754 and reaches the separation film 510W, a structure in which the intermediate film 754 and the insulating film 501A can be separated from the substrate 510 in a later step is formed between the intermediate film 754 and the substrate 510 and between the insulating film 501A and the substrate 510.

### <<Fourth Step>>

In the fourth step, the insulating film 501A is processed into a predetermined shape (see (U4) in FIG. 7).

The insulating film 501A is processed into a predetermined shape by a photolithography method and an etching method, for example.

### <<Fifth Step>>

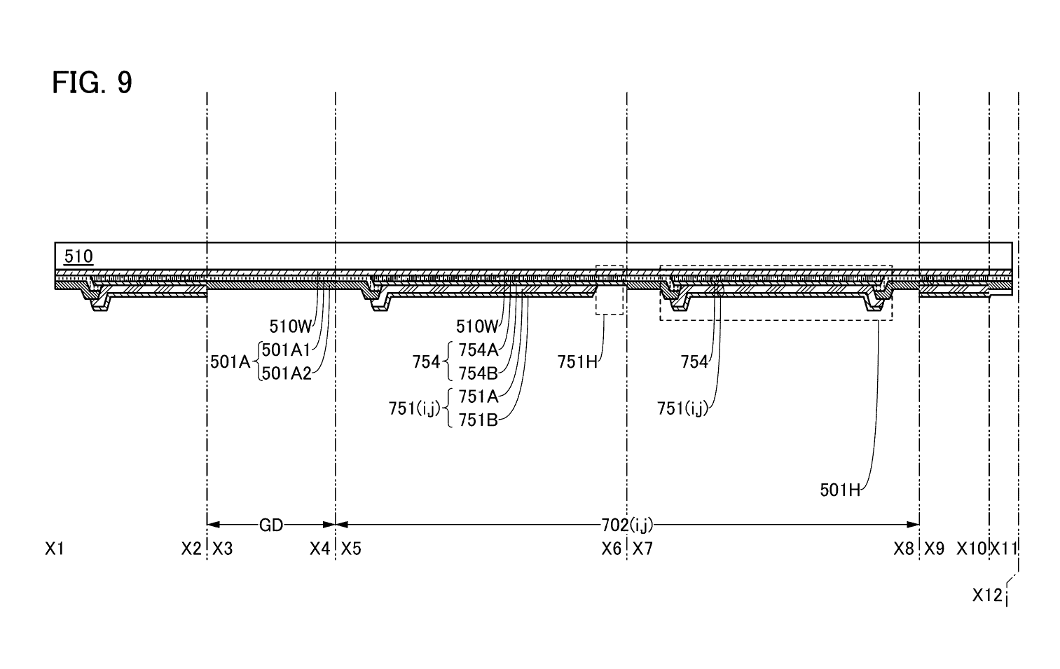

In the fifth step, a first conductive film including a region overlapping with the intermediate film 754 is formed (see (U5) in FIG. 7 and FIG. 9). Note that the first electrode 751(i,j) can be used for the first conductive film.

The first conductive film is processed into a predetermined shape by a photolithography method or an etching method, for example. Specifically, a region that reflects external light that passes through the opening 751H and the intermediate film 754 and enters the region is formed.

Specifically, a material obtained by stacking a 100-nm-thick conductive film 751A containing silver and a 100-nm-thick conductive film 751B containing indium, tin, and oxygen, in this order, can be used for the first conductive film. Alternatively, a material obtained by stacking the 100-nm-thick conductive film 751A containing silver and the 100-nm-thick conductive film 751B containing indium, tin, and oxygen, in this order, can be used for the first conductive film. Thus, a reduction in the thickness of the first conductive film in processing of the insulating film 501C into a predetermined shape can be suppressed.

### <<Sixth Step>>

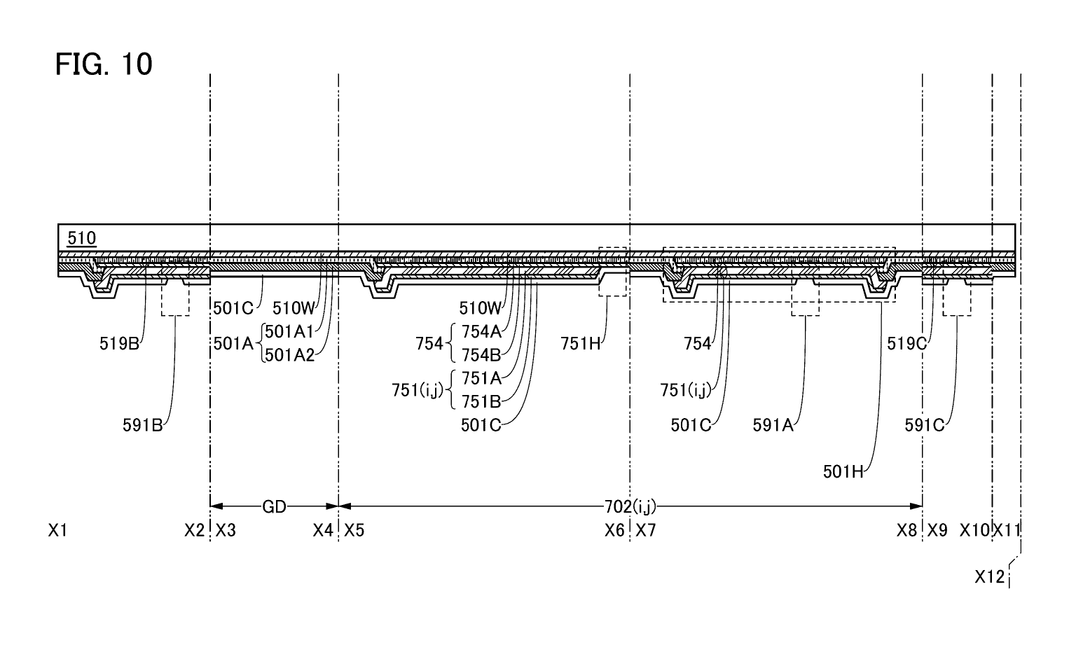

In the sixth step, the insulating film 501C having the opening 591A in a region overlapping with the first conductive film is formed (see (U6) in FIG. 7 and FIG. 10).

The insulating film 501C is processed into a predetermined shape by a photolithography method and an etching method, for example.

Specifically, the insulating film 501C with a thickness of approximately 200 nm can be used. For example, a material containing silicon and oxygen or a material containing silicon, oxygen, and nitrogen can be used for the insulating film 501C.

Note that the insulating film 501C has the opening 591B and the opening 591C. A conductive film including a region overlapping with the opening 591B can be used for the terminal 519B. A conductive film overlapping with the opening 591C can be used for the terminal 519C.

### <<Seventh Step>>

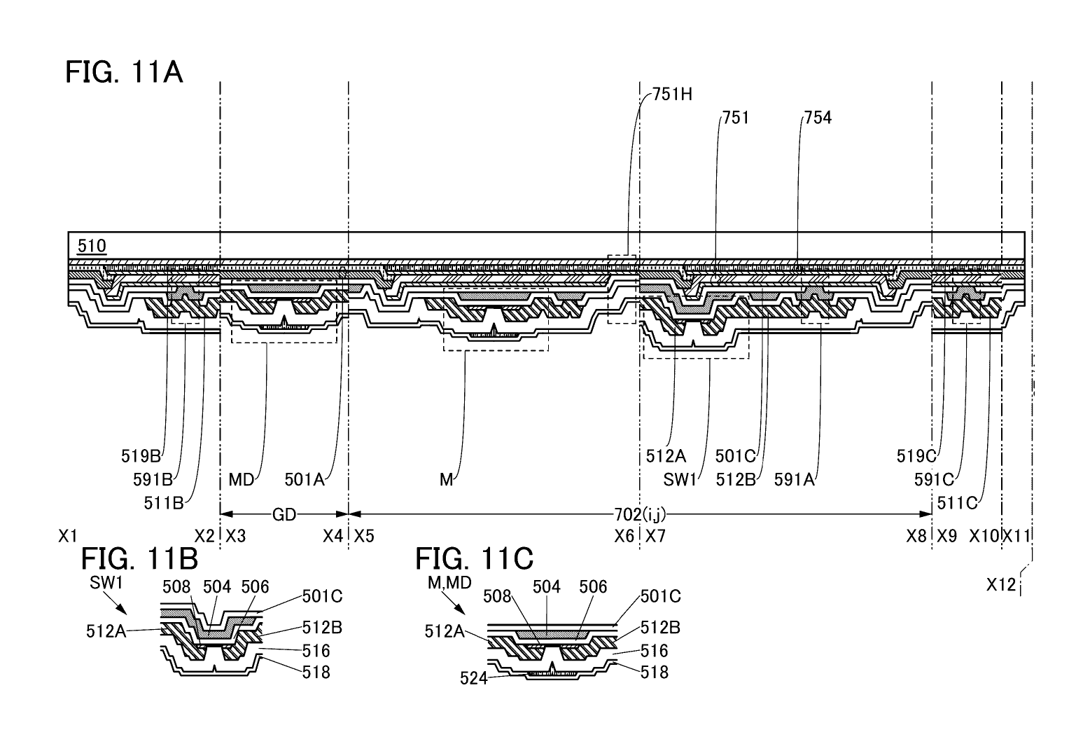

In the seventh step, a second conductive film overlapping with the opening 591A and the pixel circuit 530(i,j) are formed (see (U7) in FIG. 7 and FIGS. 11A to 11C).

For example, the conductive film 512B of a transistor that can be used for the switch SW1 can be used as the second conductive film.

The first conductive film and the second conductive film can be electrically connected to each other using another conductive film including a region overlapping with the opening 591A. For example, a conductive film that can be formed in the same process as the conductive film 504 can be used as the another conductive film.

### <<Eighth Step>>

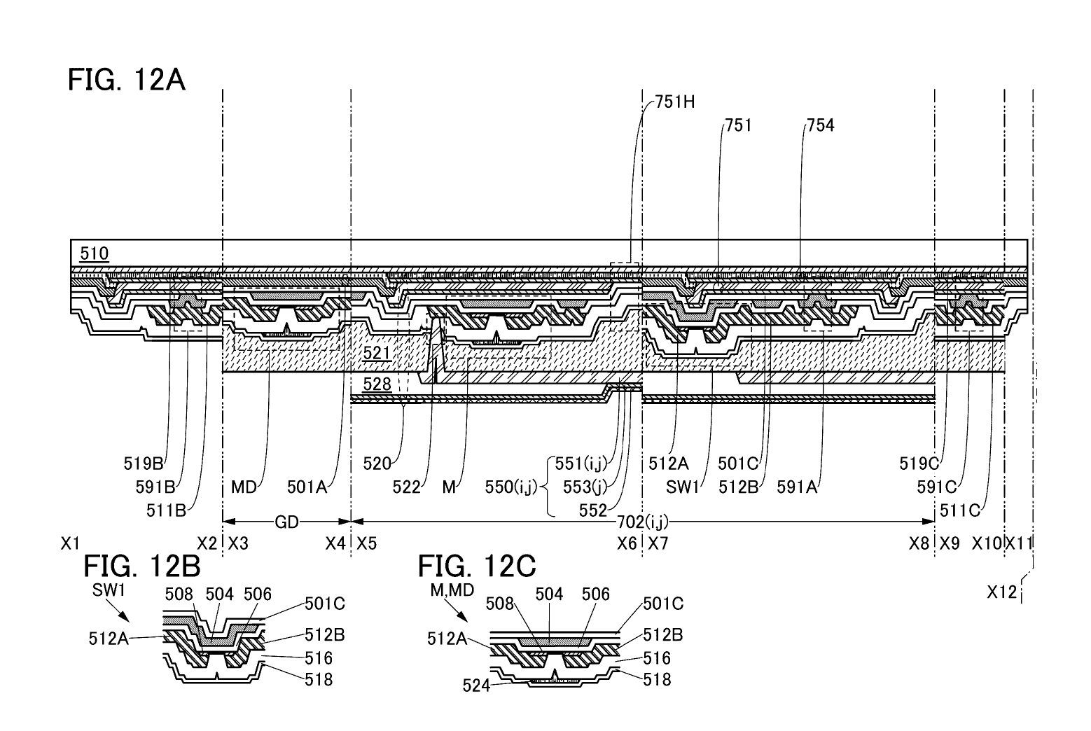

In the eighth step, the second display element 550(i,j) electrically connected to the pixel circuit 530(i,j) is formed (see (U8) in FIG. 7 and FIGS. 12A to 12C).

### <<Ninth Step>>

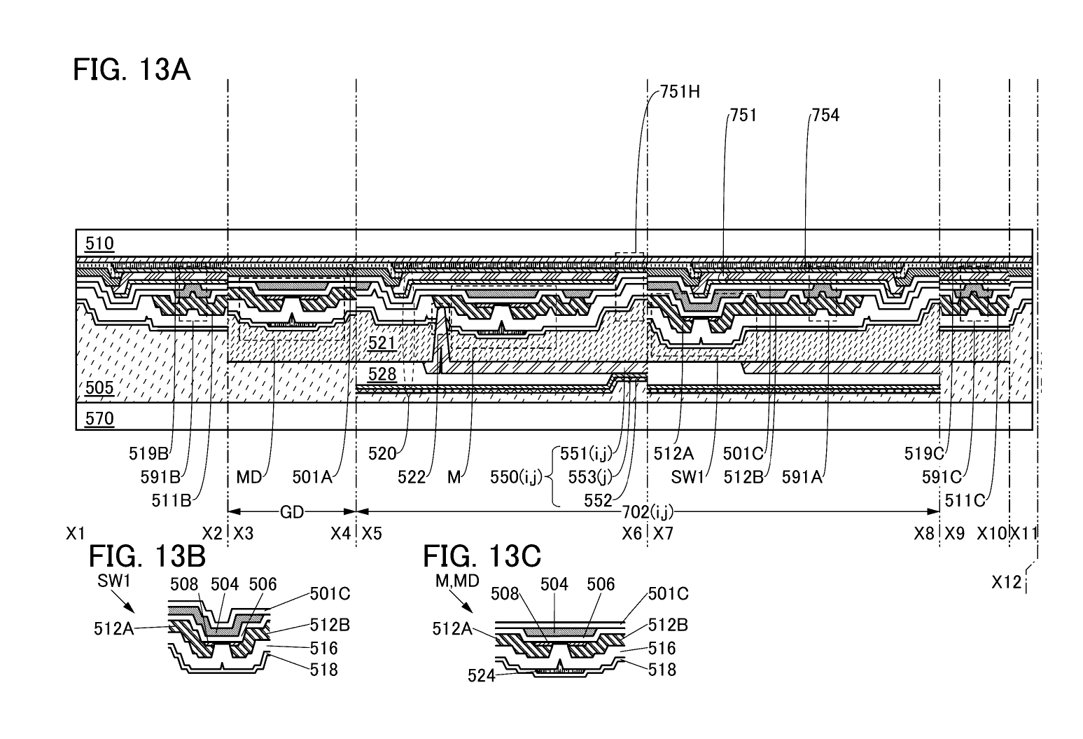

In the ninth step, the second substrate 570 is stacked such that the second display element 550(i,j) is interposed between the process substrate and the second substrate 570 (see (U9) in FIG. 7 and FIGS. 13A and 13B).

The bonding layer 505 is formed by a printing method or a coating method, for example, and the second substrate 570 is bonded to the process substrate using the bonding layer 505.

### <<Tenth Step>>

In the tenth step, the process substrate is separated (see (U10) in FIG. 7).

For example, the insulating film 501A and the intermediate film 754 are separated along the separation film 510W. Specifically, a separation trigger in which part of the insulating film 501A is separated from the process substrate is formed. Subsequently, a region in which the insulating film 501A or the intermediate film 754 is separated from the process substrate is gradually extended from the separation trigger; as a result, the insulating film 501A and the intermediate film 754 are separated from the process substrate.

The separation trigger can be formed by a method using a laser or the like (specifically, a laser ablation method) or a method using a cutter with a cutting edge, for example.

### <<Eleventh Step>>

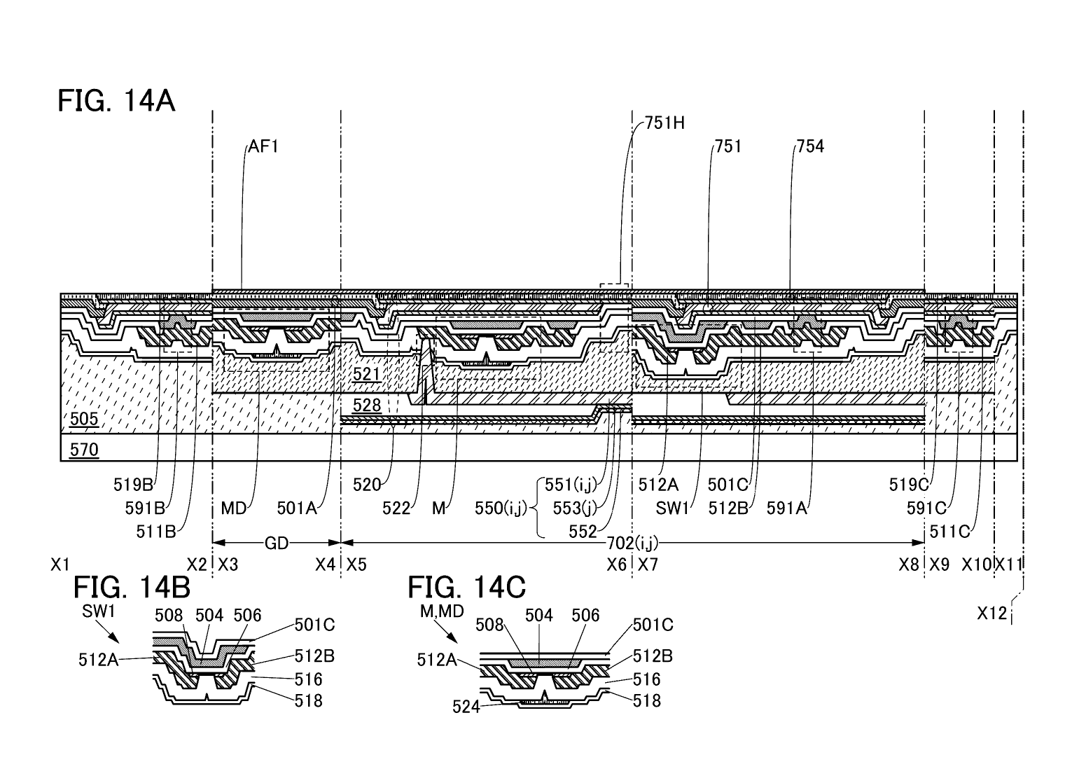

In the eleventh step, the alignment film AF1 is formed such that the intermediate film 754 is interposed between the first conductive film and the alignment film AF1 (see (U11) in FIG. 7 and FIGS. 14A to 14C).

A film containing soluble polyimide that is used as the alignment film AF1 is formed by a printing method, for example. In the case where the film containing soluble polyimide is used, the temperature of heat transferred to the second display element 550(i,j) in formation of the alignment film AF1 can be lower than that when a method using a precursor of polyimide, such as a polyamic acid, is employed. Thus, a manufacturing method for a novel display panel that is highly convenient or reliable can be provided.

### <<Twelfth Step>>

In the twelfth step, the first display element 750(i,j) is formed (see (U12) in FIG. 7 and FIGS. 2A to 2C).

The method for manufacturing the display panel of one embodiment of the present invention includes the step of forming the intermediate film, the step of forming the second insulating film overlapping with the intermediate film, and the step of separating the process substrate. The method enables formation of a region in which the intermediate film is exposed and a region in which the second insulating film is exposed. Thus, the manufacturing method of a novel display panel that is highly convenient or reliable can be provided.

A manufacturing method for the display panel of one embodiment of the present invention includes a step of forming a first conductive film; a step of forming a first insulating film that includes a region overlapping with the first conductive film and has an opening overlapping with the first conductive film; a step of forming a pixel circuit such that the first insulating film is interposed between the first conductive film and part of the pixel circuit and the pixel circuit is electrically connected to the first conductive film; a step of forming a second display element such that it is electrically connected to the pixel circuit; and a step of forming a first display element such that it is electrically connected to the first conductive film. This method allows the display panel to be manufactured through the processes performed in the following descending order of the degree of difficulty: a process for forming the pixel circuit that requires the highest temperature; a process for forming the second display element that requires a high degree of vacuum; and a process for forming the first display element that does not require a high temperature or a high degree of vacuum. Thus, a manufacturing method for a novel display panel that is highly convenient or reliable can be provided.

Note that this embodiment can be combined with any of the other embodiments in this specification as appropriate.

### Embodiment 6

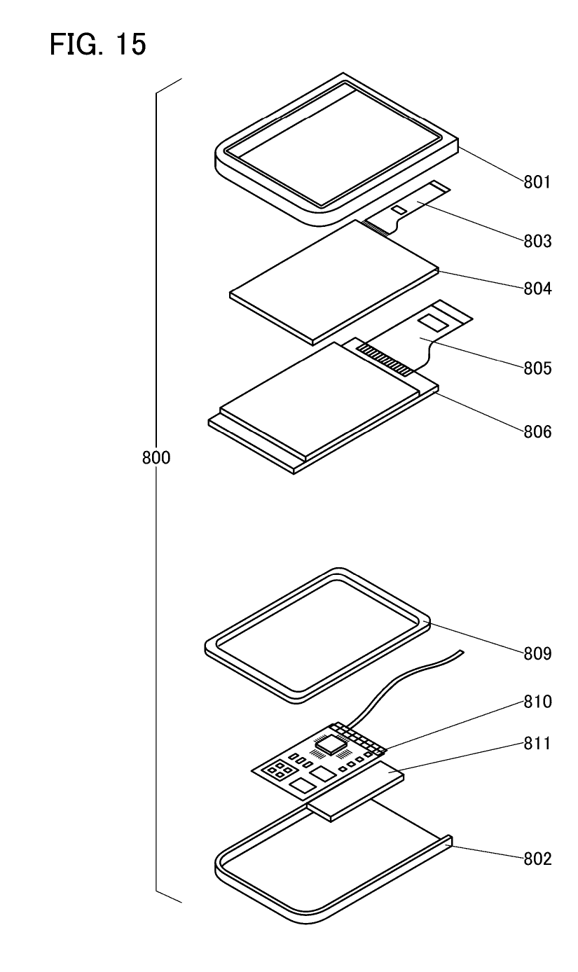

In this embodiment, the structure of an input/output device of one embodiment of the present invention will be described with reference to FIG. 15.

FIG. 15 is an exploded view of an input/output device 800 for illustrating the components.

The input/output device 800 includes a display panel 806 and a touch sensor 804 having a region overlapping with the display panel 806. Note that the input/output device 800 can be referred to as a touch panel.

The input/output device 800 is provided with a driver circuit 810 for driving the touch sensor 804 and the display panel 806, a battery 811 for supplying power to the driver circuit 810, and a housing where the touch sensor 804, the display panel 806, the driver circuit 810, and the battery 811 are housed.

### <<Touch Sensor 804>>

The touch sensor 804 includes a region overlapping with the display panel 806. Note that an FPC 803 is electrically connected to the touch sensor 804.

For the touch sensor 804, a resistive touch sensor, a capacitive touch sensor, or a touch sensor using a photoelectric conversion element can be used, for example.

Note that the touch sensor 804 may be used as part of the display panel 806.

### <<Display Panel 806>>

For example, the display panel described in Embodiment 1 can be used as the display panel 806. Note that an FPC 805 and the like are electrically connected to the display panel 806.

### <<Driver Circuit 810>>

As the driver circuit 810, a power supply circuit or a signal processing circuit can be used, for example. Power supplied to the battery or an external commercial power source can be utilized.

The signal processing circuit has a function of outputting a video signal, a clock signal, and the like.

The power supply circuit has a function of supplying predetermined power.

### <<Housing>>

An upper cover 801, a lower cover 802 which fits the upper cover 801, and a frame 809 which is housed in a region surrounded by the upper cover 801 and the lower cover 802 can be used for the housing, for example.

The frame 809 has a function of protecting the display panel 806, and a function of blocking electromagnetic waves generated by the operation of the driver circuit 810 or a function of a radiator plate.

Metal, a resin, an elastomer, or the like can be used for the upper cover 801, the lower cover 802, or the frame 809.

### <<Battery 811>>

The battery 811 has a function of supplying power.

Note that a member such as a polarizing plate, a retardation plate, or a prism sheet can be used for the input/output device 800.

This embodiment can be combined with any of the other embodiments in this specification as appropriate.

### Embodiment 7

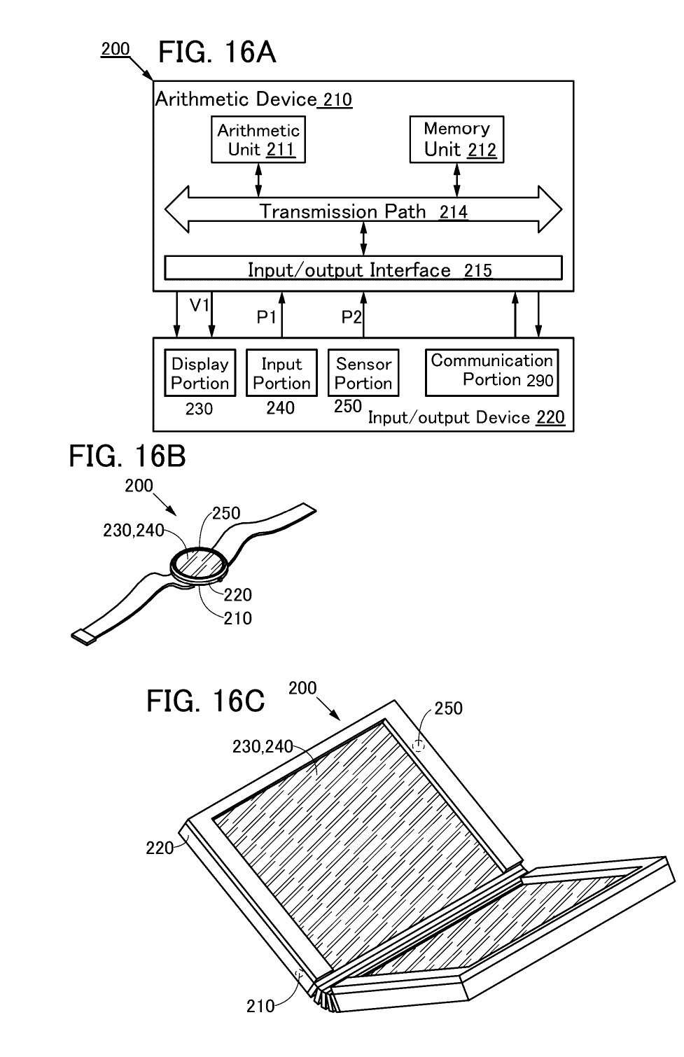

In this embodiment, the structure of a data processing device of one embodiment of the present invention will be described with reference to FIGS. 16A to 16C to FIG. 19.

FIG. 16A is a block diagram illustrating the structure of a data processing device 200. FIGS. 16B and 16C are each a projection view illustrating an example of an external view of the data processing device 200.

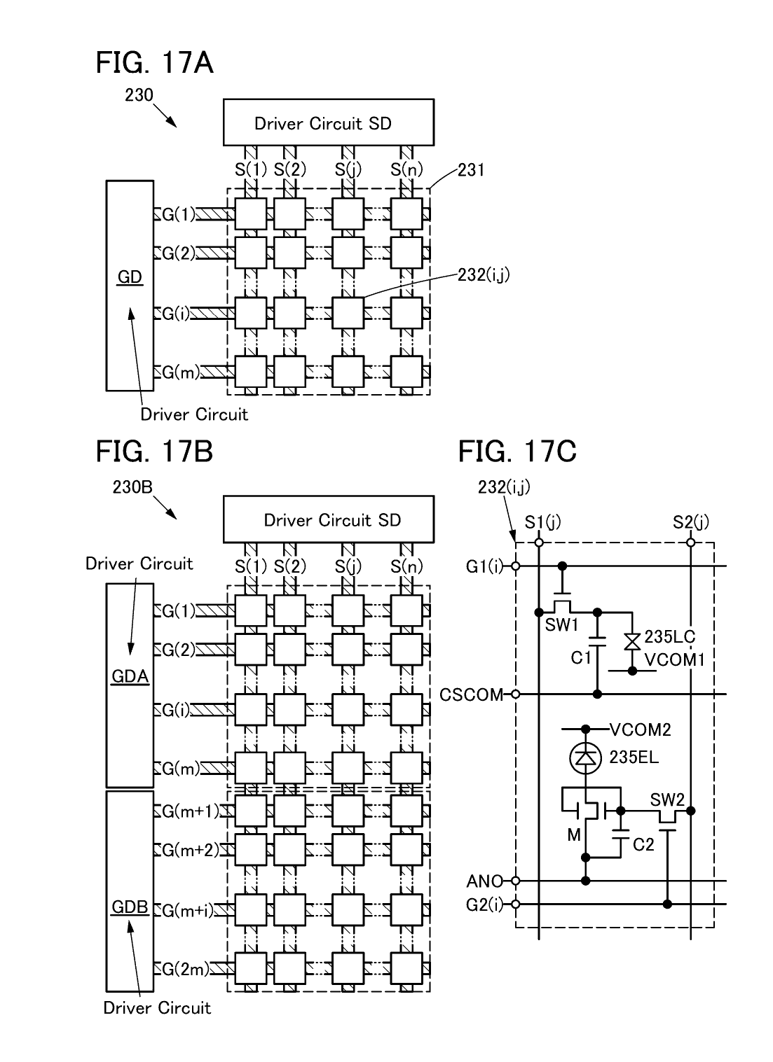

FIG. 17A is a block diagram illustrating the configuration of a display portion 230. FIG. 17B is a block diagram illustrating the configuration of a display portion 230B. FIG. 17C is a circuit diagram illustrating the configuration of a pixel 232(i,j).

### <Configuration Example of Data Processing Device>

The data processing device 200 described in this embodiment includes an arithmetic device 210 and an input/output device 220 (see FIG. 16A).

The arithmetic device 210 has a function of receiving positional data P1 and supplying image data V and control data.

The input/output device 220 has a function of supplying the positional data P1 and receiving the image data V and the control data.

The input/output device 220 includes the display portion 230 that displays the image data V and an input portion 240 that supplies the positional data P1.

The display portion 230 includes a first display element and a second display element overlapping with the first display element. The display portion 230 further includes a first pixel circuit for driving the first display element and a second pixel circuit for driving the second display element.

The input portion 240 has a function of determining the position of a pointer and supplying the positional data P1 determined in accordance with the position.

The arithmetic device 210 has a function of determining the moving speed of the pointer in accordance with the positional data P1.

The arithmetic device 210 has a function of determining the contrast or brightness of the image data V in accordance with the moving speed.

The data processing device 200 described in this embodiment includes the input/output device 220 that supplies the positional data P1 and receives the image data V and the arithmetic device 210 that receives the positional data P1 and supplies the image data V. The arithmetic device 210 has a function of determining the contrast or brightness of the image data V in accordance with the moving speed of the positional data P1.

With this structure, eyestrain on a user caused when the display position of image data is moved can be reduced, that is, eye-friendly display can be achieved. Moreover, the power consumption can be reduced and excellent visibility can be provided even in a bright place exposed to direct sunlight, for example. Thus, the novel data processing device that is highly convenient or reliable can be provided.

### <Configuration>

The data processing device of one embodiment of the present invention includes the arithmetic device 210 or the input/output device 220.

### <<Arithmetic Device 210>>

The arithmetic device 210 includes an arithmetic unit 211 and a memory unit 212. The arithmetic device 210 further includes a transmission path 214 and an input/output interface 215 (see FIG. 16A).

### <<Arithmetic Unit 211>>

The arithmetic unit 211 has a function of, for example, executing a program. For example, a CPU described in Embodiment 8 can be used. Thus, power consumption can be sufficiently reduced.

### <<Memory Unit 212>>

The memory unit 212 has a function of, for example, storing the program executed by the arithmetic unit 211, initial data, setting data, an image, or the like.

Specifically, a hard disk, a flash memory, a memory including a transistor including an oxide semiconductor, or the like can be used for the memory unit 212.

### <<Input/output Interface 215, Transmission Path 214>>

The input/output interface 215 includes a terminal or a wiring and has a function of supplying and receiving data. For example, the input/output interface 215 can be electrically connected to the transmission path 214 and the input/output device 220.

The transmission path 214 includes a wiring and has a function of supplying and receiving data. For example, the transmission path 214 can be electrically connected to the input/output interface 215. Alternatively, the transmission path 214 can be electrically connected to the arithmetic unit 211, the memory unit 212, or the input/output interface 215.

### <<Input/output Device 220>>

The input/output device 220 includes the display portion 230, the input portion 240, a sensor portion 250, or a communication portion 290.

### <<Display Portion 230>>

The display portion 230 includes a display region 231, a driver circuit GD, and a driver circuit SD (see FIG. 17A). For example, the display panel described in Embodiment 1 can be used. Thus, low power consumption can be achieved.

The display region 231 includes a plurality of pixels 232(i, l) to 232(i, n) arranged in the row direction, a plurality of pixels 232(l,j) to 232(m, j) arranged in the column direction, the scan line G1(i) and the scan line G2(i) electrically connected to the pixels 232(i, l) to 232(i, n) , and the signal line S1(j) and the signal line S2(j) electrically connected to the pixels 232(i,j) to 232(m, j). Note that i is an integer greater than or equal to 1 and less than or equal to m, j is an integer greater than or equal to 1 and less than or equal to n, and each of m and n is an integer greater than or equal to 1.

Note that the pixel 232(i, j) is electrically connected to the scan line G1(i), the scan line G2(i), the signal line S1(j), the signal line S2(j), the wiring ANO, the wiring CSCOM, the wiring VCOM1, and the wiring VCOM2 (see FIG. 17C).

The display portion can include a plurality of driver circuits. For example, the display portion 230B can include a driver circuit GDA and a driver circuit GDB (see FIG. 17B).

### <<Driver Circuit GD>>

The driver circuit GD has a function of supplying a selection signal in accordance with the control data.

For example, the driver circuit GD has a function of supplying a selection signal to one scan line at a frequency of 30 Hz or higher, preferably 60 Hz or higher, in accordance with the control data. Accordingly, moving images can be smoothly displayed.

For example, the driver circuit GD has a function of supplying a selection signal to one scan line at a frequency of lower than 30 Hz, preferably lower than 1 Hz, more preferably less than once per minute, in accordance with the control data. Accordingly, a still image can be displayed while flickering is suppressed.

For example, in the case where a plurality of driver circuits are provided, the driver circuits GDA and GDB may supply the selection signals at different frequencies. Specifically, the selection signal can be supplied at a higher frequency to a region on which moving images are smoothly displayed than to a region on which a still image is displayed in a state where flickering is suppressed.

### <<Driver Circuit SD>>

The driver circuit SD has a function of supplying an image signal in accordance with the image data V.

<<Pixel 232(i,j)>>

The pixel 232(i,j) includes a first display element 235LC and a second display element 235EL overlapping with the first display element 235LC. The pixel 232(i,j) further includes a pixel circuit for driving the first display element 235LC and a pixel circuit for driving the second display element 235EL (see FIG. 17C).

### <<First Display Element 235LC>>

For example, a display element having a function of controlling transmission or reflection of light can be used as the first display element 235LC. For example, a combined structure of a polarizing plate and a liquid crystal element or a MEMS shutter display element can be used. The use of a reflective display element can reduce power consumption of a display panel. Specifically, a reflective liquid crystal display element can be used as the first display element 235LC.

The first display element 235LC includes a first electrode, a second electrode, and a liquid crystal layer. The liquid crystal layer contains a liquid crystal material whose alignment can be controlled by a voltage applied between the first electrode and the second electrode. For example, the alignment of the liquid crystal material can be controlled by an electric field in the thickness direction (also referred to as the vertical direction), the horizontal direction, or the diagonal direction of the liquid crystal layer.

### <<Second Display Element 235EL>>

A display element having a function of emitting light, such as an organic EL element, can be used as the second display element 235EL.

Specifically, an organic EL element having a function of emitting white light can be used as the second display element 235EL. Alternatively, an organic EL element which emits blue light, green light, or red light can be used as the second display element 235EL.

### <<Pixel Circuit>>

A pixel circuit including a circuit having a function of driving the first display element 235LC or the second display element 235EL can be used.

For example, a switch, a transistor, a diode, a resistor, an inductor, a capacitor can be used in the pixel circuit.

For example, one or a plurality of transistors can be used for a switch. Alternatively, a plurality of transistors connected in parallel, in series, or in combination of parallel connection and series connection can be used for a switch.

### <<Transistor>>

For example, a semiconductor film formed in the same process can be used for transistors in the driver circuit and the pixel circuit.

For example, bottom-gate transistors, top-gate transistors, or the like can be used.

For example, a manufacturing line for a bottom-gate transistor including amorphous silicon as a semiconductor can be easily remodeled into a manufacturing line for a bottom-gate transistor including an oxide semiconductor as a semiconductor. Furthermore, for example, a manufacturing line for a top-gate transistor including polysilicon as a semiconductor can be easily remodeled into a manufacturing line for a top-gate transistor including an oxide semiconductor as a semiconductor.

For example, a transistor including a semiconductor containing an element belonging to Group 14 can be used. Specifically, a semiconductor containing silicon can be used for a semiconductor film. For example, single crystal silicon, polysilicon, microcrystalline silicon, amorphous silicon, or the like can be used for the semiconductor films of the transistors.

Note that the temperature for forming a transistor using polysilicon in a semiconductor film is lower than the temperature for forming a transistor using single crystal silicon in a semiconductor film.

In addition, the transistor using polysilicon in a semiconductor film has higher field-effect mobility than the transistor using amorphous silicon in a semiconductor film, and therefore, a pixel including the transistor using polysilicon can have a high aperture ratio. Moreover, pixels arranged at a high density, a gate driver circuit, and a source driver circuit can be formed over the same substrate. As a result, the number of components included in an electronic device can be reduced.

In addition, the transistor using polysilicon in a semiconductor film has higher reliability than the transistor using amorphous silicon in a semiconductor.

For example, a transistor including an oxide semiconductor can be used. Specifically, an oxide semiconductor containing indium or an oxide semiconductor containing indium, gallium, and zinc can be used for a semiconductor film.

For example, a transistor having a lower leakage current in an off state than a transistor that uses amorphous silicon for a semiconductor film can be used. Specifically, a transistor that uses an oxide semiconductor for a semiconductor film can be used.

Thus, a pixel circuit can hold an image signal for a longer time than a pixel circuit including a transistor that uses amorphous silicon for a semiconductor film. Specifically, the selection signal can be supplied at a frequency of lower than 30 Hz, preferably lower than 1 Hz, more preferably less than once per minute while flickering is suppressed. Consequently, eyestrain on a user of the data processing device can be reduced, and power consumption for driving can be reduced.

Alternatively, for example, a transistor including a compound semiconductor can be used. Specifically, a semiconductor containing gallium arsenide can be used for a semiconductor film.

For example, a transistor including an organic semiconductor can be used. Specifically, an organic semiconductor containing any of polyacenes and graphene can be used for the semiconductor film.

### <<Input Portion 240>>

Any of a variety of human interfaces or the like can be used as the input portion 240 (see FIG. 16A).

For example, a keyboard, a mouse, a touch sensor, a microphone, a camera, or the like can be used as the input portion 240. Note that a touch sensor having a region overlapping with the display portion 230 can be used. An input/output device that includes the display portion 230 and a touch sensor having a region overlapping with the display portion 230 can be referred to as a touch panel.

For example, a user can make various gestures (e.g., tap, drag, swipe, and pinch in) using his/her finger as a pointer on the touch panel.

The arithmetic device 210, for example, analyzes data on the position, track, or the like of the finger on the touch panel and determines that a specific gesture is supplied when the analysis results meet predetermined conditions. Therefore, the user can supply a certain operation instruction associated with a predetermined gesture by using the gesture.

For instance, the user can supply a “scrolling instruction” for changing a portion where image data is displayed by using a gesture of touching and moving his/her finger on the touch panel.

### <<Sensor Portion 250>>

The sensor portion 250 has a function of acquiring data P2 by determining the surrounding state.

For example, a camera, an acceleration sensor, a direction sensor, a pressure sensor, a temperature sensor, a humidity sensor, an illuminance sensor, or a global positioning system (GPS) signal receiving circuit can be used as the sensor portion 250.

For example, when the arithmetic device 210 determines that the ambient light level measured by an illuminance sensor of the sensor portion 250 is sufficiently higher than the predetermined illuminance, image data is displayed using the first display element 235LC. When the arithmetic device 210 determines that it is dim, image data is displayed using the first display element 235LC and the second display element 235EL. When the arithmetic device 210 determines that it is dark, image data is displayed using the second display element 235EL.

Specifically, an image is displayed with a reflective liquid crystal element and an organic EL element in accordance with the ambient brightness.

Thus, image data can be displayed in such a manner that, for example, a reflective display element is used under strong ambient light, a reflective display element and a self-luminous display element are used in dim light, and a self-luminous display element is used in dark light. Thus, a novel data processing device which has low power consumption and is highly convenient or reliable can be provided.

For example, a sensor having a function of determining the chromaticity of ambient light, such as a CCD camera, can be used in the sensor portion 250, whereby white balance can be adjusted in accordance with the chromaticity of ambient light determined by the sensor portion 250.

Specifically, in the first step, deviation of white balance of ambient light is detected.

In the second step, the intensity of light of a color which is insufficient in an image to be displayed by the first display element using reflection of ambient light is estimated.

In the third step, ambient light is reflected by the first display element, and light is emitted from the second display element so that light of the insufficient color is supplemented, whereby the image is displayed.

In this manner, display can be performed with adjusted white balance by utilizing light reflected by the first display element and light emitted from the second display element. Thus, a novel data processing device which can display an image with low power consumption or with adjusted white balance and which is highly convenient and reliable can be provided.

### <<Communication Portion 290>>

The communication portion 290 has a function of supplying and acquiring data to/from a network.

### <<Program>>

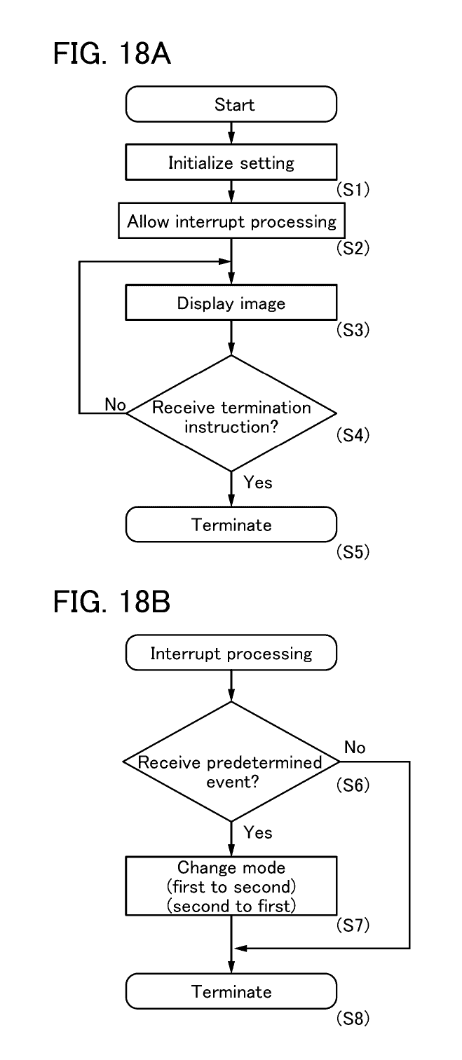

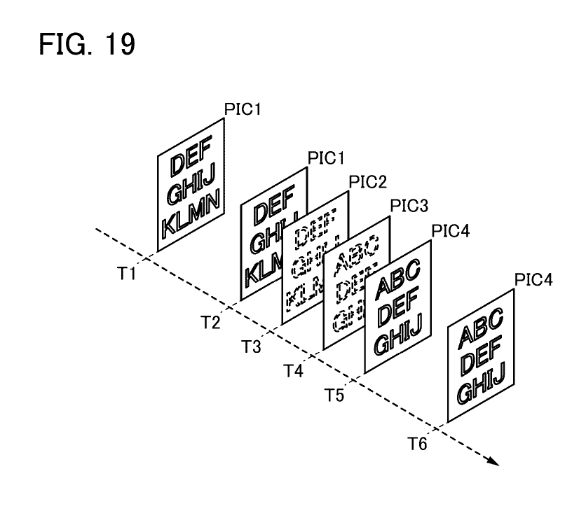

A program of one embodiment of the present invention will be described with reference to FIGS. 18A and 18B and FIG. 19.

FIG. 18A is a flow chart showing main processing of the program of one embodiment of the present invention, and FIG. 18B is a flow chart showing interrupt processing.

FIG. 19 schematically illustrates a method for displaying image data on the display portion 230.

The program of one embodiment of the present invention has the following steps (see FIG. 18A).

### [First Step]

In the first step, setting is initialized (see (S1) in FIG. 18A).

For instance, predetermined image data and the second mode can be used for the initialization.

For example, a still image can be used as the predetermined image data. Alternatively, a mode in which the selection signal is supplied at a frequency of lower than 30 Hz, preferably lower than 1 Hz, more preferably less than once per minute can be used as the second mode.

### [Second Step]

In the second step, interrupt processing is allowed (see (S2) in FIG. 18A). Note that an arithmetic device allowed to execute the interrupt processing can perform the interrupt processing in parallel with the main processing. The arithmetic device which has returned from the interrupt processing to the main processing can reflect the results of the interrupt processing in the main processing.

The arithmetic device may execute the interrupt processing when a counter has an initial value, and the counter may be set at a value other than the initial value when the arithmetic device returns from the interrupt processing. Thus, the interrupt processing is ready to be executed after the program is started up.

### [Third Step]

In the third step, image data is displayed in a mode selected in the first step or the interrupt processing (see (S3) in FIG. 18A).

For instance, predetermined image data is displayed in the second mode, in accordance with the initialization.

Specifically, the predetermined image data is displayed in a mode in which the selection signal is supplied to one scan line at a frequency of lower than 30 Hz, preferably lower than 1 Hz, more preferably less than once per minute.

For example, the selection signal is supplied at Time T1 so that first image data PIC1 is displayed on the display portion 230 (see FIG. 19). At Time T2, which is, for example, one second after Time T1, the selection signal is supplied so that the predetermined image data is displayed.

Alternatively, in the case where a predetermined event is not supplied in the interrupt processing, image data is displayed in the second mode.

For example, the selection signal is supplied at Time T5 so that fourth image data PIC4 is displayed on the display portion 230. At Time T6, which is, for example, one second after Time T5, the selection signal is supplied so that the same image data is displayed. Note that the length of a period from Time T5 to Time T6 can be equal to that of a period from Time T1 to Time T2.

For instance, in the case where the predetermined event is supplied in the interrupt processing, predetermined image data is displayed in the first mode.

Specifically, in the case where an event associated with a “page turning instruction” is supplied in the interrupt processing, image data is switched from one to another in a mode in which the selection signal is supplied to one scan line at a frequency of 30 Hz or higher, preferably 60 Hz or higher.

Alternatively, in the case where an event associated with the “scrolling instruction” is supplied in the interrupt processing, second image data PIC2, which includes part of the displayed first image data PIC1 and the following part, is displayed in a mode in which the selection signal is supplied to one scan line at a frequency of 30 Hz or higher, preferably 60 Hz or higher.

Thus, for example, moving images in which images are gradually changed in accordance with the “page turning instruction” can be displayed smoothly. Alternatively, a moving image in which an image is gradually moved in accordance with the “scrolling instruction” can be displayed smoothly.

Specifically, the selection signal is supplied at Time T3 after the event associated with the “scrolling instruction” is supplied so that the second image data PIC2 whose display position and the like are changed from those of the first image data PIC1 is displayed (see FIG. 19). The selection signal is supplied at Time T4 so that third image data PIC3 whose display position and the like are changed from those of the second image data PIC2 is displayed. Note that each of a period from Time T2 to Time T3, a period from Time T3 to Time T4, and a period from Time T4 to Time T5 is shorter than the period from Time T1 to Time T2.

### [Fourth Step]

In the fourth step, the processing proceeds to the fifth step when a termination instruction is supplied, and the processing proceeds to the third step when the termination instruction is not supplied (see (S4) in FIG. 18A).

Note that in the interrupt processing, for example, the termination instruction can be supplied.

### [Fifth Step]

In the fifth step, the program terminates (see (S5) in FIG. 18A).

The interrupt processing includes sixth to ninth steps described below (see FIG. 18B).

### [Sixth Step]

In the sixth step, the processing proceeds to the seventh step when a predetermined event has been supplied, whereas the processing proceeds to the eighth step when the predetermined event has not been supplied (see (S6) in FIG. 18B). For example, whether the predetermined event is supplied in a predetermined period or not can be a branch condition. Specifically, the predetermined period can be longer than 0 seconds and shorter than or equal to 5 seconds, preferably shorter than or equal to 1 second, more preferably shorter than or equal to 0.5 seconds, still more preferably shorter than or equal to 0.1 seconds.

### [Seventh Step]

In the seventh step, the mode is changed (see (S7) in FIG. 18B). Specifically, the mode is changed to the second mode when the first mode has been selected, or the mode is changed to the first mode when the second mode has been selected.

### [Eighth Step]

In the eighth step, the interrupt processing terminates (see (S8) in FIG. 18B). Note that in a period in which the main processing is executed, the interrupt processing may be repeatedly executed.

### <<Predetermined Event>>

A variety of instructions can be associated with a variety of events.

The following instructions can be given as examples: “page-turning instruction” for switching displayed image data from one to another and “scroll instruction” for moving the display position of part of image data and displaying another part continuing from that part.

For example, the following events can be used: events supplied using a pointing device such as a mouse (e.g., “click” and “drag”) and events supplied to a touch panel with a finger or the like used as a pointer (e.g., “tap”, “drag”, and “swipe”).

For example, the position of a slide bar pointed by a pointer, the swipe speed, and the drag speed can be used as parameters assigned to various instructions.

Specifically, a parameter that determines the page-turning speed or the like can be used to execute the “page-turning instruction,” and a parameter that determines the moving speed of the display position or the like can be used to execute the “scroll instruction.”

For example, the display brightness, contrast, or saturation may be changed in accordance with the page-turning speed and/or the scroll speed.

Specifically, in the case where the page-turning speed and/or the scroll speed are/is higher than the predetermined speed, the display brightness may be decreased in synchronization with the speed.

Alternatively, in the case where the page-turning speed and/or the scroll speed are/is higher than the predetermined speed, the contrast may be decreased in synchronization with the speed.

For example, the speed at which user's eyes cannot follow displayed images can be used as the predetermined speed.

The contrast can be reduced in such a manner that the gray level of a bright region (with a high gray level) included in image data is brought close to the gray level of a dark region (with a low gray level) included in the image data.

Alternatively, the contrast can be reduced in such a manner that the gray level of the dark region included in image data is brought close to the gray level of the bright region included in the image data.

Specifically, in the case where the page-turning speed and/or the scroll speed are/is higher than the predetermined speed, display may be performed such that the yellow tone is increased or the blue tone is decreased in synchronization with the speed.

Image data may be generated based on the usage ambience of the data processing device acquired by the sensor portion 250. For example, user's favorite color can be used as the background color of the image data in accordance with the acquired ambient brightness or the like (see FIG. 16B).

Image data may be generated in accordance with received data delivered to a specific space using the communication portion 290. For example, educational materials can be fed from a classroom of, for example, a school or a university and displayed to be used as a schoolbook. Alternatively, materials distributed from a conference room in, for example, a company can be received and displayed (see FIG. 16C).

Thus, favorable environment can be provided for a user of the data processing device 200.

This embodiment can be combined with any of the other embodiments in this specification as appropriate.

### Embodiment 8

In this embodiment, a semiconductor device (memory device) that can retain stored data even when not powered and that has an unlimited number of write cycles, and a CPU including the semiconductor device will be described. The CPU described in this embodiment can be used for the data processing device described in Embodiment 7, for example.

### <Memory Device>

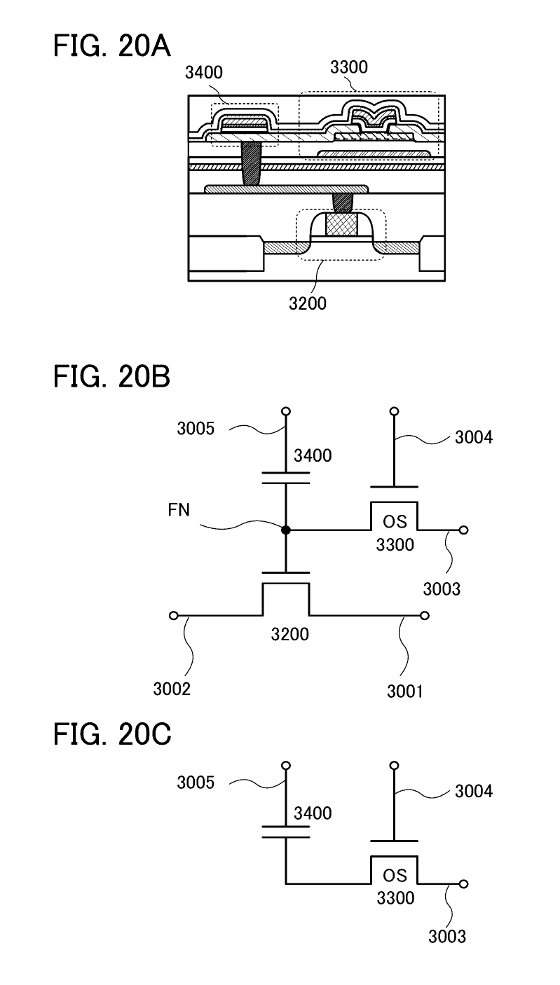

An example of a semiconductor device (memory device) which can retain stored data even when not powered and which has an unlimited number of write cycles is shown in FIGS. 20A to 20C. Note that FIG. 20B is a circuit diagram of the structure in FIG. 20A.

The semiconductor device illustrated in FIGS. 20A and 20B includes a transistor 3200 using a first semiconductor material, a transistor 3300 using a second semiconductor material, and a capacitor 3400.

The first and second semiconductor materials preferably have different energy gaps. For example, the first semiconductor material can be a semiconductor material other than an oxide semiconductor (examples of such a semiconductor material include silicon (including strained silicon), germanium, silicon germanium, silicon carbide, gallium arsenide, aluminum gallium arsenide, indium phosphide, gallium nitride, and an organic semiconductor), and the second semiconductor material can be an oxide semiconductor. A transistor using a material other than an oxide semiconductor, such as single crystal silicon, can operate at high speed easily. On the other hand, a transistor including an oxide semiconductor has a low off-state current.

In the transistor 3300, a channel is formed in a semiconductor layer including an oxide semiconductor. Since the off-state current of the transistor 3300 is low, stored data can be retained for a long time. In other words, power consumption can be sufficiently reduced because a semiconductor memory device in which refresh operation is unnecessary or the frequency of refresh operation is extremely low can be provided.

In FIG. 20B, a first wiring 3001 is electrically connected to a source electrode of the transistor 3200. A second wiring 3002 is electrically connected to a drain electrode of the transistor 3200. A third wiring 3003 is electrically connected to one of a source electrode and a drain electrode of the transistor 3300. A fourth wiring 3004 is electrically connected to a gate electrode of the transistor 3300. A gate electrode of the transistor 3200 and the other of the source electrode and the drain electrode of the transistor 3300 are electrically connected to one electrode of the capacitor 3400. A fifth wiring 3005 is electrically connected to the other electrode of the capacitor 3400.

The semiconductor device in FIG. 20A has a feature that the potential of the gate electrode of the transistor 3200 can be retained, and thus enables writing, retaining, and reading of data as follows.

Writing and retaining of data will be described. First, the potential of the fourth wiring 3004 is set to a potential at which the transistor 3300 is turned on, so that the transistor 3300 is turned on. Accordingly, the potential of the third wiring 3003 is supplied to the gate electrode of the transistor 3200 and the capacitor 3400. That is, predetermined charge is supplied to the gate of the transistor 3200 (writing). Here, one of two kinds of charge providing different potential levels (hereinafter referred to as low-level charge and high-level charge) is supplied. After that, the potential of the fourth wiring 3004 is set to a potential at which the transistor 3300 is turned off, so that the transistor 3300 is turned off Thus, the charge supplied to the gate of the transistor 3200 is retained (retaining).

Since the off-state current of the transistor 3300 is extremely low, the charge of the gate of the transistor 3200 is retained for a long time.

Next, reading of data will be described. An appropriate potential (a reading potential) is supplied to the fifth wiring 3005 while a predetermined potential (a constant potential) is supplied to the first wiring 3001, whereby the potential of the second wiring 3002 varies in accordance with the amount of charge retained in the gate of the transistor 3200. This is because in general, when an n-channel transistor is used as the transistor 3200, an apparent threshold voltage Vₜₕ_{_}_{H} at the time when the high-level charge is given to the gate electrode of the transistor 3200 is lower than an apparent threshold voltage Vₜₕ_{_}L at the time when the low-level charge is given to the gate electrode of the transistor 3200. Here, an apparent threshold voltage refers to the potential of the fifth wiring 3005 which is needed to turn on the transistor 3200. Thus, the potential of the fifth wiring 3005 is set to a potential V₀ which is between Vₜₕ_{_}H and Vₜₕ_{_}L, whereby charge supplied to the gate of the transistor 3200 can be determined. For example, in the case where the high-level charge is supplied to the gate of the transistor 3200 in writing and the potential of the fifth wiring 3005 is V₀ (>Vₜₕ_{_}H), the transistor 3200 is turned on. In the case where the low-level charge is supplied to the gate of the transistor 3200 in writing, the transistor 3200 remains off even when the potential of the fifth wiring 3005 is V₀ (<Vₜₕ_{_}L). Thus, the data retained in the gate of the transistor 3200 can be read by determining the potential of the second wiring 3002.

Note that in the case where memory cells are arrayed, it is necessary that data of a desired memory cell be read. For example, the fifth wiring 3005 of memory cells from which data is not read is supplied with a potential at which the transistor 3200 is turned off regardless of the potential supplied to the gate electrode, that is, a potential lower than Vₜₕ_{_}ft so that only data of a desired memory cell can be read. Alternatively, the fifth wiring 3005 of the memory cells from which data is not read is supplied with a potential at which the transistor 3200 is turned on regardless of the potential supplied to the gate electrode, that is, a potential higher than Vₜₕ_{_}L so that only data of a desired memory cell can be read.

The semiconductor device illustrated in FIG. 20C is different from the semiconductor device illustrated in FIG. 20A in that the transistor 3200 is not provided. In this case, data writing and retaining operations can be performed in a manner similar to those of the semiconductor device illustrated in FIG. 20A.

Next, reading of data in the semiconductor device illustrated in FIG. 20C will be described. When the transistor 3300 is turned on, the third wiring 3003 which is in a floating state and the capacitor 3400 are electrically connected to each other, and charge is redistributed between the third wiring 3003 and the capacitor 3400. As a result, the potential of the third wiring 3003 is changed. The amount of change in potential of the third wiring 3003 depends on the potential of the one electrode of the capacitor 3400 (or the charge accumulated in the capacitor 3400).

For example, the potential of the third wiring 3003 after the charge redistribution is (C_{B}×V_{B0}+C×V)/(C_{B}+C), where Vis the potential of the one electrode of the capacitor 3400, C is the capacitance of the capacitor 3400, C_{B} is the capacitance component of the third wiring 3003, and V_{BO} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the third wiring 3003 when the potential V₁ is retained (=(C_{B}×V_{B0}+C×V₁)/(C_{B}+C)) is higher than the potential of the third wiring 3003 when the potential V₀ is retained (=(C_{B}×V_{B0}+C×V₀)/(C_{B}+C)).

Then, by comparing the potential of the third wiring 3003 with a predetermined potential, data can be read.

In this case, a transistor containing the first semiconductor material may be used in a driver circuit for driving a memory cell, and a transistor containing the second semiconductor material may be stacked as the transistor 3300 over the driver circuit.

When a transistor having a channel formation region formed using an oxide semiconductor and having an extremely low off-state current is used in the semiconductor device described in this embodiment, the semiconductor device can retain stored data for an extremely long time. In other words, refresh operation becomes unnecessary or the frequency of the refresh operation can be extremely low, leading to a sufficient reduction in power consumption. Moreover, stored data can be retained for a long time even when not powered (note that a potential is preferably fixed).

Furthermore, in the semiconductor device described in this embodiment, a high voltage is not needed for data writing and there is no problem of deterioration of elements. Unlike in a conventional nonvolatile memory, for example, it is not necessary to inject and extract electrons into and from a floating gate; thus, a problem such as deterioration of a gate insulating film is unlikely to be caused. That is, the semiconductor device described in this embodiment does not have a limit on the number of times data can be rewritten, which is a problem of a conventional nonvolatile memory, and the reliability thereof is drastically improved. Moreover, since data is written depending on the state of the transistor (on or off), high-speed operation can be easily achieved.

The memory device described above can also be used in an LSI such as a central processing unit (CPU), a digital signal processor (DSP), a custom LSI, or a programmable logic device (PLD), and a radio frequency identification (RF-ID), for example.

### <CPU>

A CPU including the above memory device will be described below.

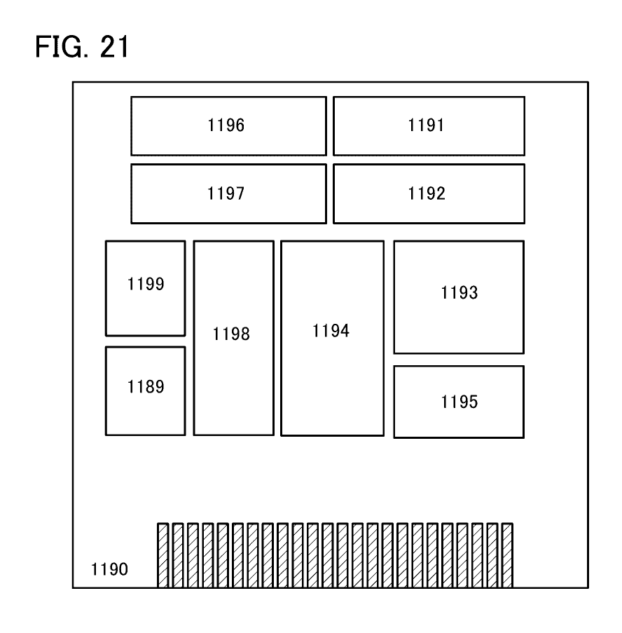

FIG. 21 is a block diagram illustrating a configuration example of the CPU including the above memory device.

The CPU illustrated in FIG. 21 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface 1198 (BUS I/F), a rewritable ROM 1199, and a ROM interface (ROM I/F) 1189. A semiconductor substrate, an SOI substrate, a glass substrate, or the like is used as the substrate 1190. The ROM 1199 and the ROM interface 1189 may be provided over a separate chip. Needless to say, the CPU in FIG. 21 is just an example in which the configuration is simplified, and an actual

CPU may have a variety of configurations depending on the application. For example, the CPU may have the following configuration: a structure including the CPU illustrated in FIG. 21 or an arithmetic circuit is considered as one core; a plurality of the cores are included; and the cores operate in parallel. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in response to the decoded instruction. Specifically, the ALU controller 1192 generates signals for controlling the operation of the ALU 1191. While the CPU is executing a program, the interrupt controller 1194 determines an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal based on a reference clock signal, and supplies the internal clock signal to the above circuits.

In the CPU illustrated in FIG. 21, a memory cell is provided in the register 1196.

In the CPU illustrated in FIG. 21, the register controller 1197 selects operation of retaining data in the register 1196 in accordance with an instruction from the ALU 1191. That is, the register controller 1197 selects whether data is retained by a flip-flop or whether it is retained by a capacitor in the memory cell included in the register 1196. When data retaining by the flip-flop is selected, a power supply voltage is supplied to the memory cell in the register 1196. When data retaining by the capacitor is selected, the data is rewritten in the capacitor, and supply of the power supply voltage to the memory cell in the register 1196 can be stopped.

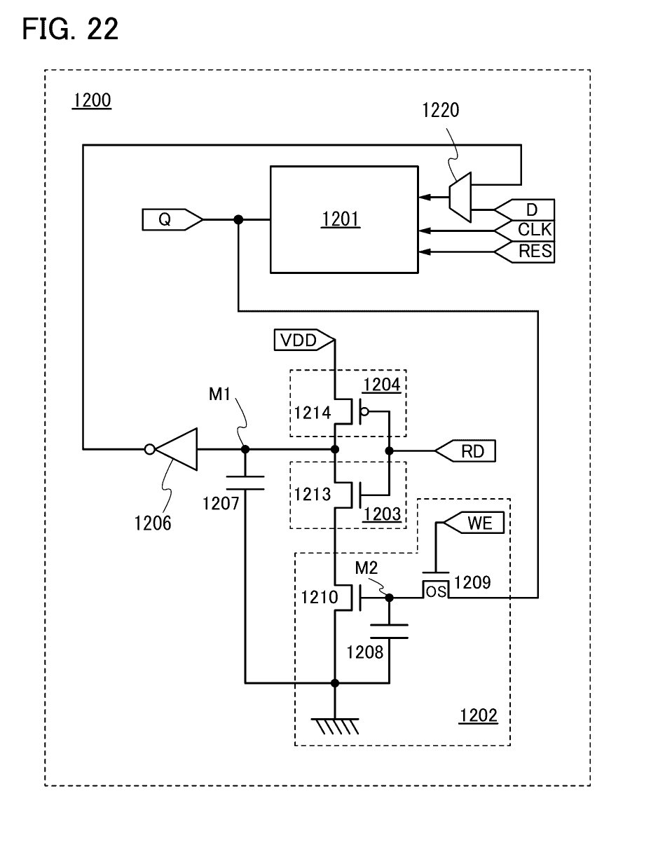

FIG. 22 is an example of a circuit diagram of a memory circuit that can be used as the register 1196. A memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the memory device described above can be used as the circuit 1202. When supply of a power supply voltage to the memory element 1200 is stopped, a ground potential (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a wiring which can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a wiring which can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the wiring which can supply a low power supply potential (e.g., a GND line). The other of the pair of electrodes of the capacitor 1208 can be supplied with a constant potential. For example, the other of the pair of electrodes of the capacitor 1208 can be supplied with a low power supply potential (e.g., GND) or a high power supply potential (e.g., VDD). The other of the pair of electrodes of the capacitor 1208 is electrically connected to the wiring which can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to the first gate (first gate electrode) of the transistor 1209. As for each of the switch 1203 and the switch 1204, a conduction state or a non-conduction state between the first terminal and the second terminal is selected by the control signal RD which is different from the control signal WE. When one of the switches is in the conduction state between the first terminal and the second terminal, the other of the switches is in the non-conduction state between the first terminal and the second terminal.

A signal corresponding to data retained in the circuit 1201 is input to the other of the source and the drain of the transistor 1209. FIG. 22 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 22, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 22, the transistors included in the memory element 1200 except the transistor 1209 can each be a transistor in which a channel is formed in a layer formed using a semiconductor other than an oxide semiconductor or in the substrate 1190. For example, the transistor can be a transistor whose channel is formed in a silicon layer or a silicon substrate. Alternatively, a transistor in which a channel is formed in an oxide semiconductor film can be used for all the transistors in the memory element 1200. Still alternatively, in the memory element 1200, a transistor in which a channel is formed in an oxide semiconductor film can be included besides the transistor 1209, and a transistor in which a channel is formed in a layer formed using a semiconductor other than an oxide semiconductor or in the substrate 1190 can be used for the rest of the transistors.

As the circuit 1201 in FIG. 22, for example, a flip-flop circuit can be used. As the logic element 1206, for example, an inverter or a clocked inverter can be used.

In a period during which the memory element 1200 is not supplied with a power supply voltage, the semiconductor device described in this embodiment can retain data stored in the circuit 1201 by the capacitor 1208 which is provided in the circuit 1202.

The off-state current of a transistor in which a channel is formed in an oxide semiconductor film is extremely low. For example, the off-state current of a transistor in which a channel is formed in an oxide semiconductor film is significantly lower than that of a transistor in which a channel is formed in silicon having crystallinity. Thus, when the transistor in which a channel is formed in an oxide semiconductor film is used as the transistor 1209, a signal held in the capacitor 1208 is retained for a long time also in a period during which a power supply voltage is not supplied to the memory element 1200. The memory element 1200 can accordingly retain the stored content (data) also in a period during which the supply of the power supply voltage is stopped.

Since the above-described memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Therefore, after supply of the power supply voltage to the memory element 1200 is restarted, the transistor 1210 is turned on or off in accordance with the signal retained by the capacitor 1208 and the signal can be read from the circuit 1202. Consequently, an original signal can be accurately read even when a potential corresponding to the signal retained by the capacitor 1208 varies to some degree.

By using the above-described memory element 1200 for a memory device such as a register or a cache memory included in a processor, data in the memory device can be prevented from being lost owing to the stop of the supply of a power supply voltage. Furthermore, shortly after the supply of the power supply voltage is restarted, the memory device can be returned to the same state as that before the power supply is stopped. Therefore, the power supply can be stopped even for a short time in the processor or one or more of logic circuits included in the processor, resulting in lower power consumption.

Although the memory element 1200 is used in a CPU in this embodiment, the memory element 1200 can also be used in an LSI such as a digital signal processor (DSP), a custom LSI, or a programmable logic device (PLD), and a radio frequency identification (RF-ID).

At least part of this embodiment can be implemented in combination with any of the other embodiments described in this specification as appropriate.

### Embodiment 9

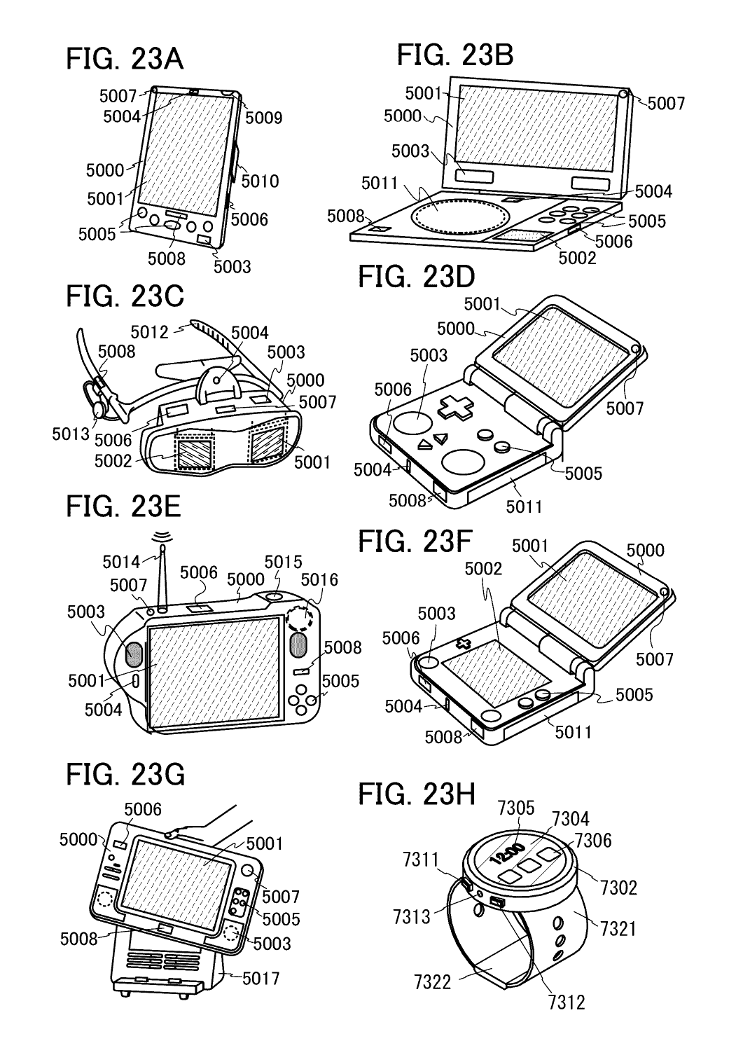

In this embodiment, a display module and electronic devices each including the display panel of one embodiment of the present invention will be described with reference to FIGS. 23A to 23H.

FIGS. 23A to 23G illustrate electronic devices. These electronic devices can include a housing 5000, a display portion 5001, a speaker 5003, an LED lamp 5004, operation keys 5005 (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, an electric field, a current, a voltage, electric power, radiation, a flow rate, humidity, gradient, oscillation, odor, or infrared ray), a microphone 5008, and the like.

FIG. 23A illustrates a mobile computer which can include a switch 5009, an infrared port 5010, and the like in addition to the above components. FIG. 23B illustrates a portable image reproducing device (e.g., a DVD reproducing device) which is provided with a memory medium and can include a second display portion 5002, a memory medium reading portion 5011, and the like in addition to the above components. FIG. 23C illustrates a goggle-type display which can include the second display portion 5002, a supporting portion 5012, an earphone 5013, and the like in addition to the above components. FIG. 23D illustrates a portable game machine which can include the memory medium reading portion 5011 and the like in addition to the above components. FIG. 23E illustrates a digital camera which has a television reception function and can include an antenna 5014, a shutter button 5015, an image receiving portion 5016, and the like in addition to the above components. FIG. 23F illustrates a portable game machine which can include the second display portion 5002, the memory medium reading portion 5011, and the like in addition to the above components. FIG. 23G illustrates a portable television receiver which can include a charger 5017 capable of transmitting and receiving signals, and the like in addition to the above components.

The electronic devices illustrated in FIGS. 23A to 23G can have a variety of functions. For example, a function of displaying a variety of data (a still image, a moving image, a text image, and the like) on a display portion, a touch panel function, a function of displaying a calendar, date, time, and the like, a function of controlling a process with a variety of software (programs), a wireless communication function, a function of being connected to a variety of computer networks with a wireless communication function, a function of transmitting and receiving a variety of data with a wireless communication function, a function of reading a program or data stored in a memory medium and displaying the program or data on a display portion, and the like can be given. Further, the electronic device including a plurality of display portions can have a function of displaying image data mainly on one display portion while displaying text data on another display portion, a function of displaying a three-dimensional image by displaying images where parallax is considered on a plurality of display portions, or the like. Furthermore, the electronic device including an image receiving portion can have a function of shooting a still image, a function of taking a moving image, a function of automatically or manually correcting a shot image, a function of storing a shot image in a memory medium (an external memory medium or a memory medium incorporated in the camera), a function of displaying a shot image on the display portion, or the like. Note that functions that can be provided for the electronic devices illustrated in FIGS. 23A to 23G are not limited thereto, and the electronic devices can have a variety of functions.

FIG. 23H illustrates a smart watch, which includes a housing 7302, a display panel 7304, operation buttons 7311 and 7312, a connection terminal 7313, a band 7321, a clasp 7322, and the like.

The display panel 7304 mounted in the housing 7302 also serving as a bezel includes a non-rectangular display region. The display panel 7304 may have a rectangular display region. The display panel 7304 can display an icon 7305 indicating time, another icon 7306, and the like.

The smart watch in FIG. 23H can have a variety of functions such as a function of displaying a variety of data (e.g., a still image, a moving image, and a text image) on the display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion.

The housing 7302 can include a speaker, a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone, and the like. Note that the smart watch can be manufactured using the light-emitting element for the display panel 7304.

This embodiment can be combined with any of the other embodiments in this specification as appropriate.

For example, in this specification and the like, an explicit description “X and Y are connected” means that X and Y are electrically connected, X and Y are functionally connected, and X and Y are directly connected. Accordingly, without limitation to a predetermined connection relation, for example, a connection relation shown in drawings or text, another connection relation is included in the drawings or the text.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, and a load) is not connected between X and Y, that is, the case where X and Y are connected without the element that allows the electrical connection between X and Y provided therebetween.

For example, in the case where X and Y are electrically connected, one or more elements that enable electrical connection between X and Y (e.g., a switch, a transistor, a capacitor, an inductor, a resistor, a diode, a display element, a light-emitting element, and a load) can be connected between X and Y. A switch is controlled to be on or off That is, a switch is conducting or not conducting (is turned on or off) to determine whether a current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that enable functional connection between X and Y (e.g., a logic circuit such as an inverter, a NAND circuit, or a NOR circuit; a signal converter circuit such as a DA converter circuit, an AD converter circuit, or a gamma correction circuit; a potential level converter circuit such as a power supply circuit (e.g., a step-up circuit and a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; and/or a control circuit) can be connected between X and Y. Note that for example, in the case where a signal output from X is transmitted to Y even when another circuit is interposed between X and Y, X and Y are functionally connected. Note that the case where X and Y are functionally connected includes the case where X and Y are directly connected and X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the description “X and Y are connected”.

Note that, for example, the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to a part of Z1 and another part of Z1 is directly connected to X while a drain (or a second terminal or the like) of the transistor is directly connected to a part of Z2 and another part of Z2 is directly connected to Y, can be expressed by using any of the following expressions.

The expressions include, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”, “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path”. Other examples of the expressions also include “a source (or a first terminal or the like) of a transistor is electrically connected to X through at least Z1 on a first connection path, the first connection path does not include a second connection path, the second connection path includes a connection path through the transistor, a drain (or a second terminal or the like) of the transistor is electrically connected to Y through at least Z2 on a third connection path, and the third connection path does not include the second connection path”, and “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit configuration is defined by an expression similar to the above examples, a source (or a first terminal or the like) and a drain (or a second terminal or the like) of a transistor can be distinguished from each other to specify the technical scope.

Note that these expressions are only examples and one embodiment of the present invention is not limited to the expressions. Here, X, Y, Z1, and Z2 each denote an object (e.g., a device, an element, a circuit, a wiring, an electrode, a terminal, a conductive film, and a layer).

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

### EXPLANATION OF REFERENCE

AF1: alignment film, AF2: alignment film, Cl: capacitor, C2: capacitor, CF1: coloring film, CF1D: coloring film, CF2: coloring film, ANO: wiring, CSCOM: wiring, G1(i): scan line, G2(i): scan line, S1(j): signal line, S2(j): signal line, VCOM1: wiring, VCOM2: wiring, GD: driver circuit, GDA: driver circuit, GDB: driver circuit, SD: driver circuit, KB1: structure body, M1: node, M2: node, M: transistor, MD: transistor, MB: transistor, MDB: transistor, P1: positional data, P2: data, SW1: switch, SW2: switch, SW1B: switch, T1: time, T2: time, T3: time, T4: time, T5: time, T6: time, V: image data, V0: potential, V1: potential, VDD: power supply potential, PIC1: image data, PIC2: image data, PIC3: image data, PIC4: image data, 100: transistor, 102: substrate, 104: conductive film, 106: insulating film, 107: insulating film, 108: oxide semiconductor film, 108a: oxide semiconductor film, 108b: oxide semiconductor film, 108c: oxide semiconductor film, 112a: conductive film, 112b: conductive film, 114: insulating film, 116: insulating film, 118: insulating film, 120a: conductive film, 120b: conductive film, 200: data processing device, 210: arithmetic device, 211: arithmetic unit, 212: memory unit, 214: transmission path, 215: input/output interface, 220: input/output device, 230: display portion, 230B: display portion, 231: display region, 232: pixel, 235EL: display element, 235LC: display element, 240: input portion, 250: sensor portion, 290: communication portion, 501A: insulating film, 501A1: insulating film, 501A2: insulating film, 501C: insulating film, 501H: opening, 504: conductive film, 505: bonding layer, 506: insulating film, 508: semiconductor film, 510: substrate, 511B: conductive film, 511C: conductive film, 512A: conductive film, 512B: conductive film, 516: insulating film, 518: insulating film, 519B: terminal, 519C: terminal, 520: functional layer, 521: insulating film, 522: connection portion, 524: conductive film, 528: insulating film, 530: pixel circuit, 550: display element, 551: electrode, 552: electrode, 553: layer containing a light-emitting organic compound, 570: substrate, 591A: opening, 591B: opening, 591C: opening, 700: display panel, 700B: display panel, 700C: display panel, 700D: display panel, 702: pixel, 705: sealing material, 750: display element, 751: electrode, 751A: conductive film, 751B: conductive film, 751H: opening, 752: electrode, 753: layer, 754: intermediate film, 754A: intermediate film, 754B: intermediate film, 770: substrate, 770P: functional film, 771: insulating film, 800: input/output device, 801: upper cover, 802: lower cover, 803: FPC, 804: touch sensor, 805: FPC, 806: display panel, 809: frame, 810: driver circuit, 811: battery, 1189: ROM interface, 1190: substrate, 1191: ALU, 1192: ALU controller, 1193: instruction decoder, 1194: interrupt controller, 1195: timing controller, 1196: register, 1197: register controller, 1198:

bus interface, 1199: ROM, 1200: memory element, 1201: circuit, 1202: circuit, 1203: switch, 1204: switch, 1206: logic element, 1207: capacitor, 1208: capacitor, 1209: transistor, 1210: transistor, 1213: transistor, 1214: transistor, 1220: circuit, 3001: wiring, 3002: wiring, 3003: wiring, 3004: wiring, 3005: wiring, 3200: transistor, 3300: transistor, 3400: capacitor, 5000: housing, 5001: display portion, 5002: display portion, 5003: speaker, 5004: LED lamp, 5005:

operation keys, 5006: connection terminal, 5007: sensor, 5008: microphone, 5009: switch, 5010: infrared port, 5011: memory medium reading portion, 5012: supporting portion, 5013: earphone, 5014: antenna, 5015: shutter button, 5016: image receiving portion, 5017: charger, 7302: housing, 7304: display panel, 7305: icon, 7306: icon, 7311: operation button, 7312: operation button, 7313: connection terminal, 7321: band, 7322: clasp

This application is based on Japanese Patent Application serial no. 2015-156992 filed with Japan Patent Office on Aug. 7, 2015 and Japanese Patent Application serial no. 2016-122745 filed with Japan Patent Office on Jun. 21, 2016, the entire contents of which are hereby incorporated by reference.

1. A display panel comprising:
a signal line; and
a pixel,
wherein the pixel is electrically connected to the signal line,
wherein the pixel comprises:
a first display element;
a first conductive film;
a second conductive film;
a first insulating film;
an intermediate film;
a pixel circuit; and
a second display element,
wherein the first conductive film is electrically connected to the first display element,
wherein a portion of the second conductive film overlaps with the first conductive film;
wherein a first portion of the first insulating film is located between the second conductive film and the first conductive film,
wherein the first insulating film has a first opening,
wherein the second conductive film is electrically connected to the first conductive film through the first opening,
wherein the first conductive film is located between the first insulating film and a first portion of the intermediate film,
wherein the pixel circuit is electrically connected to the second conductive film,
wherein the pixel circuit is electrically connected to the signal line, and
wherein the second display element is electrically connected to the pixel circuit.

2. The display panel according to claim 1,
wherein the intermediate film includes a conductive oxide or an oxide semiconductor.

3. The display panel according to claim 1, further comprising:
a second insulating film,
wherein the second insulating film has a second opening,
wherein a portion of the second insulating film is located between the intermediate film and the first insulating film, along an outer edge of the second opening,
wherein the intermediate film includes a side end portion embedded at the second insulating film, and
wherein a second portion of the intermediate film overlaps with the second opening and is in contact with the first conductive film.

4. The display panel according to claim 1,
wherein the pixel circuit includes a switch,
wherein the switch includes a transistor, and
wherein the transistor includes an oxide semiconductor.

5. The display panel according to claim 1,
wherein the second display element is located so as to be seen in a part of a range in which the first display element is seen.

6. The display panel according to claim 1,
wherein the second display element is configured to display an image in a first region surrounded by a second region in which the first display element displays an image.

7. The display panel according to claim 1,
wherein the first display element includes a reflective film and is configured to control intensity of reflected light,
wherein the reflective film is configured to reflect incident light,
wherein the reflective film has a third opening, and
wherein the second display element is configured to emit light toward the third opening.

8. The display panel according to claim 1, comprising:
the pixel;
a first group of pixels;
a second group of pixels; and
a scan line,
wherein the first group of pixels include the pixel,
wherein the first group of pixels are arranged in a row direction,
wherein the second group of pixels include the pixel,
wherein the second group of pixels are arranged in a column direction intersecting the row direction,
wherein the scan line is electrically connected to the first group of pixels arranged in the row direction,
wherein the second group of pixels arranged in the column direction are electrically connected to the signal line,
wherein the first group of pixels comprises a first pixel,
wherein a second pixel comprised in the first group of pixels or the second group of pixels is adjacent to the first pixel,
wherein the first pixel has a fourth opening,
wherein the second pixel has a fifth opening, and
wherein a relative position of the fourth opening in the first pixel is different from a relative position of the fifth opening in the second pixel.

9. The display panel according to claim 1, further comprising:
a terminal; and
a third conductive film,
wherein a portion of the third conductive film overlaps with the terminal,
wherein a second portion of the first insulating film is located between the terminal and the third conductive film,
wherein the first insulating film has a sixth opening,
wherein the terminal is electrically connected to the third conductive film through the sixth opening, and
wherein the third conductive film is electrically connected to the pixel circuit.

10. A data processing device comprising:
an arithmetic device; and
an input/output device,
wherein the arithmetic device is configured to receive positional data and supply image data and control data,
wherein the input/output device is configured to supply the positional data and receive the image data and the control data,
wherein the input/output device includes a display portion that displays the image data and an input portion that supplies the positional data,
wherein the display portion includes the display panel according to claim 1,
wherein the input portion is configured to supply the positional data based on a position of a pointer,
wherein the arithmetic device is configured to determine moving speed of the pointer in accordance with the positional data, and
wherein the arithmetic device is configured to determine contrast or brightness of the image data in accordance with the moving speed of the pointer.

11. The data processing device according to claim 10,
wherein the input portion includes at least one of a keyboard, a hardware button, a pointing device, a touch sensor, an illuminance sensor, an imaging device, an audio input device, a viewpoint input device, and a posture determination device.

12. A method for manufacturing a display panel, comprising the steps of:
forming an intermediate film including a region overlapping with a process substrate;
forming a second insulating film covering the intermediate film;
heating the second insulating film;
processing the second insulating film into a predetermined shape;
forming a first conductive film including a region overlapping with the intermediate film;
forming a first insulating film having an opening in a region overlapping with the first conductive film;
forming a second conductive film and a pixel circuit that overlap with the opening,
forming a second display element electrically connected to the pixel circuit;
stacking a second substrate such that the second display element is located between the second substrate and the process substrate;
separating the process substrate;
forming an alignment film such that the intermediate film is located between the first conductive film and the alignment film; and
forming a first display element.
